(19) United States
(12) Patent Application Publication
(10) Pub. No.: US 2025/0053092 A1
(43) Pub. Date: Feb. 13, 2025

(54) AQUEOUS ACID DEVELOPMENT OR TREATMENT OF ORGANOMETALLIC PHOTORESIST

(71) Applicant: Lam Research Corporation, Fremont, CA (US)

(72) Inventors: Nizan Kenane, San Francisco, CA (US); Timothy William Weidman, Sunnyvale, CA (US); Eric Calvin Hansen, San Jose, CA (US); Chenghao Wu, San Jose, CA (US); Kevin Li Gu, Mountain View, CA (US); Benjamin Kam, Heverlee (BE)

(21) Appl. No.: 18/719,443

(22) PCT Filed: Dec. 12, 2022
(86) PCT No.: PCT/US2022/081390

§ 371 Date: Jun. 13, 2024

Related U.S. Application Data
(60) Provisional application No. 63/265,568, filed on Dec. 16, 2021.

(51) Int. Cl. G03F 7/36; G03F 7/004; G03F 7/38; G03F 7/40

(52) U.S. Cl. CPC G03F 7/36; G03F 7/0042; G03F 7/38; G03F 7/405

(57) ABSTRACT

The present disclosure relates to use of aqueous acid for developing or treating a radiation-sensitive film. The aqueous acid can be employed to form a pattern by a positive tone wet development process or to treat a developed pattern by further removing residual resist components.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### FIELD

The present disclosure relates to use of aqueous acid for developing or treating a radiation-sensitive film. The aqueous acid can be employed to form a pattern by a positive tone wet development process or to treat a developed pattern by further removing residual resist components.

### BACKGROUND

As semiconductor fabrication continues to advance, feature sizes continue to shrink, and new processing methods are needed. One area where advances are being made is in the context of patterning, for example using photoresist materials that are sensitive to lithographic radiation.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Various embodiments herein relate to methods, materials, apparatus, and systems for developing or treating a photoresist material on a substrate. In particular, described herein are methods and processes employing an aqueous acid. Organotin-based photoresists generally possess a hydrophobic ligand that can be released upon exposure to radiation. Thus, the exposed resist generally possesses decreased hydrophobicity (or increased hydrophilicity), as compared to unexposed resist. As described herein, the present disclosure takes advantage of this hydrophobicity difference by using an aqueous acid to preferentially dissolve and remove the radiation-exposed regions of the photoresist layer or film. In this way, an aqueous acid can be used to develop exposed photoresist in a positive tone manner.

Described herein are other uses of an aqueous acid to dissolve any residual species or particles that could remain after processing substrates having such organotin photoresist films. For instance, such residual species may include tin halide species, tin-containing particles, and the like.

When negative tone development is employed with organotin photoresists (PR), the radiation-exposed regions are processed to provide dense, tin oxide (SnOx)-containing networks. The radiation-unexposed regions can include a hydrophobic ligand that, while hydrophobic, are still more amenable to etching by dry development processes, as compared to SnOx-containing networks. Dry development processes can etch away organotin species but may leave behind unwanted, residual species. The present disclosure encompasses the use of an aqueous acid to remove such residual species, while retaining SnOx-containing networks that are resistant to removal by an aqueous acid.

Further described herein are methods and processes to enhance selectivity of a process that employs an aqueous acid. In one non-limiting instance, the hydrophobic character of unexposed organotin PR can be enhanced or amplified at the surface. For example and without limitation, such hydrophobicity enhancement at the surface can be achieved by post-application baking (PAB). In another non-limiting example, hydrophobicity at the surface can be enhanced by conducting an organic-rich deposition step at the end of the deposition process. The organic-rich deposition process can include use of a hydrophobic capping layer. In another instance, the organic-rich deposition process can include use of a precursor having increased hydrophobicity at a top surface of the PR film, as compared to a precursor employed within the bulk PR film.

Accordingly, in a first aspect, the present disclosure encompasses a method including: exposing a radiation-sensitive resist film to a patterning radiation source, thereby providing an exposed resist film having an exposed region and an unexposed region; and developing the exposed resist film by removing the exposed region with an aqueous acid, thereby forming a pattern by a positive tone wet development process.

In some embodiments, the method does not include a baking operation before or after said exposing. In other embodiments, the method includes a baking operation (e.g., a post-application baking operation) before said exposing.

In other embodiments, the resist film further includes a hydrophobic capping layer disposed on a top surface. In some embodiments, the resist film includes a vertical gradient characterized by an increase in hydrophobicity at a top surface.

In some embodiments, the method further includes (e.g., after said wet developing operation): rinsing the film with an aqueous solvent. In further embodiments, the method further includes (e.g., after said rinsing): drying the film.

In a second aspect, the present disclosure encompasses a method including: exposing a radiation-sensitive resist film to a patterning radiation source, thereby providing an exposed resist film having an exposed region and an unexposed region; developing the exposed resist film by removing the unexposed region, thereby forming a pattern by a negative tone development process; and treating the pattern with an aqueous acid.

In some embodiments, said developing includes a wet process or a dry process. In other embodiments, said developing includes use of an alkaline developer, an acidic developer, or a deprotecting solvent. In yet other embodiments, said developing includes use of a quaternary alkylammonium hydroxide, tetramethylammonium hydroxide (TMAH), choline, a halide, hydrogen fluoride (HF), hydrogen chloride (HCl), an organic acid, formic acid, acetic acid, oxalic acid, or citric acid. In some embodiments, said developing includes use of a vapor-based acidic etchant. Non-limiting examples of vapor-based acidic etchants include hydrogen chloride (HCl), hydrogen bromide (HBr), boron trichloride (BCl₃), silicon tetrachloride (SiCl₄), a combination of hydrogen gas (H₂) and chlorine gas (Cl₂), or a combination of hydrogen gas (H₂) and bromine gas (Cl₂).

In some embodiments, said treating includes removing residual species or particles formed after said developing. Such residual species or particles can include any having a metal or an atom having a high EUV absorption cross-section (e.g., any metal or atom described herein).

In some embodiments, the method further includes (e.g., before said exposing and/or said developing): applying the radiation-sensitive resist film on a surface of the radiation-absorbing layer. In particular embodiments, said applying includes: providing one or more precursors including a structure having formula (I), formula (II), or any precursor described herein to the surface of the substrate.

In a third aspect, the present disclosure encompasses an apparatus for processing a substrate, the apparatus including: one or more process chambers, each process chamber optionally including a chuck or a pedestal; one or more inlets into the process chambers and associated flow-control hardware; and a controller having at least one processor and a memory.

In some embodiments, the at least one processor and the memory are communicatively connected with one another; the at least one processor is at least operatively connected with the flow-control hardware; and the memory stores computer-executable instructions for controlling the at least one processor to at least control the flow-control hardware and for causing any of method described herein.

In a fourth aspect, the present disclosure features an apparatus for forming a resist film, the apparatus including: a deposition module, a patterning module, a development module, an optional treatment module, and a controller including one or more memory devices, one or more processors, and system control software coded with instructions including machine-readable instructions.

In some embodiments, the deposition module includes a chamber for depositing a resist film (e.g., a patterning radiation-sensitive film, such as an EUV-sensitive film), in which the chamber can be configured to house a semiconductor substrate. In other embodiments, the patterning module includes a photolithography tool with a source of sub-300 nm wavelength radiation (e.g., in which the source can be a source of sub-30 nm wavelength radiation). In some embodiments, the development module includes a chamber for developing the resist film (e.g., for wet developing or dry developing). In other embodiments, the treatment module includes a chamber for treating the resist film (e.g., the resist film having a pattern).

In further embodiments, the instructions include machine-readable instructions for (e.g., in the deposition module) causing deposition of a precursor in the optional presence of a counter-reactant on a top surface of a semiconductor substrate to form the resist film. In some embodiments, such deposition can form the patterning radiation-sensitive film as a resist film.

In some embodiments, the instructions include machine-readable instructions for (e.g., in the patterning module) causing patterning of the resist film with sub-300 nm resolution (e.g., or with sub-30 nm resolution) directly by patterning radiation exposure (e.g., by EUV exposure), thereby forming an exposed film having radiation exposed areas and radiation unexposed areas. In other embodiments, the exposed film has EUV exposed areas and EUV unexposed areas.

In other embodiments, the instructions include machine-readable instructions for (e.g., in the development module) causing development of the film to remove the radiation exposed areas or the radiation unexposed areas to provide a pattern within the resist film. In particular embodiments, the machine-readable instructions include instructions for causing removal of the EUV exposed areas or the EUV unexposed areas. In some embodiments, such development can include delivering one or more acids into the development module.

In yet other embodiments, the instructions include machine-readable instructions for (e.g., in the treatment module) causing treatment of the film to remove residual species or particles from the film. In some embodiments, such treatment can include delivering one or more acids into the treatment module.

In any embodiment herein, the aqueous acid includes about 0.01% (v/v) to 5% (v/v), 0.1% (v/v) to 5% (v/v), or 0.1% (v/v) to 2% (v/v) of an acid in a solvent. Non-limiting acids include a halogen-containing acid, a hydrogen halide, an inorganic acid, a phosphorus oxoacid, a sulfur oxoacid, a carboxylic acid, or any described herein. Yet other examples of acids include hydrogen chloride (HCl), hydrogen bromide (HBr), hydrogen iodide (HI), phosphoric acid, sulfuric acid, formic acid, acetic acid, trifluoroacetic acid, oxalic acid, or citric acid. Such an acid can be provided within a dry process (e.g., as a vapor) or a wet process (e.g., as a liquid).

In any embodiment herein, the patterning radiation-sensitive film includes an extreme ultraviolet (EUV)-sensitive film, an EUV-sensitive inorganic photoresist layer, a deep-ultraviolet (DUV)-sensitive film, a photoresist film, or a photopattemable film.

In any embodiment herein, the patterning radiation source includes an EUV radiation source.

In any embodiment herein, the resist film includes tin (Sn), indium (In), bismuth (Bi), antimony (Sb), tellurium (Te), an oxide thereof, an alloy thereof, or a combination thereof.

In any embodiment herein, the resist film includes a chemical vapor deposited (CVD) film, a spin-on film, an organometallic oxide film, an organometallic oxide hydroxide film, a tin oxide film, or an organotin oxide film.

In any embodiment herein, a precursor (e.g., to provide a resist film) includes a structure having formula (I):

MₐR_{b} (I),

wherein: M is a metal or an atom having a high EUV absorption cross-section; each R is, independently, H, halo, optionally substituted alkyl, optionally substituted cycloalkyl, optionally substituted cycloalkenyl, optionally substituted alkenyl, optionally substituted alkynyl, optionally substituted alkoxy, optionally substituted alkanoyloxy, optionally substituted aryl, optionally substituted amino, optionally substituted bis(trialkylsilyl)amino, optionally substituted trialkylsilyl, oxo, an anionic ligand, a neutral ligand, or a multidentate ligand; a≥1; and b≥1.

In any embodiment herein, a precursor (e.g., to provide a resist film) includes a structure having formula (II):

MₐR_{b}L_{c} (II),

wherein: M is a metal or an atom having a high EUV absorption cross-section; each R is, independently, halo, optionally substituted alkyl, optionally substituted aryl, optionally substituted amino, optionally substituted alkoxy, or L; each L is, independently, a ligand, an anionic ligand, a neutral ligand, a multidentate ligand, ion, or other moiety that is reactive with a counter-reactant, in which R and L with M, taken together, can optionally form a heterocyclyl group or in which R and L, taken together, can optionally form a heterocyclyl group; a≥1; b≥1; and c≥1.

In any embodiment herein, said providing the resist film or said depositing the resist film further includes providing a counter-reactant. Non-limiting counter-reactants include oxygen or a chalcogenide precursor, as well as any described herein (e.g., an oxygen-containing counter-reactant, including oxygen (O₂), ozone (O₃), water, a peroxide, hydrogen peroxide, oxygen plasma, water plasma, an alcohol, a dihydroxy alcohol, a polyhydroxy alcohol, a fluorinated dihydroxy alcohol, a fluorinated polyhydroxy alcohol, a fluorinated glycol, formic acid, and other sources of hydroxyl moieties, as well as combinations thereof).

Other features and advantages of the disclosure will be apparent from the following description and the claims.

### BRIEF DESCRIPTION OF THE DRAWINGS

FIG. 1A-1B presents diagrams of (A) a non-limiting method for exposing and developing a resist film by a positive tone wet process that employs an aqueous acid; and (B) a non-limiting method for exposing and developing a resist film by a negative tone wet process, which can be followed by treating a pattern with an aqueous acid to remove residual species or particles formed after negative development. The chemical structures herein provide a simplified illustration of the mechanism, in which additional bonds and/or atoms may be present or in which depicted bonds and/or atoms may be absent.

FIG. 2A-2C presents schematic diagram of non-limiting methods that employ an aqueous acid with a resist film. Provided are (A) a non-limiting method 200 using a positive tone development process; (B) another non-limiting method 250 using a positive tone development process; and (C) a non-limiting method 2000 using a negative tone development process and then treatment with an aqueous acid.

FIG. 3A-3D presents schematic block diagrams of non-limiting methods for making and using a resist film.

FIG. 4A-4C presents results from a process that includes a photoresist (PR) deposition operation, post-application bake (PAB) operation, an electron-beam exposure operation, and then a positive tone aqueous development operation. Provided are scanning electron microscopy (SEM) images of (A) dry deposited films that were developed using tetramethylammonium hydroxide (TMAH) or hydrogen chloride (HCl), in which PAB is employed in the presence of air or nitrogen gas (N₂); (B) a side view of a developed film that was developed using TMAH and processed with a PAB operation under N₂; and (C) a side view of a developed film that was developed using HCl and processed with a PAB operation under N₂.

FIG. 5A-5C presents results from a process that includes a PR deposition operation, an electron-beam exposure operation, and then a positive tone aqueous development operation. In particular, the process lacks a PAB operation and lacks a post-exposure bake (PEB) operation. Provided are (A) a graph showing extent of film loss as a function of development time using either 0.9% (v/v) of aqueous HCl (gray squares) or 0.5% (v/v) of aqueous HCl (black circles); (B, C) SEM images of dry deposited films that were developed for 30 seconds using 0.5% (v/v) of aqueous HCl.

FIG. 6 presents a schematic illustration of an embodiment of a process station 600 for dry development.

FIG. 7 presents a schematic illustration of an embodiment of a multi-station processing tool 700.

FIG. 8 presents a schematic illustration of an embodiment of an inductively coupled plasma apparatus 800.

FIG. 9 presents a schematic illustration of an embodiment of a semiconductor process cluster tool architecture 900.

FIG. 10 depicts a cross-sectional schematic view of an example of a dry deposition apparatus 1000.

### DETAILED DESCRIPTION

Reference is made herein in detail to specific embodiments of the disclosure. Examples of the specific embodiments are illustrated in the accompanying drawings. While the disclosure will be described in conjunction with these specific embodiments, it will be understood that it is not intended to limit the disclosure to such specific embodiments. On the contrary, it is intended to cover alternatives, modifications, and equivalents as may be included within the spirit and scope of the disclosure. In the following description, numerous specific details are set forth in order to provide a thorough understanding of the present disclosure. The present disclosure may be practiced without some or all of these specific details. In other instances, well known process operations have not been described in detail so as to not unnecessarily obscure the present disclosure.

The present disclosure describes use of dilute aqueous acid for processing photoresists. In one embodiment, the disclosure encompasses a wet positive tone development solution for extreme ultraviolet lithography (EUVL)-patterned organotin oxide hydroxide photoresists (PRs) using dilute aqueous acid. In another embodiment, the disclosure encompasses using dilute aqueous acid to remove metal-based residues or particles (e.g., tin-based residues or tin-based particles) that can exist after developing such organotin oxide hydroxide PRs.

Current organotin PRs prepared by solution and chemical vapor deposition (CVD) methods are engineered for negative tone behavior due to radiation-induced condensation chemistries. These condensation mechanisms can yield a crosslinked material in radiation-exposed regions that is less soluble in organic solvent-based wet developers, as compared to the non-crosslinked unexposed regions-giving rise to negative tone patterning. Due to the tendency for exposed regions of organotin PRs to crosslink, positive tone development strategies of organotin PRs have been demonstrated in limited occasions, such as by using aqueous tetramethyl ammonium hydroxide (TMAH). Aqueous TMAH is also the industry standard for developing chemically-amplified resists (CARs).

In contrast, the present disclosure encompasses the use of dilute aqueous acids (e.g., hydrogen halides, as well as others described herein) as positive tone wet developers for organometallic PRs. Described herein is use of halogen-containing acidic aqueous wet developers, which yield greater selectivity than TMAH (aq) between exposed and unexposed regions in positive tone patterning. Furthermore, in some embodiments, use of aqueous acid can provide improvements in lithographic pattern quality in terms of exposure latitude (EL), dose-to-size (DtS), and/or linewidth roughness (LWR).

Without wishing to be limited by mechanism, an aqueous acid can be used to preferentially dissolve hydrophilic regions within a PR film. If radiation is used to release hydrophobic ligands from the PR film, then exposed regions can possess decreased hydrophobicity (or increased hydrophilicity) as compared to unexposed regions. In this way, exposed, hydrophilic regions can be selectively removed by use of an aqueous acid, thereby providing a positive tone developer.

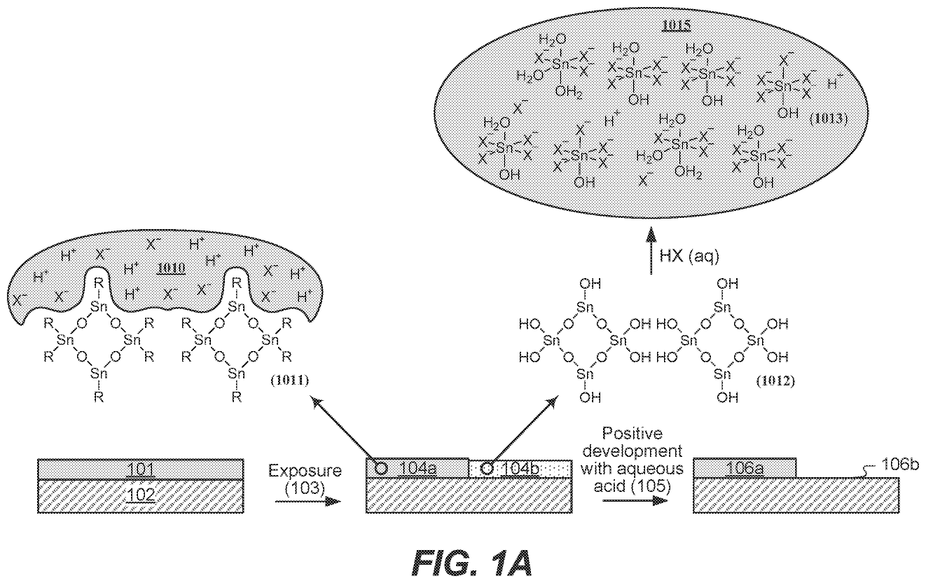

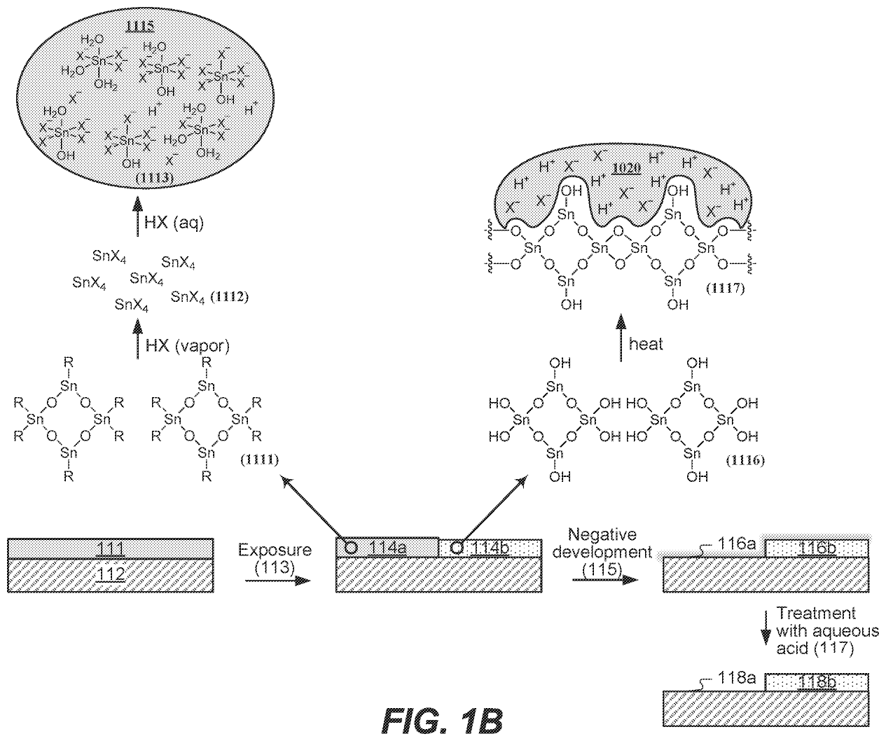

FIG. 1A provides a non-limiting example of using an aqueous acid for positive tone development. A PR film 101 can be deposited on a substrate 102. Such a film can be deposited by using wet or dry deposition processes, in which a metal-containing precursor (e.g., a tin-containing precursor, such as any described herein) is provided in proximity to a substrate. In one embodiment, the metal-containing precursor is deposited as a solution by using a liquid-based spin-on technique. In another embodiment, the metal-containing precursor is deposited in vapor form by using a dry technique (e.g., chemical vapor deposition). While FIG. 1A shows the metal-containing precursor being a tin-containing precursor, other metal atoms could be employed.

Upon exposure 103 to radiation, the film can include an unexposed region 104a and an exposed region 104b. In one embodiment, the unexposed region 104a includes a network of organotin complexes 1011, which can include Sn—O bonds, Sn—R bonds, and labile R ligands.

In particular embodiments, R is an organic group that can be cleaved upon exposure to radiation.

In some embodiments, the film includes EUV labile R groups attached to metal (M) centers in which EUV exposed regions can then include cleaved moieties, such as M-H and/or M-OH bonds, that can be more readily developed or removed by use of an aqueous acid. In this way, development selectivity can be tuned to provide a positive tone resist.

Radiation exposure can provide additional Sn—O crosslinking within exposed regions, as well as release of hydrophobic R groups that are present on the tin-based precursor. Thus, the exposed region 104b includes tin oxide hydroxide complexes 1012, which can include Sn—O bonds and Sn—OH bonds. For the most part, R ligands are not present within exposed regions. Of course, minimal amounts of R could be present within exposed regions but to a lesser extent than within unexposed regions.

To further enhance the hydrophobicity difference between exposed and unexposed regions, precursors having bulky and/or hydrophobic R ligands can be selected. For instance, as isopropyl is more hydrophobic than methyl, use of isopropyl as R could provide a greater hydrophobicity difference between exposed and unexposed region. Other examples of hydrophobic R groups are described herein, such as optionally substituted C₂₋₆ groups, as well as branched forms thereof. In particular embodiments, R groups can be optionally substituted, such as with halo (e.g., in which R can be haloalkyl).

Upon exposure to an aqueous acid, the exposed and unexposed regions can act differently based on the hydrophobicity difference that is present between these regions. For instance, the unexposed region 104a includes organotin complexes 1011 that have retained their organic, hydrophobic R ligands. The presence of such hydrophobic ligands slows down penetration of the aqueous acidic phase 1010 into the unexposed region. As can be seen, the organotin complexes 1011 are resistant to dissolution by an aqueous acidic phase 1010 including halide ions (X⁻) and hydrogen ions (H⁺). However, the exposed region 104b includes tin oxide hydroxide complexes 1012 that readily form soluble species 1013 within the aqueous phase 1015. In this way, the process provides positive tone development 105 by using an aqueous acid that preferentially dissolves exposed (and hydrophilic) regions.

The developed film (or pattern) can then include maintained (unexposed) regions 106a and removed (exposed) regions 106b. Optionally, development can include or be followed by a prewetting step (e.g., by use of an aqueous solvent, such as any described herein), a rinse step (e.g., by use of an aqueous solvent, such as any described herein), and/or a drying step. Acidic development (with or without a rinse operation) can be repeated an n number of times, in which n is 1, 2, 3, 4, 5, or more.

As described herein, use of a halogen-containing aqueous acid as a developer provided no detectable levels of residual halide species by energy-dispersive X-ray spectroscopy (EDX) and x-ray photoelectron spectroscopy (XPS) analyses. As such, these dilute aqueous acid solutions could also be used to remove unwanted residual volatile metal halide species from substrates that were dry developed for negative tone patterning.

Taken together, the present disclosure encompasses wet processes that employ an aqueous acid. In some embodiments, the process is a wet development process that yields positive-tone patterning of organotin oxide hydroxide PR materials using a dilute aqueous acid (e.g., dilute aqueous hydrogen chloride (HCl), hydrogen bromide (HBr), or hydrogen iodide (HI)). In particular embodiments, the process does not yield residual volatile halide species on developed surfaces.

In other embodiments, the process is a wet development process using a dilute aqueous acids that does not require high-temperature processing operation(s) (e.g., a post-exposure bake (PEB), as described herein). Without wishing to be limited by mechanism, avoiding such an operation can minimize opportunities for nonuniformity, particles, and/or contamination issues to arise. In other embodiments, avoiding such an operation can reduce process complexity.

In yet other embodiments, the process includes a post-application bake (PAB) prior to development. For example, a process can include conducting a PAB operation to increase hydrophobicity of the unexposed region(s), as further described herein. Use of PAB may be beneficial with particular developers. For instance, use of PAB can include use of an aqueous developer (e.g., including TMAH). In another instance, while PAB is employed, PEB can be avoided.

When used as a developer, an aqueous acid could provide certain advantages. In one embodiment, a dilute aqueous acid developer can offer advantages over current aqueous TMAH developers based off of ionic size and formation of water-soluble tin halide complexes. Without wishing to be limited by mechanism, the hydrophobicity difference between exposed and unexposed materials can be leveraged by maximizing the difference in polarity of the solvent and the solutes in the solution. For instance, TMAH is a large organic molecule and that is less polar than inorganic ions. Unprotonated TMAH may have some possibility to penetrate and dissolve into the hydrophobic part of the unexposed material. Inorganic halide ions and tin halide complex ions typically have smaller size and higher charge density and, thus, are more likely to remain within the aqueous solution.

In some embodiments, the aqueous acid is a dilute aqueous acid. For instance, use of dilute aqueous acid still provided removal of exposed regions. Non-limiting concentrations for dilute solutions can include from about 0.1% (v/v) to 1% (v/v) of an acid (e.g., a halogen-containing acid, as well as other acids described herein) within a solvent (e.g., water). In some non-limiting instances, potential enhancements in selectivity can include further dilution of an acid concentration (e.g., characterized by a decrease in concentration of H⁺), while increasing halide concentration (e.g., characterized by an increase in concentration of X⁻). Such an increase in halide concentration can be provided by using halide salts (e.g., ammonium halide).

Furthermore, also described herein are processes in which the hydrophobic character of unexposed organotin PR is further amplified at the surface. For example, a process can include conducting a PAB operation to increase hydrophobicity of the unexposed region(s). In another example, a process can include performing an organic-rich deposition step at the end of the film deposition process. Such an organic-rich deposition can provide a hydrophobic capping layer or a gradient film having increasingly hydrophobic groups (e.g., increased carbon content) towards the top of the film. Organic-rich deposition can employ any useful precursor or hydrocarbyl-substituted capping agent having an organic R group. Examples of hydrophobic R groups are described herein, such as optionally substituted C₂₋₆ groups, including ethyl (Et), n-propyl (n-Pr), isopropyl (i-Pr), cyclopropyl, n-butyl (n-Bu), isobutyl (i-Bu), s-butyl (s-Bu), t-butyl (t-Bu), cyclobutyl, n-pentyl, isopentyl, s-pentyl, neopentyl, hexyl, and the like. In other embodiments, the metal-containing precursor can include one, two, three, or more hydrophobic R groups attached to the metal atom (e.g., the tin atom). Further examples of precursors and capping agents (e.g., capping agents to provide organic moieties) are described herein.

When employed, a capping layer provides a barrier to aqueous acid from dissolving unexposed regions of the PR layer. The capping layer can be any useful thickness (e.g., any thickness described herein, including from about 0.1 nm to about 5 nm, such as from about 0.1 nm to 0.5 nm, 0.1 nm to 1 nm, 0.1 nm to 3 nm, 0.3 nm to 0.5 nm, 0.3 nm to 1 nm, 0.3 nm to 3 nm, 0.3 nm to 5 nm, 0.5 nm to 1 nm, 0.5 nm to 3 nm, 0.5 nm to 5 nm, 0.8 nm to 1 nm, 0.8 nm to 3 nm, 0.8 nm to 5 nm, 1 nm to 3 nm, 1 nm to 5 nm, or 3 nm to 5 nm).

When employed, a gradient film can include a vertical gradient characterized by a change in hydrophobicity. In one embodiment, the vertical gradient includes a decrease in carbon content, in which a bottom portion of the film in proximity to the substrate has a lower carbon content than a top portion of the film.

FIG. 1B provides a non-limiting example of using an aqueous acid for removing residual metal species after negative tone development. A PR film 111 can be deposited on a substrate 112. Such a film can be deposited by using wet or dry deposition processes, in which a metal-containing precursor (e.g., a tin-containing precursor, such as any described herein) is provided in proximity to a substrate. In one embodiment, the metal-containing precursor is deposited as a solution by using a liquid-based spin-on technique. In another embodiment, the metal-containing precursor is deposited in vapor form by using a dry technique (e.g., chemical vapor deposition). While FIG. 1B shows the metal-containing precursor being a tin-containing precursor, other metal atoms could be employed.

Upon exposure 113 to radiation, the film can include an unexposed region 114a and an exposed region 114b. In one embodiment, the unexposed region 114a includes a network of organotin complexes 1111, which can include Sn—O bonds, Sn—R bonds, and labile R ligands. The exposed region 114b includes tin oxide hydroxide complexes 1116, which can include Sn—O bonds and Sn—OH bonds. For the most part, R ligands are not present within exposed regions. Of course, minimal amounts of R could be present within exposed regions but to a lesser extent than within unexposed regions.

The film can then be developed, such as by use of development to remove unexposed regions. In FIG. 1B, the unexposed region 114a includes organotin complexes 1111 that can be developed in the presence of acidic vapor (HX, in which X is a halogen) to provide volatile tin halide species 1112. Yet other development conditions include any described herein, including dry development that is followed with optional plasma treatment.

The exposed region 1116 can optionally be treated, such as by way of a post-exposure bake (PEB) operation to further harden the film and provide a dense, crosslinked network 1117 of tin oxide hydroxide. Such dense networks can be resistant to dissolution with aqueous acid, particularly if dilute aqueous acid is employed. In this way, the process provides negative tone development 115 by using a developer that preferentially removes unexposed (or less crosslinked) regions. The developed film (or pattern) can then include maintained (exposed) regions 116b and removed (unexposed) regions 116a.

Upon exposure 117 to an aqueous acid, residual metal halide species (if present on regions 116a/116b) can be dissolved. For instance, the unexposed region 116a can include residual tin halide species 1112 that may remain after development. The aqueous acidic phase 1115 having halide ions (X⁻) and hydrogen ions (H⁺) can react with the tin halide species 1112 to form soluble species 1113 within the aqueous phase 1115. In this way, the process provides further treatment of a developed PR film by using an aqueous acid that dissolves residual species or particles that could remain after a negative tone process, thereby providing a first treated region 118a (or a treated, exposed region) and a second treated region 118b (or a treated, unexposed region)

Optionally, acid treatment can include or be followed by a prewetting step (e.g., by use of an aqueous solvent, such as any described herein), a rinse step (e.g., by use of an aqueous solvent, such as any described herein), and/or a drying step. Acid treatment (with or without a rinse operation) can be repeated an n number of times, in which n is 1, 2, 3, 4, 5, or more.

Thus, in some embodiments, the process is a wet treatment process using a dilute aqueous acids that removes residual metal halide species (e.g., tin halide species) or particles that can be generated after a development process (e.g., after a dry development processes).

In certain instances, the PR film can be co-deposited with one or more reactants. Such reactants could contribute to the hydrophobicity difference between exposed or unexposed regions. Alternatively, such reactants could contribute to crosslinking differences between hardened, exposed regions and hardened, unexposed regions. Non-limiting reactants include carbon dioxide (CO₂), which can be used during deposition to form organometallic carbonate films having a metal carbonate (M-CO₃) bond.

In other instance, the PR film (e.g., after development and/or treatment) can be further processed. Such processing can include any useful operation, such as one or more of a rinse operation, a hardening operation, a post-development bake (PDB) operation, and the like. In some embodiments, a rinse operation can be performed to remove reagents (e.g., acid), residual species, particles, particulates, or other contaminants from the substrate. In some embodiments, a hardening operation can be performed to provide a hardened resist film including metal-oxygen-metal (M-O-M) bonds, which are more resistant to developing or etching.

Various steps, operations, and apparatuses for such patterning and developing steps include those useful for lithography processes, as well as any described herein. In one instance, the lithography process includes use of extreme ultraviolet (EUV) lithography.

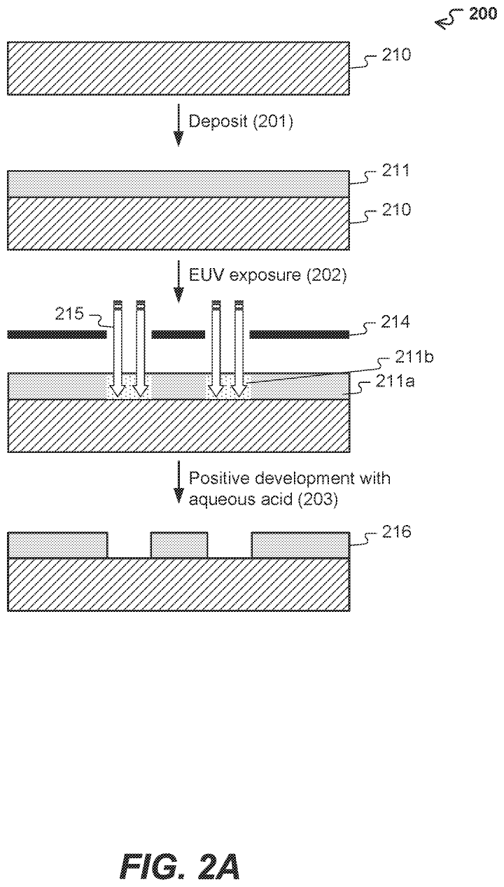

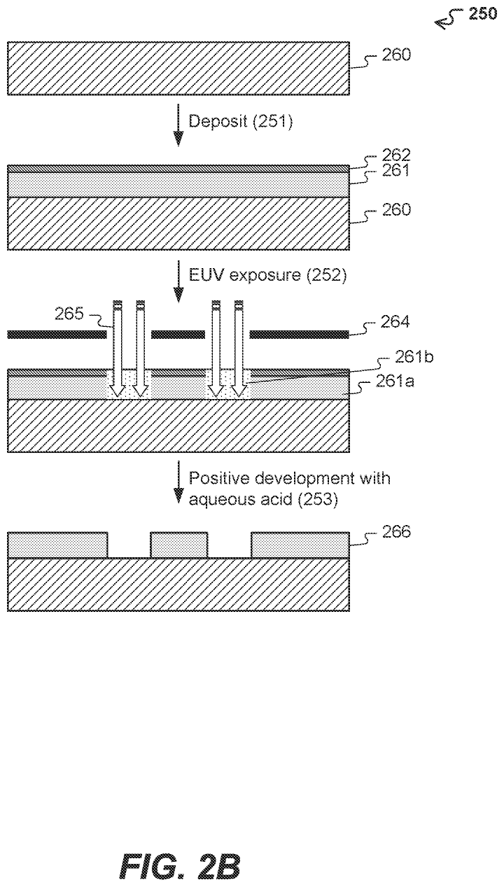

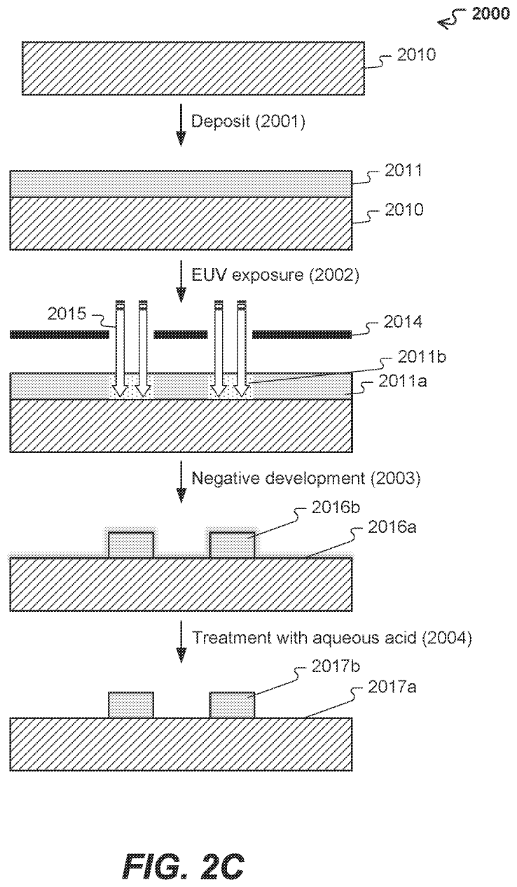

For instance, FIG. 2A provides an exemplary method 200 to provide a positive tone resist, in which EUV exposed regions can be removed. As can be seen, the method 200 includes depositing 201 a film 211 on the top surface of the substrate 210. As described herein, the film includes an EUV-sensitive material.

The method 200 can further include patterning the film by an EUV exposure 202. EUV exposure can include, e.g., an exposure having a wavelength in the range of about 10 nm to about 20 nm in a vacuum ambient (e.g., about 13.5 nm in a vacuum ambient). Patterning can include use of a mask 214 having EUV transparent regions and EUV opaque regions, in which EUV beams 215 are transmitted through the EUV transparent region, into the film 211. In this manner, the film includes EUV unexposed regions 211a and EUV exposed regions 211b.

An additional step includes developing 203 the film, thereby selectively removing the EUV exposed regions 211b and maintaining the EUV unexposed regions 211a, which in turn provides a pattern or a patterned film 216. The developing operation can include any described herein that includes an aqueous acid.

The method can include further steps to provide a stack having a capping layer. Accordingly, FIG. 2B provides an exemplary method 250 to provide a positive tone resist, in which EUV exposed regions can be removed. As can be seen, the method 250 includes depositing 251 a film 261 on the top surface of the substrate 260, and then depositing a capping layer 262 on a top surface of the film 261. As described herein, the film includes an EUV-sensitive material.

The method 250 can further include patterning the film by an EUV exposure 252. Patterning can include use of a mask 264 having EUV transparent regions and EUV opaque regions, in which EUV beams 265 are transmitted through the EUV transparent region, through the capping layer 262 and then into the film 261. In this manner, the film includes EUV unexposed regions 261a and EUV exposed regions 261b.

An additional step includes developing 253 the film, thereby selectively removing the EUV exposed regions 261b and maintaining the EUV unexposed regions 261a, which in turn provides a pattern or a patterned film 266. The developing operation can include any described herein that includes an aqueous acid. In some embodiments, the developing operation also removes the capping layer. In other embodiments, the method further includes conducts a stripping step to remove the capping layer.

The stripping and developing steps can conducted under the same or different conditions, such as any described herein for a development process (e.g., a wet development process). In one embodiment, both the stripping and developing steps can include use of an aqueous acid. In another embodiment, stripping of the capping layer includes use of halide chemistry (e.g., HBr chemistry) in a gas phase, and developing of the film includes use of aqueous acid. Additional development process conditions are described herein.

In addition to positive tone development processes, an aqueous acid can be employed in conjunction with negative tone development process. For instance, FIG. 2C provides an exemplary method 2000 to provide a negative tone resist, in which EUV exposed regions are retained and EUV unexposed regions can be removed.

As can be seen, the method 2000 includes depositing 2001 a film 2011 on the top surface of the substrate 2010. As described herein, the film includes an EUV-sensitive material.

The method 2000 can further include patterning the film by an EUV exposure 2002. Patterning can include use of a mask 2014 having EUV transparent regions and EUV opaque regions, in which EUV beams 2015 are transmitted through the EUV transparent region, into the film 2011. In this manner, the film includes EUV unexposed regions 2011a and EUV exposed regions 2011b.

An additional step includes developing 2003 the film, thereby selectively removing the EUV unexposed regions 2011a and maintaining the EUV exposed regions 2011b, which in turn provides a pattern or a patterned film having maintained (exposed) regions 2016b and removed (unexposed) regions 2016a. The developing operation can include any described herein that provides negative tone development (e.g., dry development).

After development, the maintained regions 2016b and/or removed regions 2016a can include residual metal halide species or metal-containing particles. To remove such species or particles, the method 2000 can further include treating 2004 the patterned film with an aqueous acid, thereby providing a first treated region 2017a (or a treated, unexposed region) and a second treated region 2017b (or a treated, exposed region). Optionally, treatment of the aqueous acid can include or be followed by a prewetting step (e.g., by use of an aqueous solvent, such as any described herein), a rinse step (e.g., by use of an aqueous solvent, such as any described herein), and/or a drying step. Acid treatment (with or without a rinse operation) can be repeated an n number of times, in which n is 1, 2, 3, 4, 5, or more.

Optionally (e.g., after development, before acid treatment, or after acid treatment), the method can further hardening an exposed film, a developed film, or a patterned film (e.g., to provide a resist mask). Hardening steps can include any useful process to further crosslink or react the EUV unexposed regions or EUV exposed regions. In one embodiments, hardening is performed to further crosslink or react the EUV exposed regions (e.g., in negatively developed films that can be treated with an acid, thereby providing exposed regions within the final pattern). In other embodiments, hardening is performed to crosslink or react the EUV unexposed regions (e.g., in exposed films that can be developed with an acid, thereby providing a positively developed film having unexposed regions within the final pattern to provide a mask). Exemplary hardening steps can include exposing to plasma, annealing, thermal baking, or combinations thereof that can be useful for a post development baking (PDB) step. In particular embodiments, hardening can include exposure to vacuum ultraviolet (VUV), optionally in the presence of an O₂, Ar, He, or CO₂ plasma environment; or thermal annealing (e.g., at a temperature of about 180° C. to about 240° C.), optionally in the presence of an air ambient environment or atomic oxygen or in the presence of an ozone/O₂ ambient environment.

In one embodiment, the hardened or densified film is provided by annealing in the absence of an oxygen (O)-containing gas. In some instances, annealing can include heating to a temperature at or above about 190° C. In some embodiments, annealing can be conducted under vacuum, in the presence of an inert gas (e.g., nitrogen gas (N₂), argon gas (Ar), or other non-oxidizing gas), or in the presence of an oxygen (O)-free gas, i.e., a gas free of oxygen atoms. Non-limiting examples of oxygen-free gas include O₂-free gas or H₂O-free gas. The inert gas can include one gas or a combination of inert gases. In some embodiments, a non-oxidizing gas is a gas having less than 1% of an oxygen (O)-containing gas (e.g., less than 1% of an O₂ gas). Gases can be employed at atmosphere pressure or lower.

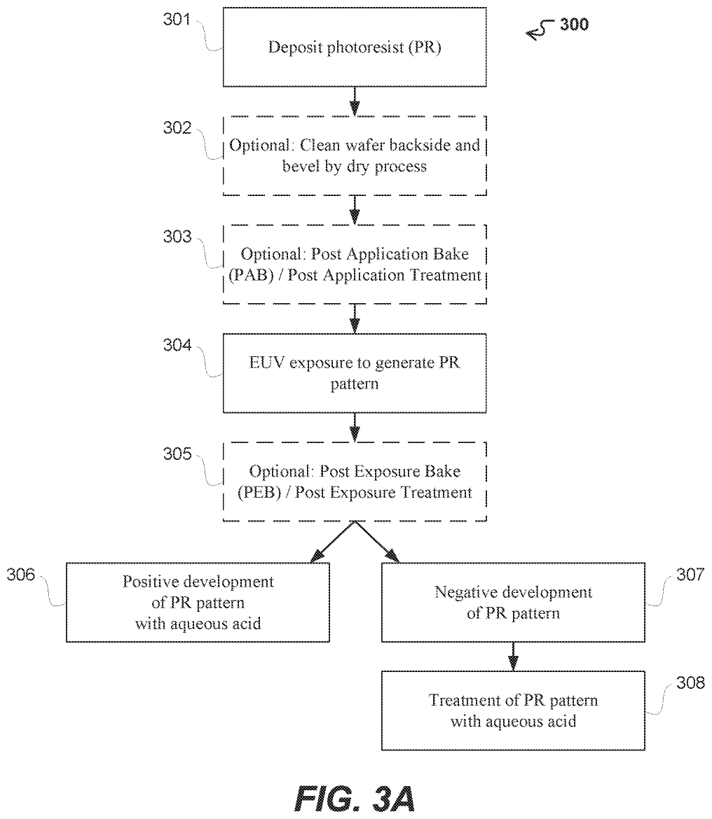

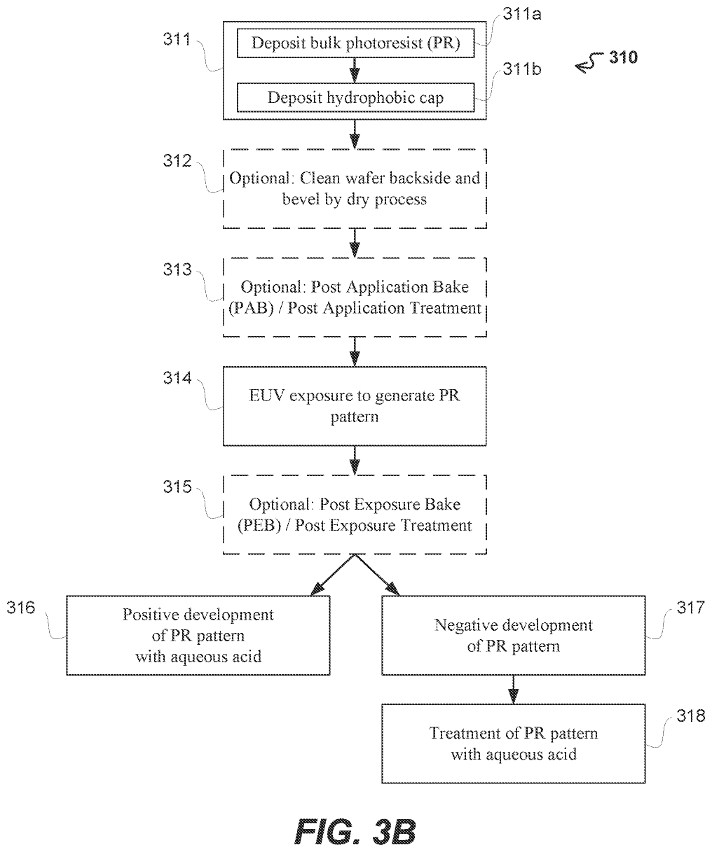

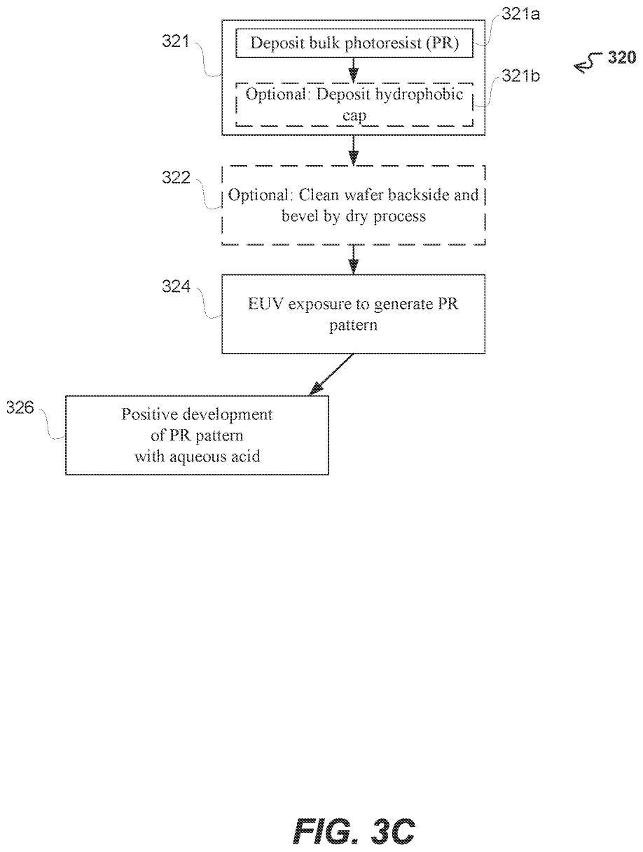

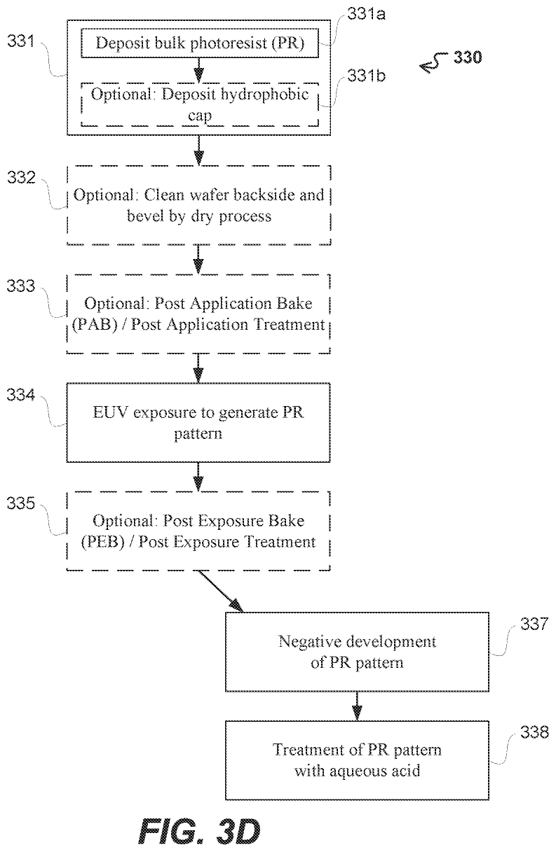

FIG. 3A provides a flow chart of an exemplary method 300 having various operations, including optional operations. Optional steps may be conducted to further modulate, modify, or treat the EUV-sensitive film(s) and/or substrate in any method herein.

As can be seen, in operation 301, a film is deposited employing a precursor with an optional counter-reactant to provide a photoresist (PR). In optional operation 302, the backside surface or bevel of the substrate can be cleaned, and/or an edge bead of the photoresist that was deposited in the prior step can be removed. Such cleaning or removing steps can be useful for removing particles that may be present after depositing a photoresist layer. The removing step can include processing the wafer with a wet metal oxide (MeOx) edge bead removal (EBR) step.

In optional operation 303, post-application bake (PAB) or another post-application treatment can be performed. Such treatment can improve etch resistance of unexposed material to aqueous or non-aqueous solution. In one instance, such treatment can enhance the hydrophobicity difference (or contrast) between unexposed and exposed regions, thus the PAB operation is conducted. In another instance, such treatment can reduce the hydrophobicity difference (or contrast) between unexposed and exposed regions, thus the PAB operation is not conducted. In yet another instance, use of PAB removes residual moisture from the layer to form a hardened resist film. The PAB can involve some combination of thermal treatment, chemical exposure, and/or moisture to increase the EUV sensitivity of the film, thereby reducing the EUV dose to develop a pattern in the film. In particular embodiments, the PAB step is conducted at a temperature greater than about 100° C. or at a temperature of from about 100° C. to about 200° C. or from about 100° C. to about 250° C. In other embodiments, the PAB step is conducted at a temperature from about 190° C. to about 350° C. in the absence of an O-containing gas. In another instance, post-application treatment includes exposing the film to an inert gas or CO₂, which can optionally include cooling or heating. Use of an inert gas can provide metal-oxygen-metal species, and use of CO₂ can provide metal carbonate species within the film.

In operation 304, the film is exposed to EUV radiation to develop a pattern. Generally, the EUV exposure causes a change in the chemical composition of the film, creating a contrast in etch selectivity that can be used to remove a portion of the film. Such a contrast can provide a positive tone resist, as described herein. EUV exposure can include, e.g., an exposure having a wavelength in the range of about 10 nm to about 20 nm in a vacuum ambient (e.g., about 13.5 nm in a vacuum ambient).

Operation 305 is an optional post-exposure bake (PEB) of the exposed film, thereby further removing residual moisture, promoting chemical condensation within the film, or increasing contrast in etch selectivity of the exposed film; or post-treating the film in any useful manner. In one instance, such treatment can reduce the hydrophobicity difference (or contrast) between unexposed and exposed regions, thus the PEB operation is not conducted. In another instance, the exposed film can be thermally treated (e.g., at a low temperature and/or optionally in the presence of various chemical species) to promote reactivity within the EUV exposed or unexposed portions of the resist upon exposure to a stripping agent or a positive tone developer (e.g., a halide-based aqueous acid, such as HCl, HBr, HI, or combinations thereof). In another instance, the exposed film can be thermally treated (e.g., at a low temperature) to further crosslink ligands within the EUV unexposed portions of the resist, thereby providing EUV exposed portions that can be selectively removed upon exposure to a stripping agent (e.g., a positive tone developer). In yet another instance, PEB is omitted.

Next, the PR pattern can be developed by way of positive tone development or negative tone development. In operation 306, the PR pattern is developed by way of positive development in the presence of an aqueous acid. In various embodiments of development, the exposed regions are removed (to provide a pattern within a positive tone resist). These steps may be wet processes using one or more developers or developing solutions, followed by an optional rinse operation (e.g., with deionized water or another solvent) or an optional dry operation (e.g., with air or under inert conditions with optional heat). In particular embodiments, the development step is a wet process applied to a tin-based film.

In operation 307, the PR pattern is developed by way of negative development. In various embodiments of development, the exposed regions are retained (to provide a pattern within a negative tone resist). These steps may be dry processes (e.g., any described herein) or wet processes using one or more developers or developing solutions, followed by an optional rinse (e.g., with deionized water or another solvent). In particular embodiments, the development step is a wet process applied to a tin-based film. In other embodiments, the development step is a dry process applied to a tin-based film.

After negative development, operation 308 can be performed to treat the PR pattern with an aqueous acid. These steps may be wet processes using one or more aqueous acid solutions, followed by an optional rinse operation (e.g., with deionized water or another solvent) or an optional dry operation (e.g., with air or under inert conditions with optional heat). Such treatment can be a wet process applied to developed, tin-based film to remove residual species or particles that can be present after development.

Methods can include deposition of a hydrophobic capping layer. FIG. 3B provides a flow chart of an exemplary method 310 having various operations, including optional operations. As can be seen, in operation 311, a film and a hydrophobic capping layer are deposited. In particular, operation 311a includes employing a precursor with an optional counter-reactant to provide a bulk photoresist (PR). Operation 311b includes employing a precursor (e.g., a second precursor different than that employed in operation 311a) with an optional counter-reactant to provide a hydrophobic capping layer.

The method includes various optional operations, which have been described with respect to FIG. 3A. Similarly, exemplary method 310 in FIG. 3B can include optional operation 312 for cleaning the backside surface or bevel of the substrate and/or removing an edge bead of the photoresist that was deposited in the prior step; optional operation 313 for PAB or another post-application treatment; and optional operation 315 for PEB or another post-exposure treatment.

In operation 314, the film is exposed to EUV radiation to develop a pattern. Next, the PR pattern can be developed by way of positive tone development in operation 316 or negative tone development in operation 317. After negative development, operation 318 can be performed to treat the PR pattern with an aqueous acid to remove residual species present after development.

In particular embodiments, PAB and PEB are avoided, especially for positive tone processes. FIG. 3C provides a flow chart of an exemplary method 320 having various operations, including optional operations. As can be seen, in operation 321, a film and an optional hydrophobic capping layer are deposited. In particular, operation 321a includes employing a precursor with an optional counter-reactant to provide a bulk photoresist (PR). Optional operation 321b includes employing a precursor (e.g., a second precursor different than that employed in operation 321a) with an optional counter-reactant to provide an optional hydrophobic capping layer.

The method further includes optional operation 322 for cleaning the backside surface or bevel of the substrate and/or removing an edge bead of the photoresist that was deposited in the prior step.

In operation 324, the film is exposed to EUV radiation to develop a pattern. Next, the PR pattern can be developed by way of positive tone development in operation 326 in the presence of an aqueous acid.

In other embodiments, PAB and PEB may (or may not) be performed in a negative tone process. Without wishing to be limited by mechanism, the negative process described herein employs an aqueous acid for solubilization of residual metal halide species that can be present after development (e.g., dry development). In this post-development use of aqueous acid, maintaining hydrophobicity contrast for wet development may not be critical to achieve etch selectivity. As can be seen, FIG. 3D provides a flow chart of an exemplary method 330 that provides a negative tone process. In operation 331, a film and an optional hydrophobic capping layer are deposited. In particular, operation 331a includes employing a precursor with an optional counter-reactant to provide a bulk photoresist (PR). Optional operation 331b includes employing a precursor (e.g., a second precursor different than that employed in operation 331a) with an optional counter-reactant to provide an optional hydrophobic capping layer.

The method includes various optional operations, which have been described with respect to FIG. 3A. Similarly, exemplary method 330 in FIG. 3D can include optional operation 332 for cleaning the backside surface or bevel of the substrate and/or removing an edge bead of the photoresist that was deposited in the prior step; optional operation 333 for PAB or another post-application treatment; and optional operation 335 for PEB or another post-exposure treatment.

In operation 334, the film is exposed to EUV radiation to develop a pattern. Next, the PR pattern can be developed by way of negative tone development in operation 337 to provide a PR pattern. Non-limiting development processes for negative tone resists are described herein. After negative development, operation 338 can be performed to treat the PR pattern with an aqueous acid to remove residual species present after development.

In any embodiment herein, the method can include (e.g., after development) rinsing, further hardening, and/or baking the patterned film, thereby providing a resist mask disposed on a top surface of the substrate. Hardening steps can include any useful process to further crosslink or react the EUV unexposed or exposed regions, such as steps of exposing to plasma (e.g., O₂, O₃, Ar, He, or CO₂ plasma), exposing to ultraviolet radiation, annealing (e.g., at a temperature of about 180° C. to about 240° C.), thermal baking, or combinations thereof that can be useful for a post-development baking (PDB) step.

Any useful type of chemistry can be employed during the depositing, patterning, and/or developing steps. Such steps may be based on dry processes employing chemistry in a gaseous phase or wet processes employing chemistry in a wet phase. Various embodiments include combining dry operations of film formation by vapor deposition and (EUV) lithographic photopatterning with wet development operations.

Accordingly, it has been demonstrated that high performance, dry- or wet-deposited EUV photoresist material can be effectively patterned to give positive tone images or to provide treated negative tone images. This could also enable the application of aqueous acids, including dilute aqueous acids, to provide novel process flows involving EUV PR films.

### Aqueous Acid

The aqueous acid can be provided in any useful concentration, including a concentration of about 0.1% (v/v) to 10% (v/v) of an acid in a solvent (e.g., an aqueous solvent, such as water). In other embodiments, the concentration is about 0.1% (v/v) to 2% (v/v) of an acid in a solvent

Non-limiting acids include a halogen-containing acid, such as those including fluorine, chlorine, bromine, and/or iodine. Other halogen-containing acids include a hydrogen halide, including hydrogen fluoride (HF), hydrogen chloride (HCl), hydrogen bromide (HBr), hydrogen iodide (HI), and combinations thereof. Yet other acids include an inorganic acid (e.g., phosphoric acid, sulfuric acid, and the like) or an organic acid (e.g., formic acid, acetic acid, trifluoroacetic acid, oxalic acid, citric acid, and the like).

In some embodiments, the acid is a phosphorus oxoacid (e.g., phosphoric acid), a sulfur oxoacid (e.g., sulfuric acid), or a carboxylic acid (e.g., formic acid, acetic acid, trifluoroacetic acid, oxalic acid, citric acid, and combinations thereof).

Use of an aqueous acid can include any exposure time, such as from about 10 seconds to 3 minutes (e.g., from about 10 seconds to 60 seconds). Such exposure times can be any sufficient for development by removing exposed regions or for treatment by removing residual metal halide species.

### Precursors

The layers and films herein may include an element (e.g., a metal atom or a non-metal atom) having a high photoabsorption cross-section, such as equal to or greater than 1×10⁷ cm²/mol. Such elements can be provided by depositing one or more precursor(s) to provide the imaging layer.

In some embodiments, the film is a radiation-sensitive film (e.g., an EUV-sensitive film). This film, in turn, can serve as an EUV resist, as further described herein. In particular embodiments, the layer or film can include one or more ligands (e.g., EUV labile ligands) that can be removed, cleaved, or cross-linked by radiation (e.g., EUV or DUV radiation).

The precursor can provide a patternable film that is sensitive to radiation (or a patterning radiation-sensitive film or a photopattemable film). Such radiation can include EUV radiation, DUV radiation, or UV radiation that is provided by irradiating through a patterned mask, thereby being a patterned radiation. The film itself can be altered by being exposed to such radiation, such that the film is radiation-sensitive or photosensitive. In particular embodiments, the precursor is an organometallic compound, which includes at least one metal center.

The precursor can have any useful number and type of ligand(s). In some embodiments, the ligand can be characterized by its ability to react in the presence of a counter-reactant, or in the presence of patterned radiation. For instance, the precursor can include a ligand that reacts with a counter-reactant, which can introduce linkages between metal centers (e.g., an —O— linkage). In another instance, the precursor can include a ligand that eliminates in the presence of patterned radiation. Such an EUV labile ligand can include branched or linear alkyl groups having a beta-hydrogen, as well as any described herein for R in formula (I) or (II). In one embodiment, the precursor is a capping agent having two, three, or more hydrophobic ligands (e.g., organic ligands, including C₂₋₆ optionally substituted alkyl, alkenyl, or alkynyl).

Other EUV labile ligands include alkyl, alkenyl, or alkynyl groups, which can be branched or linear. Yet other EUV labile ligands include aryl groups, such as those having one, two, or three rings. Such alkyl, alkenyl, alkynyl, and aryl groups can be substituted with one or more halos (e.g., one or more fluoro). Non-limiting labile ligands include optionally substituted C₁₋₁₂ alkyl, optionally substituted C₂₋₁₂ alkenyl, optionally substituted C₂₋₁₂ alkynyl, optionally substituted C₁₋₁₂ haloalkyl, optionally substituted C₂₋₁₂ haloalkenyl, optionally substituted C₂₋₁₂ haloalkynyl, optionally substituted aryl, or optionally substituted haloaryl.

The precursor can be any useful metal-containing precursor, such as an organometallic agent, a metal halide, or a capping agent (e.g., as described herein). In a non-limiting instance, the precursor includes a structure having formula (I):

MₐR_{b} (I),

wherein:
M is a metal or an atom having a high EUV absorption cross-section;
each R is, independently, H, halo, optionally substituted alkyl, optionally substituted cycloalkyl, optionally substituted cycloalkenyl, optionally substituted alkenyl, optionally substituted alkynyl, optionally substituted alkoxy, optionally substituted alkanoyloxy, optionally substituted aryl, optionally substituted amino, optionally substituted bis(trialkylsilyl)amino, optionally substituted trialkylsilyl, oxo, an anionic ligand, a neutral ligand, or a multidentate ligand;
a≥1; and b≥1.

In another non-limiting instance, the precursor includes a structure having formula (II):

MₐR_{b}L_{c} (II),

wherein:
M is a metal or an atom having a high EUV absorption cross-section;
each R is, independently, halo, optionally substituted alkyl, optionally substituted aryl, optionally substituted amino, optionally substituted alkoxy, or L;
each L is, independently, a ligand, an anionic ligand, a neutral ligand, a multidentate ligand, ion, or other moiety that is reactive with a counter-reactant, in which R and L with M, taken together, can optionally form a heterocyclyl group or in which R and L, taken together, can optionally form a heterocyclyl group;
a≥1; b≥1; and c≥1.

In some embodiments, each ligand within the precursor can be one that is reactive with a counter-reactant. In one instance, the precursor includes a structure having formula (II), in which each R is, independently, L. In another instance, the precursor includes a structure having formula (IIa):

MₐL_{c} (IIa),
wherein:
M is a metal or an atom having a high EUV absorption cross-section;
each L is, independently, a ligand, ion, or other moiety that is reactive with a counter-reactant, in which two L, taken together, can optionally form a heterocyclyl group;
a≥1; and c≥1.
   In particular embodiments of formula (IIa), a is 1. In further embodiments, c is 2, 3, or 4.

For any formula herein, M can be a metal or a metalloid or an atom with a high patterning radiation-absorption cross-section (e.g., an EUV absorption cross-section that is equal to or greater than 1×10⁷ cm²/mol). In some embodiments, M is tin (Sn), bismuth (Bi), tellurium (Te), cesium (Cs), antimony (Sb), indium (In), molybdenum (Mo), hafnium (H), iodine (I), zirconium (Zr), iron (Fe), cobalt (Co), nickel (Ni), copper (Cu), zinc (Zn), silver (Ag), platinum (Pt), and lead (Pb). In further embodiments, M is Sn, a is 1, and c is 4 in formula (I), (II), or (Ha). In other embodiments, M is Sn, a is 1, and c is 2 in formula (I), (II), or (Ha). In particular embodiments, M is Sn(II) (e.g., in formula (I), (II), or (Ha)), thereby providing a precursor that is a Sn(II)-based compound. In other embodiments, M is Sn(IV)(e.g., in formula (I), (II), or (Ha)), thereby providing a precursor that is a Sn(IV)-based compound. In particular embodiments, the precursor includes iodine (e.g., as in periodate).

For any formula herein, each R is, independently, H, halo, optionally substituted alkyl, optionally substituted cycloalkyl, optionally substituted cycloalkenyl, optionally substituted alkenyl, optionally substituted alkynyl, optionally substituted alkoxy (e.g., —OR¹, in which R¹ can be optionally substituted alkyl), optionally substituted alkanoyloxy, optionally substituted aryl, optionally substituted amino, optionally substituted bis(trialkylsilyl)amino, optionally substituted trialkylsilyl, oxo, an anionic ligand (e.g., oxido, chlorido, hydrido, acetate, iminodiacetate, propanoate, butanoate, benzoate, etc.), a neutral ligand, or a multidentate ligand.

In some embodiments, the optionally substituted amino is —NR¹R², in which each R¹ and R² is, independently, H or alkyl; or in which R¹ and R², taken together with the nitrogen atom to which each are attached, form a heterocyclyl group, as defined herein. In other embodiments, the optionally substituted bis(trialkylsilyl)amino is —N(SiR¹R²R³)₂, in which each R¹, R², and R³ is, independently, optionally substituted alkyl. In yet other embodiments, the optionally substituted trialkylsilyl is —SiR¹R²R³, in which each R¹, R², and R³ is, independently, optionally substituted alkyl.

In other embodiments, the formula includes a first R (or first L) that is —NR¹R² and a second R (or second L) that is —NR¹R², in which each R¹ and R² is, independently, H or optionally substituted alkyl; or in which R¹ from a first R (or first L) and R¹ from a second R (or second L), taken together with the nitrogen atom and the metal atom to which each are attached, form a heterocyclyl group, as defined herein. In yet other embodiments, the formula includes a first R that is —OR¹ and a second R that is —OR¹, in which each R¹ is, independently, H or optionally substituted alkyl; or in which R¹ from a first R and R¹ from a second R, taken together with the oxygen atom and the metal atom to which each are attached, form a heterocyclyl group, as defined herein.

In some embodiments, at least one of R or L (e.g., in formula (I), (II), or (Ha)) is optionally substituted alkyl. Non-limiting alkyl groups include, e.g., CₙH₂ₙ₊₁, where n is 1, 2, 3, or greater, such as methyl, ethyl, n-propyl, isopropyl, n-butyl, isobutyl, s-butyl, or t-butyl. In various embodiments, R or L has at least one beta-hydrogen, beta-halogen, or beta-fluorine. In other embodiments, at least one of R or L is a halo-substituted alkyl (e.g., a fluoro-substituted alkyl).

In some embodiments, each R or L or at least one R or L (e.g., in formula (I), (II), or (IIa)) is halo. In particular, the precursor can be a metal halide. Non-limiting metal halides include SnBr₄, SnCl₄, SnI₄, and SbCl₃.

In some embodiments, each R or L or at least one R or L (e.g., in formula (I), (II), or (IIa)) can include a nitrogen atom. In particular embodiments, one or more R or L can be optionally substituted amino, an optionally substituted monoalkylamino (e.g., —NR¹H, in which R¹ is optionally substituted alkyl), an optionally substituted dialkylamino (e.g., —NR¹R², in which each R¹ and R² is, independently, optionally substituted alkyl), or optionally substituted bis(trialkylsilyl)amino. Non-limiting R and L substituents can include, e.g., —NMe₂, —NHMe, —NEt₂, —NHEt, —NMeEt, —N(t-Bu)-[CHCH₃]₂—N(t-Bu)-(tbba), —N(SiMe₃)₂, and —N(SiEt₃)₂.

In some embodiments, each R or L or at least one R or L (e.g., in formula (I), (II), or (IIa)) can include a silicon atom. In particular embodiments, one or more R or L can be optionally substituted trialkylsilyl or optionally substituted bis(trialkylsilyl)amino. Non-limiting R or L substituents can include, e.g., —SiMe₃, —SiEt₃, —N(SiMe₃)₂, and —N(SiEt₃)₂.

In some embodiments, each R or L or at least one R or L (e.g., in formula (I), (II), or (IIa)) can include an oxygen atom. In particular embodiments, one or more R or L can be optionally substituted alkoxy or optionally substituted alkanoyloxy. Non-limiting R or L substituents include, e.g., methoxy, ethoxy, isopropoxy (i-PrO), t-butoxy (t-BuO), acetate (—OC(O)—CH₃), and —O═C(CH₃)—CH═C(CH₃)—O— (acac).

Any formulas herein can include one or more neutral ligands. Non-limiting neutral ligands include an optionally substituted amine (e.g., NR₃ or R₂N-Ak-NR₂, in which each R can be, independently, H, optionally substituted alkyl, optionally substituted hydrocarbyl, or optionally substituted aryl, and Ak is optionally substituted alkylene), an optionally substituted phosphine (e.g., PR₃ or R₂P-Ak-PR₂, in which each R can be, independently, H, optionally substituted alkyl, optionally substituted hydrocarbyl, or optionally substituted aryl, and Ak is optionally substituted alkylene), an optionally substituted ether (e.g., OR₂, in which each R can be, independently, H, optionally substituted alkyl, optionally substituted hydrocarbyl, or optionally substituted aryl), an optionally substituted alkyl, an optionally substituted alkene, an optionally substituted alkyne, an optionally substituted benzene, oxo, or carbon monoxide.

Any formulas herein can include one or more multidentate (e.g., bidentate) ligands. Non-limiting multidentate ligand include a diketonate (e.g., acetylacetonate (acac) or —OC(R¹)-Ak-(R¹)CO— or —OC(R¹)—C(R²)—(R¹)CO—), a bidentate chelating dinitrogen (e.g., —N(R¹)-Ak-N(R¹)— or —N(R³)—CR⁴—CR²═N(R¹)—), an aromatic (e.g., —Ar—), an amidinate (e.g., —N(R¹)—C(R²)—N(R¹)—), an aminoalkoxide (e.g., —N(R¹)-Ak-O— or —N(R¹)₂-Ak-O—), a diazadienyl (e.g., —N(R¹)—C(R²)—C(R²)—N(R¹)—), a cyclopentadienyl, a pyrazolate, an optionally substituted heterocyclyl, an optionally substituted alkylene, or an optionally substituted heteroalkylene. In particular embodiments, each R¹ is, independently, H, optionally substituted alkyl, optionally substituted haloalkyl, or optionally substituted aryl; each R² is, independently, H or optionally substituted alkyl; R³ and R⁴, taken together, forms an optionally substituted heterocyclyl; Ak is optionally substituted alkylene; and Ar is optionally substituted arylene.

In particular embodiments, the precursor includes tin. In some embodiments, the tin precursor includes SnR or SnR₂ or SnR₄ or R₃SnSnR₃, wherein each R is, independently, H, halo, optionally substituted C₁₋₁₂ alkyl, optionally substituted C₁₋₁₂ alkoxy, optionally substituted amino (e.g., —NR¹R²), optionally substituted C₂₋₁₂ alkenyl, optionally substituted C₂₋₁₂ alkynyl, optionally substituted C₃₋₈ cycloalkyl, optionally substituted aryl, cyclopentadienyl, optionally substituted bis(trialkylsilyl)amino (e.g., —N(SiR¹R²R³)₂), optionally substituted alkanoyloxy (e.g., acetate), a diketonate (e.g., —OC(R¹)-Ak-(R²)CO—), or a bidentate chelating dinitrogen (e.g., —N(R¹)-Ak-N(R¹)—). In particular embodiments, each R¹, R², and R³ is, independently, H or C₁₋₁₂ alkyl (e.g., methyl, ethyl, isopropyl, t-butyl, or neopentyl); and Ak is optionally substituted C₁₋₆ alkylene. In particular embodiments, each R is, independently, halo, optionally substituted C₁₋₁₂ alkoxy, optionally substituted amino, optionally substituted aryl, cyclopentadienyl, or a diketonate. Non-limiting tin precursors include SnF₂, SnH₄, SnBr₄, SnCl₄, SnI₄, tetramethyl tin (SnMe₄), tetraethyl tin (SnEt₄), trimethyl tin chloride (SnMe₃Cl), dimethyl tin dichloride (SnMe₂Cl₂), methyl tin trichloride (SnMeCl₃), tetraallyltin, tetravinyl tin, hexaphenyl ditin (IV) (Ph₃Sn—SnPh₃, in which Ph is phenyl), dibutyldiphenyltin (SnBu₂Ph₂), trimethyl(phenyl) tin (SnMe₃Ph), trimethyl(phenylethynyl) tin, tricyclohexyl tin hydride, tributyl tin hydride (SnBu₃H), dibutyltin diacetate (SnBu₂(CH₃COO)₂), tin(II) acetylacetonate (Sn(acac)₂), tributyltin ethoxide (SnBu₃(OEt)), dibutyltin dimethoxide (SnBu₂(OMe)₂), tributyltin methoxide (SnBu₃(OMe)), tin(IV) tert-butoxide (Sn(t-BuO)₄), n-butyltin tributoxide (Sn(n-Bu)(t-BuO)₃), tetrakis(dimethylamino)tin (Sn(NMe₂)₄), tetrakis(ethylmethylamino)tin (Sn(NMeEt)₄), tetrakis(diethylamino)tin(IV) (Sn(NEt₂)₄), (dimethylamino)trimethyl tin(IV) (Sn(Me)₃(NMe₂), Sn(i-Pr)(NMe₂)₃, Sn(n-Bu)(NMe₂)₃, Sn(s-Bu)(NMe₂)₃, Sn(i-BuXNMe₂)₃, Sn(t-Bu)(NMe₂)₃, Sn(t-Bu)₂(NMe₂)₂, Sn(t-Bu)(NEt₂)₃, Sn(tbba), Sn(II) (1,3-bis(1,1-dimethylethyl)-4,5-dimethyl-(4R,5R)-1,3,2-diazastannolidin-2-ylidene), or bis[bis(trimethylsilyl)amino]tin (Sn[N(SiMe₃)₂]₂).

In other embodiments, the precursor includes bismuth, such as in BiR₃, wherein each R is, independently, halo, optionally substituted C₁₋₁₂ alkyl, mono-C₁₋₁₂ alkylamino (e.g., —NR¹H), di-C₁₋₁₂ alkylamino (e.g., —NR¹R²), optionally substituted aryl, optionally substituted bis(trialkylsilyl)amino (e.g., —N(SiR¹R²R³)₂), or a diketonate (e.g., —OC(R⁴)-Ak-(R⁵)CO—). In particular embodiments, each R¹, R², and R³ is, independently, C₁₋₁₂ alkyl (e.g., methyl, ethyl, isopropyl, t-butyl, or neopentyl); and each R⁴ and R⁵ is, independently, H or optionally substituted C₁₋₁₂ alkyl (e.g., methyl, ethyl, isopropyl, t-butyl, or neopentyl). Non-limiting bismuth precursors include BiCl₃, BiMe₃, BiPh₃, Bi(NMe₂)₃, Bi[N(SiMe₃)₂]₃, and Bi(thd)₃, in which thd is 2,2,6,6-tetramethyl-3,5-heptanedionate.

In other embodiments, the precursor includes tellurium, such as TeR₂ or TeR₄, wherein each R is, independently, halo, optionally substituted C₁₋₁₂ alkyl (e.g., methyl, ethyl, isopropyl, t-butyl, and neopentyl), optionally substituted C₁₋₁₂ alkoxy, optionally substituted aryl, hydroxyl, oxo, or optionally substituted trialkylsilyl. Non-limiting tellurium precursors include dimethyl tellurium (TeMe₂), diethyl tellurium (TeEt₂), di(n-butyl) tellurium (Te(n-Bu)₂), di(isopropyl) tellurium (Te(i-Pr)₂), di(t-butyl) tellurium (Te(t-Bu)₂), t-butyl tellurium hydride (Te(t-Bu)(H)), Te(OEt)₄, bis(trimethylsilyl)tellurium (Te(SiMe₃)₂), and bis(triethylsilyl) tellurium (Te(SiEt₃)₂).

The precursor can include antimony, such as in SbR₃, wherein each R is, independently, halo, optionally substituted C₁₋₁₂ alkyl (e.g., methyl, ethyl, isopropyl, t-butyl, and neopentyl), optionally substituted C₁₋₁₂ alkoxy, or optionally substituted amino (e.g., —NR¹R², in which each R¹ and R² is, independently, H or optionally substituted C₁₋₁₂ alkyl). Non-limiting antimony precursors include SbCl₃, Sb(OEt)₃, Sb(On-Bu)₃, and Sb(NMe₂)₃.

Other precursors include indium precursors, such as in InR₃, wherein each R is, independently, halo, optionally substituted C₁₋₁₂ alkyl (e.g., methyl, ethyl, isopropyl, t-butyl, and neopentyl), or a diketonate (e.g., —OC(R⁴)-Ak-(R⁵)CO—, in which each R⁴ and R⁵ is, independently, H or C₁₋₁₂ alkyl). Non-limiting indium precursors include InCp, in which Cp is cyclopentadienyl, InCl₃, InMe₃, In(acac)₃, In(CF₃COCHCOCH₃)₃, and In(thd)₃.

The precursor can include iodine, such as RI, wherein R is iodo (I) or optionally substituted C₁₋₁₂ alkyl, or periodate. Non-limiting iodine precursors include iodine gas (I₂), diiodomethane (CH₂I₂), and periodate.

Yet other precursors and non-limiting substituents are described herein. For instance, precursors can be any having a structure of formulas (I), (II), and (Ha), as described above; or formulas (II), (IV), (V), (VI), (VII), or (VIII), as described below. Any of the substituents M, R, X, or L, as described herein, can be employed in any of formulas (I), (II), (Ha), (III), (IV), (V), (VI), (VII), or (VIII).

Various atoms present in the precursor and/or counter-reactant can be provided within a gradient film. In some embodiments of the techniques discussed herein, a non-limiting strategy that can further improve the hydrophobicity contrast within a PR film by creating a film in which the film composition is vertically graded, resulting in a depth-dependent hydrophobic character. In a homogenous PR, the hydrophobic character of the film is same throughout the bulk of the film and the top surface of the film. By increasing the hydrophobicity of the film at the top of the film relative to the bottom of the film (closer to the substrate), it becomes possible to more effectively avoid dissolution through the top surface of the film by an aqueous acid solution.

The strategy of engineering a vertical composition gradient in a PR film is particularly applicable to dry deposition methods, such as CVD and ALD, and can be realized by tuning the flow ratios between different reactants during deposition. The type of composition gradients that can be engineered include: the ratios between different R or L ligands for the precursor, use of different precursors having more hydrophobic R ligands, the percentages of counter-reactants that contain carbon-containing elements, and combinations of the above.

In addition, such compositional gradients can include a higher fraction of bulky, terminal substituents located at the top surface of the film. For example, in the case of Sn-based resists, the incorporation of tin precursors with two or more R groups is possible at the top surface, thereby presenting additional hydrophobic R groups at the top surface of the PR film.

In one embodiment, the gradient film can include a first concentration of carbon content in a top portion of the film (away from the substrate) and a second concentration of carbon content in a bottom portion of the film (closer to the substrate), in which the first and second concentration values are different. In one instance, the first concentration is greater than the second concentration. Non-limiting gradients include a linear gradient, an exponential gradient, a sigmoidal gradient, and the like. In particular embodiments, gradient density films of EUV-responsive organic moieties can yield more homogeneous film properties of EUV exposed areas at all depths in the film, which might improve development processes, improve EUV sensitivity, and/or improve patterning quality (e.g., having improved LWR and/or LER).

Such gradient films can be formed by using any precursors (e.g., tin or non-tin precursors) and/or counter-reactants described herein. Yet other films, methods, precursors, and other compounds are described in U.S. Provisional Pat. Appl. No. 62/909,430, filed Oct. 2, 2019, and International Appl No. PCT/US20/53856, filed Oct. 1, 2020, published as International Pub. No. WO 2021/067632, in which each is titled SUBSTRATE SURFACE MODIFICATION WITH HIGH EUV ABSORBERS FOR HIGH PERFORMANCE EUV PHOTORESISTS; and International Appl. No. PCT/US20/70172, filed Jun. 24, 2020, published as International Pub. No. WO 2020/264557, and titled PHOTORESIST WITH MULTIPLE PATTERNING RADIATION-ABSORBING ELEMENTS AND/OR VERTICAL COMPOSITION GRADIENT, the disclosures of which at least relating to the composition, deposition, and patterning of directly photopattemable metal oxide films to form EUV resist masks are incorporated by reference herein.

Various atoms present in the precursor and/or counter-reactant can be provided within a capping layer, which in turn is disposed on any useful layer or structure. The capping layer can be any useful thickness (e.g., any thickness described herein, including from about 0.1 nm to about 5 nm).

Furthermore, two or more different precursors can be employed within each layer (e.g., a film or a capping layer). For instance, two or more of any metal-containing precursors herein can be employed to form an alloy. In one non-limiting instance, tin telluride can be formed by employing tin precursor including an —NR₂ ligand with RTeH, RTeD, or TeR₂ precursors, in which R is an alkyl, particularly t-butyl or i-propyl. In another instance, a metal telluride can be formed by using a first precursor including an alkoxy or a halo ligand (e.g., SbCl₃) with a tellurium-containing precursor including a trialkylsilyl ligand (e.g., bis(trimethylsilyl)tellurium).

Yet other exemplary EUV-sensitive materials, as well as processing methods and apparatuses, are described in U.S. Pat. No. 9,996,004; Int. Pat. Pub. No. WO 2020/102085; and Int. Pat. Pub. No. WO 2019/217749, each of which is incorporated herein by reference in its entirety.

As described herein, the films, layers, and methods herein can be employed with any useful precursor. In some instances, the precursor includes a metal halide having the following formula (III):

MXₙ (III),

in which M is a metal, X is halo, and n is 2 to 4, depending on the selection of M. Exemplary metals for M include Sn, Te, Bi, or Sb. Exemplary metal halides include SnBr₄, SnCl₄, SnI₄, and SbCl₃.

Another non-limiting precursor includes a structure having formula (IV):

MRₙ (IV),

in which M is a metal; each R is independently H, an optionally substituted alkyl, amino (e.g., —NR₂, in which each R is independently alkyl), optionally substituted bis(trialkylsilyl) amino (e.g., —N(SiR₃)₂, in which each R is independently alkyl), or an optionally substituted trialkylsilyl (e.g., —SiR₃, in which each R is independently alkyl); and n is 2 to 4, depending on the selection of M. Exemplary metals for M include Sn, Te, Bi, or Sb. The alkyl group may be CₙH₂ₙ₊₁, where n is 1, 2, 3, or greater. Exemplary organometallic agents include SnMe₄, SnEt₄, TeRn, RTeR, t-butyl tellurium hydride (Te(t-Bu)(H)), dimethyl tellurium (TeMe₂), di(t-butyl) tellurium (Te(t-Bu)₂), di(isopropyl)tellurium (Te(i-Pr)₂), bis(trimethylsilyl)tellurium (Te(SiMe₃)₂), bis(triethylsilyl) tellurium (Te(SiEt₃)₂), tris(bis(trimethylsilyl)amido) bismuth (Bi[N(SiMe₃)₂]₃), Sb(NMe₂)₃, and the like.

Another non-limiting precursor can include a capping agent having the following formula (V):

MLₙ (V),

in which M is a metal; each L is independently an optionally substituted alkyl, amino (e.g., —NR¹R², in which each of R¹ and R² can be H or alkyl, such as any described herein), alkoxy (e.g., —OR, in which R is alkyl, such as any described herein), halo, or other organic substituent; and n is 2 to 4, depending on the selection of M. Exemplary metals for M include Sn, Te, Bi, or Sb. Exemplary ligands include dialkylamino (e.g., dimethylamino, methylethylamino, and diethylamino), alkoxy (e.g., t-butoxy and isopropoxy), halo (e.g., F, Cl, Br, and I), or other organic substituents (e.g., acetylacetone or N²,N³-di-tertbutyl-butane-2,3-diamino). Non-limiting capping agents include SnCl₄; SnI₄; Sn(NR₂)₄, wherein each of R is independently methyl or ethyl; or Sn(t-BuO)₄. In some embodiments, multiple types of ligands are present.

A precursor can include a hydrocarbyl-substituted capping agent having the following formula (VI):

RₙMXₘ (VI),

wherein M is a metal, R is a C₂₋₁₀ alkyl or substituted alkyl having a beta-hydrogen, and X is a suitable leaving group upon reaction with a hydroxyl group of the exposed hydroxyl groups. In various embodiments, n=1 to 3, and m=4−n, 3−n, or 2−n, so long asm>0 (or m≥1). For example, R may be t-butyl, t-pentyl, t-hexyl, cyclohexyl, isopropyl, isobutyl, sec-butyl, n-butyl, n-pentyl, n-hexyl, or derivatives thereof having a heteroatom substituent in the beta position. Suitable heteroatoms include halogen (F, Cl, Br, or I), or oxygen (—OH or —OR). X may be dialkylamino (e.g., dimethylamino, methylethylamino, or diethylamino), alkoxy (e.g., t-butoxy, isopropoxy), halo (e.g., F, Cl, Br, or I), or another organic ligand. Examples of hydrocarbyl-substituted capping agents include t-butyltris(dimethylamino)tin (Sn(t-Bu)(NMe₂)₃), n-butyltris(dimethylamino)tin (Sn(n-Bu)(Nme₂)₃), t-butyltris(diethylamino)tin (Sn(t-Bu)(Net₂)₃), di(t-butyl)di(dimethylamino)tin (Sn(t-Bu)₂(Nme₂)₂), sec-butyltris(dimethylamino)tin (Sn(s-Bu)(Nme₂)₃), n-pentyltris(dimethylamino)tin (Sn(n-pentyl)(Nme₂)₃), i-butyltris(dimethylamino) tin (Sn(i-Bu)(Nme₂)₃), i-propyltris(dimethylamino)tin (Sn(i-Pr)(Nme₂)₃), t-butyltris(t-butoxy)tin (Sn(t-Bu)(t-BuO)₃), n-butyl(tris(t-butoxy)tin (Sn(n-Bu)(t-BuO)₃), or isopropyltris(t-butoxy)tin (Sn(i-Pr)t-BuO)₃).

In various embodiments, a precursor includes at least one alkyl group on each metal atom that can survive the vapor-phase reaction, while other ligands or ions coordinated to the metal atom can be replaced by the counter-reactants. Accordingly, another non-limiting precursor includes an organometallic agent having the formula (VII):

MₐR_{b}L_{c} (VII),

in which M is a metal; R is an optionally substituted alkyl; L is a ligand, ion, or other moiety which is reactive with the counter-reactant; a≥1; b≥1; and c≥1. In particular embodiments, a=1, and b+c=4. In some embodiments, M is Sn, Te, Bi, or Sb. In particular embodiments, each L is independently amino (e.g., —NR¹R², in which each of R¹ and R² can be H or alkyl, such as any described herein), alkoxy (e.g., —OR, in which R is alkyl, such as any described herein), or halo (e.g., F, Cl, Br, or I). Exemplary agents include SnMe₃Cl, SnMe₂Cl₂, SnMeCl₃, SnMe(NMe₂)₃, SnMe₂(NMe₂)₂, SnMe₃(NMe₂), and the like.

In other embodiments, the non-limiting precursor includes an organometallic agent having the formula (VIII):

MₐL_{c} (VIII),

in which M is a metal; L is a ligand, ion, or other moiety which is reactive with the counter-reactant; a≥1; and c≥1. In particular embodiments, c=n−1, and n is 2, 3, or 4. In some embodiments, M is Sn, Te, Bi, or Sb. Counter-reactants preferably have the ability to replace the reactive moieties ligands or ions (e.g., L in formulas herein) so as to link at least two metal atoms via chemical bonding.

In any embodiment herein, R can bean optionally substituted alkyl (e.g., C₁₋₁₀ alkyl). In one embodiment, alkyl is substituted with one or more halo (e.g., halo-substituted C₁₋₁₀ alkyl, including one, two, three, four, or more halo, such as F, Cl, Br, or I). Exemplary R substituents include CₙH₂ₙ₊₁, preferably wherein n≥3; and CₙFₓH₍₂ₙ₊₁₋ₓ₎, wherein 2n+1≥x≥1. In various embodiments, R has at least one beta-hydrogen, beta-halogen, or beta-fluorine. For example, R may be selected from the group consisting of i-propyl, n-propyl, t-butyl, i-butyl, n-butyl, sec-butyl, n-pentyl, i-pentyl, t-pentyl, sec-pentyl, and mixtures thereof.

In any embodiment herein, L may be any moiety readily displaced by a counter-reactant to generate an M-OH moiety, such as a moiety selected from the group consisting of an amino (e.g., —NR¹R², in which each of R¹ and R² can be H or alkyl, such as any described herein), alkoxy (e.g., —OR, in which R is alkyl, such as any described herein), carboxylates, halo (e.g., F, Cl, Br, or I), and mixtures thereof.

Counter-reactants preferably have the ability to replace the reactive moieties, ligands, or ions (e.g., L in formulas herein) so as to link at least two metal atoms via chemical bonding. Exemplary counter-reactants include oxygen-containing counter-reactants, such as oxygen (O₂), ozone (O₃), water, peroxides (e.g., hydrogen peroxide), oxygen plasma, water plasma, alcohols, dihydroxy alcohols, polyhydroxy alcohols, fluorinated dihydroxy alcohol, fluorinated polyhydroxy alcohols, fluorinated glycols, formic acid, and other sources of hydroxyl moieties, as well as combinations thereof. In various embodiments, a counter-reactant reacts with the precursor by forming oxygen bridges between neighboring metal atoms. Other potential counter-reactants include hydrogen sulfide and hydrogen disulfide, which can crosslink metal atoms via sulfur bridges and bis(trimethylsilyl)tellurium, which can crosslink metal atoms via tellurium bridges. In addition, hydrogen iodide may be utilized to incorporate iodine into the film.

Yet other non-limiting counter-reactants include a chalcogenide precursor having the formula ZR₂, wherein: Z is sulfur, selenium, or tellurium; and each R is, independently, H, optionally substituted alkyl (e.g., methyl, ethyl, n-propyl, isopropyl, n-butyl, t-butyl, etc.), optionally substituted alkenyl, optionally substituted aryl, optionally substituted amino, optionally substituted alkoxy, or optionally substituted trialkylsilyl.

Exemplary organometallic agents include SnMeCl₃, (N²,N³-di-t-butyl-butane-2,3-diamido) tin(II) (Sn(tbba)), bis(bis(trimethylsilyl)amido) tin(II), tetrakis(dimethylamino) tin(IV) (Sn(NMe₂)₄), t-butyl tris(dimethylamino) tin (Sn(t-butyl)(NMe₂)₃), i-butyl tris(dimethylamino) tin (Sn(i-Bu)(NMe₂)₃), n-butyl tris(dimethylamino) tin (Sn(n-Bu)(NMe₂)₃), sec-butyl tris(dimethylamino) tin (Sn(s-BuxNMe₂)₃), i-propyl(tris)dimethylamino tin (Sn(i-PrXNMe₂)₃), n-propyl tris(diethylamino) tin (Sn(n-Pr)(NEt₂)₃), and analogous alkyl(tris)(t-butoxy) tin compounds, such as t-butyl tris(t-butoxy) tin (Sn(t-Bu)(t-BuO)₃). In some embodiments, the organometallic agents are partially fluorinated.

In some embodiments, patterning structure can include a surface layer or film comprising exposed hydroxyl groups or hydroxyl-terminated SnOₓ. Without limiting the mechanism, function or utility of present technology, it is believed that the hydroxyl-terminated SnOₓ layer may offer benefits such as improved adhesion of materials deposited on the surface of the substrate and enhanced absorption of EUV (or other radiation) during patterning. Sensitivity to EUV or other irradiation and resolution may be dependent on the properties of the SnOₓ layer, such as thickness, density and short-range charge transfer characteristics. In various embodiments, the SnOₓ layer has a thickness of from 0.1 nm to 20 nm, or from 0.2 nm to 10 nm, or from 0.5 nm to 5 nm.

In some embodiments, the hydroxyl-terminated SnOₓ layer is deposited on a surface of the substrate by vapor deposition. In such methods, the deposition comprises reacting Sn—Xₙ with an oxygen-containing counter-reactant, wherein X is a ligand such as dialkylamino, (e.g., dimethylamino, methylethylamino, and diethylamino), alcohol (e.g., t-butoxy, and isopropoxy), halogen (e.g., F, Cl, Br, and I), or other organic substituent (e.g., acetylacetone, N₂,N3-di-tertbutyl-butane-2,3-diamino). For example, Sn—X may be SnCl₄, SnI₄, or Sn(NR₂)₄ wherein R is methyl or ethyl, or Sn(t-BuO)₄. In some embodiments, multiple types of ligands are present. The oxygen-containing counter-reactant may be selected from the group consisting of water, hydrogen peroxide, formic acid, alcohols, oxygen, ozone, and combinations thereof.

Suitable vapor deposition processes include chemical vapor deposition (CVD), atomic layer deposition (ALD), plasma-enhanced chemical vapor deposition (PECVD), or plasma-enhanced atomic layer deposition (PEALD). In some embodiments, the deposition is ALD, in a cyclical process of depositing the Sn—Xₙ and depositing the oxygen-containing counter-reactant. In some embodiments, the deposition is CVD, by simultaneously flowing the Sn—Xe and the oxygen-containing counter-reactant. Materials and processes among those useful herein for depositing SnOₓ layers are described in Nazarov et al., Atomic Layer Deposition of Tin Dioxide Nanofilms: A Review, 40 Rev. Adv. Mater. Sci. 262 (2015). A SnOₓ substrate may be deposited by a CVD or ALD process, as described herein.

A surface activation operation may be used to activate the surface for future operations. For example, for a SiOx surface, a water or oxygen/hydrogen plasma may be used to create hydroxyl groups on the surface. For a carbon- or hydrocarbon-based surface, a water, hydrogen/oxygen or CO₂ plasma or ozone treatment may be used to create carboxylic acids/or hydroxyl groups. Such approaches can improve adhesion of resist features to the substrate, which might otherwise delaminate or lift off in the solvent used for development.

Adhesion may also be enhanced by inducing roughness in the substrate surface to increase the surface area available for interaction, as well as directly improve mechanical adhesion. For example, first a sputtering process using Ar or other non-reactive ion bombardment can be used to produce rough surfaces. Then, the surface can be terminated with a desired surface functionality as described above (e.g., hydroxyl and/or carboxylic acid groups). On carbon, a combination approach can be employed wherein a chemically reactive oxygen-containing plasma such as CO₂, O₂, H₂O (or mixtures of H₂ and O₂) can be used to etch away a thin layer of film with local non-uniformity and simultaneously terminate with —OH, —OOH, or —COOH groups. This may be done with or without bias. In conjunction with the surface modification strategies mentioned above, this approach could serve the dual purpose of surface roughening and chemical activation of the substrate surface, either for direct adhesion to an inorganic metal-oxide based resist or as an intermediate surface modification for further functionalization.

The patterning structure can include any useful substrate. For instance, an incoming wafer can be prepared with a substrate surface of a desired material, with the uppermost material being the layer into which the resist pattern is transferred. While the material selection may vary depending on integration, it is generally desired to select a material which can be etched with high selectivity to (i.e., much faster than) the EUV resist or imaging layer. In some embodiments, the substrate is a hardmask, which is used in lithographic etching of an underlying semiconductor material. The hardmask may comprise any of a variety of materials, including amorphous carbon (a-C), tin oxide (e.g., SnOₓ), silicon oxide (e.g., SiOₓ, including SiO₂), silicon oxynitride (e.g., SiOₓN_{y}), silicon oxycarbide (e.g., SiOₓC_{y}), silicon nitride (e.g., Si₃N₄), titanium oxide (e.g., TiO₂), titanium nitride (e.g., TiN), tungsten (e.g., W), doped carbon (e.g., W-doped C), tungsten oxide (e.g., WOₓ), hafnium oxide (e.g., HfO₂), zirconium oxide (e.g., ZrO₂), and aluminum oxide (e.g., Al₂O₃). Suitable substrate materials can include various carbon-based films (e.g., ashable hardmask (AHM), silicon-based films (e.g., SiOₓ, SiCₓ, SiOₓC_{y}, SiOₓN_{y}, SiOₓC_{y}N_{z}), a-Si:H, poly-Si, or SiN), or any other (generally sacrificial) film applied to facilitate the patterning process). For example, the substrate may preferably comprise SnOₓ, such as SnO₂. In various embodiments, the layer may be from 1 nm to 100 nm thick, or from 2 nm to 10 nm thick.

In various embodiments, the surface (e.g., of the substrate and/or the film) comprises exposed hydroxyl groups on its surface. In general, the surface may be any surface that comprises, or has been treated to produce, an exposed hydroxyl surface. Such hydroxyl groups may be formed on the surface by surface treatment of a substrate using oxygen plasma, water plasma, or ozone. In other embodiments, the surface of the film can be treated to provide exposed hydroxyl groups, upon which a capping layer can be applied. In various embodiments, the hydroxyl-terminated metal oxide layer has a thickness of from 0.1 nm to 20 nm, or from 0.2 nm to 10 nm, or from 0.5 nm to 5 nm.

The implementations disclosed herein describe deposition of a material on a substrate such as a wafer, substrate, or other work piece. The work piece may be of various shapes, sizes, and materials. In this application, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry can have a diameter of 200 mm, or 300 mm, or 450 mm. Unless otherwise stated, the processing details recited herein (e.g., flow rates, power levels, etc.) are relevant for processing 300 mm diameter substrates, or for treating chambers that are configured to process 300 mm diameter substrates, and can be scaled as appropriate for substrates or chambers of other sizes. In addition to semiconductor wafers, other work pieces that may be used implementations disclosed herein include various articles such as printed circuit boards and the like. The processes and apparatuses can be used in the fabrication of semiconductor devices, displays, and the like.

### Lithographic Processes

Patterning of thin films in semiconductor processing is often one step in the fabrication of semiconductors. Patterning involves lithography. In photolithography, such as 193 nm photolithography, patterns are printed by emitting photons from a photon source onto a mask and printing the pattern onto a photosensitive photoresist, thereby causing a chemical reaction in the photoresist that, after development, removes certain portions of the photoresist to form the pattern.

Advanced technology nodes (as defined by the International Technology Roadmap for Semiconductors)include nodes 22 nm, 16 nm, and beyond. In the 16 nm node, for example, the width of a via or line in a Damascene structure can be no greater than about 30 nm. Scaling of features on advanced semiconductor integrated circuits (ICs) and other devices is driving lithography to improve resolution.

Extreme ultraviolet (EUV) lithography can extend lithography technology by moving to smaller imaging source wavelengths than would be achievable with photolithography methods. EUV light sources at approximately 10-20 nm, or 11-14 nm wavelength, for example 13.5 nm wavelength, can be used for leading-edge lithography tools, also referred to as scanners. The EUV radiation is strongly absorbed in a wide range of solid and fluid materials including quartz and water vapor, and so operates in a vacuum.

Traditional organic chemically amplified resists (CAR) have a few drawbacks when used in EUV lithography, particularly low absorption coefficient in EUV region and acid diffusion of photo-activated chemical species. To overcome the low absorption coefficient, a relatively thick CAR film is necessary, but at the risk of pattern collapse. Moreover, the broad clearing radius during the acid diffusion process leads to relatively high line roughness in patterned CAR films. Quenchers may be used to reduce the acid diffusion radius, but at the cost of decreased sensitivity. As such, the lithographic performance of current CARs is generally unable to reach the desired EUV lithographic performance.

Directly photopattemable EUV resists containing metals and/or metal oxides mixed within organic components show promise in that they can enhance the EUV photon absorption and generate secondary electrons and/or show increased etch selectivity to an underlying film stack and device layers. Spin-on organometallic resists, such as are available from Inpria Corp., Corvallis, OR, have a substantially higher absorption coefficient than CARs and can be significantly thinner while still providing good etch resistance. Dry deposition of metal-organic based photopattemable EUV resists has also been described, for example in our prior International Application PCT/US19/31618, published as International Pub. No. WO 2019/217749, filed May 9, 2019, and titled METHODS FOR MAKING EUV PATTERNABLE HARD MASKS, the disclosure of which relating to the composition, dry deposition, and patterning of directly photopattemable metal-organic based metal oxide films to form EUV resist masks is incorporated by reference herein.

EUV lithography makes use of EUV resists, which may be polymer-based chemically amplified resists produced by liquid-based spin-on techniques or metal oxide-based resists produced by dry vapor-deposited techniques. Such EUV resists can include any EUV-sensitive film or material described herein. Lithographic methods can include patterning the resist, e.g., by exposure of the EUV resist with EUV radiation to form a photo pattern, followed by developing the pattern by removing a portion of the resist according to the photo pattern to form a mask.

It should also be understood that while the present disclosure relates to lithographic patterning techniques and materials exemplified by EUV lithography, it is also applicable to other next generation lithographic techniques. In addition to EUV, which includes the standard 13.5 nm EUV wavelength currently in use and development, the radiation sources most relevant to such lithography are DUV (deep-UV), which generally refers to use of 248 nm or 193 nm excimer laser sources, X-ray, which formally includes EUV at the lower energy range of the X-ray range, as well as e-beam, which can cover a wide energy range. Such methods include those where a substrate (e.g., optionally having exposed hydroxyl groups) is contacted with a precursor (e.g., any described herein) to form a metal oxide (e.g., a layer including a network of metal oxide bonds, which may include other non-metal and non-oxygen groups) film as the imaging/PR layer on the surface of the substrate. The specific methods may depend on the particular materials and applications used in the semiconductor substrate and ultimate semiconducting device. Thus, the methods described in this application are merely exemplary of the methods and materials that may be used in present technology. In some embodiments, lithography includes use of a radiation source having a wavelength that is between 10 nm and 400 nm.

Directly photopattemable EUV resists may be composed of or contain metals and/or metal oxides. The metals/metal oxides are highly promising in that they can enhance the EUV photon absorption and generate secondary electrons and/or show increased etch selectivity to an underlying film stack and device layers. Additional processes employed during lithography are described in detail below.

### Deposition Processes, Including Dry or Wet Deposition

As discussed above, the present disclosure provides methods for films on semiconductor substrates, which may be patterned using EUV or other next generation lithographic techniques. Methods include those where polymerized organometallic materials are produced in a vapor and deposited on a substrate. In some embodiments, dry deposition can employ any useful precursor (e.g., metal halides, capping agents, or organometallic agents described herein). In other embodiments, a spin-on formulation may be used. Deposition processes can include applying a EUV-sensitive material as a resist film or an EUV-sensitive film.

Such EUV-sensitive films comprise materials which, upon exposure to EUV, undergo changes, such as the loss of bulky pendant ligands bonded to metal atoms. If the unexposed region includes a dense M-O-M rich material, then EUV induced cleavage can provide intermediates that are more readily removed by positive tone developers.

Through EUV patterning, areas of the film are created that have altered physical or chemical properties relative to unexposed regions. These properties may be exploited in subsequent processing, such as to dissolve either unexposed or exposed regions or to selectively deposit materials on either the exposed or unexposed regions. In some embodiments, the unexposed film has a hydrophobic surface, and the exposed film has a hydrophilic surface (it being recognized that the hydrophilic properties of exposed and unexposed regions are relative to one another) under the conditions at which such subsequent processing is performed. For example, the removal of material may be performed by leveraging differences in chemical composition, density, and cross-linking of the film. Removal may be by wet processing or dry processing, as further described herein.

The thickness of the EUV-patternable film formed on the surface of the substrate may vary according to the surface characteristics, materials used, and processing conditions. In various embodiments, the film thickness may range from about 0.5 nm to about 100 nm. Preferably, the film has a sufficient thickness to absorb most of the EUV light under the conditions of EUV patterning. For example, the overall absorption of the resist film may be 30% or less (e.g., 10% or less, or 5% or less), so that the resist material at the bottom of the resist film is sufficiently exposed. In some embodiments, the film thickness is from 10 nm to 20 nm. Without limiting the mechanism, function, or utility of the present disclosure, it is believed that, the processes of the present disclosure can be applied to a wide variety of substrates. Moreover, as discussed above, the deposited films may closely conform to surface features, providing advantages in forming masks over substrates, such as substrates having underlying features, without “filling in” or otherwise planarizing such features.

The film may be composed of a metal oxide layer deposited in any useful manner. Such a metal oxide layer can be deposited or applied by using any EUV-sensitive material described herein, such as a precursor (e.g., metal-containing precursor, a metal halide, a capping agent, or an organometallic agent) in combination with a counter-reactant. In exemplary processes, a polymerized organometallic material is formed in vapor phase or in situ on the surface of the substrate in order to provide the metal oxide layer. The metal oxide layer may be employed as a film, an adhesion layer, or a capping layer.

Optionally, the metal oxide layer can include a hydroxyl-terminated metal oxide layer, which can be deposited by employing a capping agent (e.g., any described herein) with an oxygen-containing counter-reactant. Such a hydroxyl-terminated metal oxide layer can be employed, e.g., as an adhesion layer between two other layers, such as between the substrate and the film and/or between the photoresist layer and the capping layer.

Exemplary deposition techniques (e.g., for a film) include any described herein, such as ALD (e.g., thermal ALD and plasma-enhanced ALD), spin-coat deposition, PVD including PVD co-sputtering, CVD (e.g., PE-CVD or LP-CVD), sputter deposition, e-beam deposition including e-beam co-evaporation, etc., or a combination thereof, such as ALD with a CVD component, such as a discontinuous, ALD-like process in which precursors and counter-reactants are separated in either time or space.

Further description of precursors and methods for their deposition as EUV photoresist films applicable to this disclosure may be found in International Appl. No. PCT/US19/31618, published as International Pub. No. WO 2019/217749, filed May 9, 2019, and titled METHODS FOR MAKING EUV PATTERNABLE HARD MASKS. The thin films may include optional materials in addition to a precursor and a counter-reactant to modify the chemical or physical properties of the film, such as to modify the sensitivity of the film to EUV or enhancing etch resistance. Such optional materials may be introduced, such as by doping during vapor phase formation prior to deposition on the substrate, during deposition on the substrate, and/or after deposition of the film. In some embodiments, a gentle remote H₂ plasma may be introduced so as to replace some Sn-L bonds with Sn—H, for example, which can increase reactivity of the resist under EUV. In other embodiments, CO₂ may be introduced to replace some Sn—O bonds with Sn—CO₃ bonds, which can be more resistant to wet development.

In general, methods can include mixing a vapor stream of a precursor (e.g., a metal-containing precursor, such as an organometallic agent) with an optional vapor stream of a counter-reactant so as to form a polymerized organometallic material, and depositing the organometallic material onto the surface of the semiconductor substrate. In some embodiments, mixing the precursor and optional counter-reactant can form a polymerized organometallic material. As will be understood by one of ordinary skill in the art, the mixing and depositing aspects of the process may be concurrent, in a substantially continuous process.

In an exemplary continuous CVD process, two or more gas streams, in separate inlet paths, of sources of precursor and optional counter-reactant are introduced to the deposition chamber of a CVD apparatus, where they mix and react in the gas phase, to form agglomerated polymeric materials (e.g., via metal-oxygen-metal bond formation) or a film on the substrate. Gas streams may be introduced, for example, using separate injection inlets or a dual-plenum showerhead. The apparatus is configured so that the streams of precursor and optional counter-reactant are mixed in the chamber, allowing the precursor and optional counter-reactant to react to form a polymerized organometallic material or a film (e.g., a metal oxide coating or agglomerated polymeric materials, such as via metal-oxygen-metal bond formation).

For depositing metal oxide, the CVD process is generally conducted at reduced pressures, such as from 0.1 Torr to 10 Torr. In some embodiments, the process is conducted at pressures from 1 Torr to 2 Torr. The temperature of the substrate is preferably below the temperature of the reactant streams. For example, the substrate temperature may be from 0° C. to 250° C., or from ambient temperature (e.g., 23° C.) to 150° C.

For depositing agglomerated polymeric materials, the CVD process is generally conducted at reduced pressures, such as from 10 mTorr to 10 Torr. In some embodiments, the process is conducted at from 0.5 to 2 Torr. The temperature of the substrate is preferably at or below the temperature of the reactant streams. For example, the substrate temperature may be from 0° C. to 250° C., or from ambient temperature (e.g., 23° C.) to 150° C. In various processes, deposition of the polymerized organometallic material on the substrate occurs at rates inversely proportional to surface temperature. Without limiting the mechanism, function or utility of present technology, it is believed that the product from such vapor-phase reaction becomes heavier in molecular weight as metal atoms are crosslinked by counter-reactants, and is then condensed or otherwise deposited onto the substrate. In various embodiments, the steric hindrance of the bulky alkyl groups further prevents the formation of densely packed network and produces low density films having increased porosity.

A potential advantage of using dry deposition methods is ease of tuning the composition of the film as it grows. In a CVD process, this may be accomplished by changing the relative flows of a first precursor and a second precursor during deposition. Deposition may occur between 30° C. and 200° C. at pressures between 0.01 Torr to 100 Torr, but more generally between about 0.1 Torr and 10 Torr.

A film (e.g., a metal oxide coating or agglomerated polymeric materials, such as via metal-oxygen-metal bond formation) may also be deposited by an ALD process. For example, the precursor(s) and optional counter-reactant are introduced at separate times, representing an ALD cycle. The precursors react on the surface, forming up to a monolayer of material at a time for each cycle. This may allow for excellent control over the uniformity of film thickness across the surface. The ALD process is generally conducted at reduced pressures, such as from 0.1 Torr to 10 Torr. In some embodiments, the process is conducted from 1 Torr to 2 Torr. The substrate temperature may be from 0° C. to 250° C., or from ambient temperature (e.g., 23° C.) to 150° C. The process may be a thermal process or, preferably, a plasma-assisted deposition.

Any of the deposition methods herein can be modified to allow for use of two or more different precursors. In one embodiment, the precursors can include the same metal but different ligands. In another embodiment, the precursors can include different metal groups. In one non-limiting instance, alternating flows of various volatile precursors can provide a mixed metal-containing layer, such as use of a metal alkoxide precursor having a first metal (e.g., Sn) with a silyl-based precursor having a different second metal (e.g., Te).

Processes herein can be used to achieve a surface modification. In some iterations, a vapor of the precursor may be passed over the wafer. The wafer may be heated to provide thermal energy for the reaction to proceed. In some iterations, the heating can be between about 50° C. to about 250° C. In some cases, pulses of the precursor may be used, separated by pump and/or purging steps. For instance, a first precursor may be pulsed between pulses of a second precursor pulses resulting in ALD or ALD-like growth. In other cases, both precursors may be flowed at the same time. Examples of elements useful for surface modification include I, F, Sn, Bi, Sb, Te, and oxides or alloys of these compounds.

The processes herein can be used to deposit a thin metal oxide or metal by ALD or CVD. Examples include tin oxide (SnOx), bismuth oxide (BiOx), and Te. Following deposition, the film may be capped with an alkyl substituted precursor of the form MₐR_{b}L_{c}, as described elsewhere herein. A counter-reactant may be used to better remove the ligands, and multiple cycles may be repeated to ensure complete saturation of the substrate surface. The surface can then ready for the EUV-sensitive film to be deposited. One possible method is to produce a thin film of SnOx. Possible chemistries include growth of SnO₂ by cycling tetrakis(dimethylamino)tin and a counter-reactant such as water or O₂ plasma. After the growth, a capping agent could be used. For example, isopropyltris(dimethylamino)tin vapor may be flown over the surface.

Deposition processes can be employed on any useful surface. As referred to herein, the “surface” is a surface onto which a film of the present technology is to be deposited or that is to be exposed to EUV during processing. Such a surface can be present on a substrate (e.g., upon which a film is to be deposited) or on a film (e.g., upon which a capping layer can be deposited).

Any useful substrate can be employed, including any material construct suitable for lithographic processing, particularly for the production of integrated circuits and other semiconducting devices. In some embodiments, substrates are silicon wafers. Substrates may be silicon wafers upon which features have been created (“underlying topographical features”), having an irregular surface topography.

Such underlying topographical features may include regions in which material has been removed (e.g., by etching) or regions in which materials have been added (e.g., by deposition) during processing prior to conducting a method of this technology. Such prior processing may include methods of this technology or other processing methods in an iterative process by which two or more layers of features are formed on the substrate. Without limiting the mechanism, function, or utility of the present technology, it is believed that, in some embodiments, methods of the present technology offer advantages, such as conformance of the films of the present technology to underlying features without “filling in” or otherwise planarizing such features and the ability to deposit films on a wide variety of material surfaces.

In some embodiments, the substrate is a hard mask, which is used in lithographic etching of an underlying semiconductor material. The hard mask may comprise any of a variety of materials, including amorphous carbon (a-C), tin oxide (e.g., SnOₓ), silicon oxide (e.g., SiO₂), silicon oxynitride (e.g., SiOₓN_{y}), silicon oxycarbide (e.g., SiOₓC_{y}), silicon nitride (e.g., Si₃N₄), titanium oxide (e.g., TiO₂), titanium nitride (e.g., TiN), tungsten (e.g., W), doped carbon (e.g., W-doped C), tungsten oxide (e.g., WOₓ), hafnium oxide (e.g., HfO₂), zirconium oxide (e.g., ZrO₂), and aluminum oxide (e.g., Al₂O₃). For example, the substrate may preferably comprise SnOₓ, such as SnO₂. In various embodiments, the layer may be from 1 nm to 100 nm thick, or from 2 nm to 10 nm thick.

In some non-limiting embodiments, a substrate comprises an underlayer. An underlayer may be deposited on a hard mask or other layer and is generally underneath an imaging layer (or film), as described herein. An underlayer may be used to improve the sensitivity of a PR, increase EUV absorptivity, and/or increase the patterning performance of the PR In cases where there are device features present on the substrate to be patterned which create significant topography, another important function of the underlayer can be to overcoat and planarize the existing topography so that the subsequent patterning step may be performed on a flat surface with all areas of the pattern in focus. For such applications, the underlayer (or at least one of multiple underlayers) may be applied using spin-coating techniques. When the PR material being employed possesses a significant inorganic component, for example it exhibits a predominately metal oxide framework, the underlayer may advantageously be a carbon-based film, applied either by spin-coating or by dry vacuum-based deposition processes. The layer may include various ashable hard mask (AHM) films with carbon- and hydrogen-based compositions and may be doped with additional elements, such as tungsten, boron, nitrogen, or fluorine.

In various embodiments, the surface (e.g., of the substrate and/or the film) comprises exposed hydroxyl groups on its surface. In general, the surface may be any surface that comprises, or has been treated to produce, an exposed hydroxyl surface. Such hydroxyl groups may be formed on the surface by surface treatment of a substrate using oxygen plasma, water plasma, or ozone. In other embodiments, the surface of the film can be treated to provide exposed hydroxyl groups, upon which a capping layer can be applied. In various embodiments, the hydroxyl-terminated metal oxide layer has a thickness of from 0.1 nm to 20 nm, or from 0.2 nm to 10 nm, or from 0.5 nm to 5 nm.

### EUV Exposure Processes

EUV exposure of the film can provide EUV exposed regions having activated reactive centers including a metal atom (M), which are produced by EUV-mediated cleavage events. Such reactive centers can include dangling metal bonds, M-H groups, cleaved M-ligand groups, dimerized M-M bonds, or M-O-M bridges.

EUV exposure can have a wavelength in the range of about 10 nm to about 20 nm in a vacuum ambient, such as a wavelength of from 10 nm to 15 nm, e.g., 13.5 nm. In particular, patterning can provide EUV exposed regions and EUV unexposed regions to form a pattern.

The present technology can include patterning using EUV, as well as DUV or e-beam. In such patterning, the radiation is focused on one or more regions of the imaging layer. The exposure can be performed such that imaging layer film comprises one or more regions that are not exposed to the radiation. The resulting imaging layer may comprise a plurality of exposed and unexposed regions, creating a pattern consistent with the creation of transistor or other features of a semiconductor device, formed by addition or removal of material from the substrate in subsequent processing of the substrate. EUV, DUV and e-beam radiation methods and equipment among useful herein include methods and equipment known in the art.

In some EUV lithography techniques, an organic hard mask (e.g., an ashable hard mask of PECVD amorphous hydrogenated carbon) is patterned using a photoresist process. During photoresist exposure, EUV radiation is absorbed in the resist and in the substrate below, producing highly energetic photoelectrons (e.g., about 100 eV) and in turn a cascade of low-energy secondary electrons (e.g., about 10 eV) that diffuse laterally by several nanometers. These electrons increase the extent of chemical reactions in the resist which increases its EUV dose sensitivity. However, a secondary electron pattern that is random in nature is superimposed on the optical image. This unwanted secondary electron exposure results in loss of resolution, observable line edge roughness (LER) and linewidth variation in the patterned resist. These defects are replicated in the material to be patterned during subsequent pattern transfer etching.

A vacuum-integrated metal hard mask process and related vacuum-integrated hardware that combines film formation (deposition/condensation) and optical lithography with the result of greatly improved EUV lithography (EUVL) performance—e.g., reduced line edge roughness—is disclosed herein.

In various embodiments described herein, a deposition (e.g., condensation) process (e.g., ALD or MOCVD carried out in a PECVD tool, such as the Lam Vector®) can be used to form a thin film of a metal-containing film, such a photosensitive metal salt or metal-containing organic compound (organometallic compound), with a strong absorption in the EUV (e.g., at wavelengths on the order of 10 nm to 20 nm), for example at the wavelength of the EUVL light source (e.g., 13.5 nm=91.8 eV). This film photo-decomposes upon EUV exposure and forms a metal mask that is the pattern transfer layer during subsequent etching (e.g., in a conductor etch tool, such as the Lam 2300® Kiyo®).

Following deposition, the EUV-patternable thin film is patterned by exposure to a beam of EUV light, in some instances under relatively high vacuum. For EUV exposure, the metal-containing film can then be deposited in a chamber integrated with a lithography platform (e.g., a wafer stepper such as the TWINSCAN NXE: 3300B® platform supplied by ASML of Veldhoven, NL) and transferred under vacuum so as not to react before exposure. Integration with the lithography tool is facilitated by the fact that EUVL also requires a greatly reduced pressure given the strong optical absorption of the incident photons by ambient gases such as H₂O, O₂, etc. In other embodiments, the photosensitive metal film deposition and EUV exposure may be conducted in the same chamber.

### Development Processes, Including Wet or Dry Development

EUV exposed or unexposed regions can be removed by any useful development process. In one embodiment, the EUV exposed region can have activated reactive centers, such as dangling metal bonds, M-H groups, or dimerized M-M bonds. In other embodiments, EUV exposed regions are removed by use of wet development.

In particular embodiments, a wet development process is used to remove EUV exposed regions to provide a positive tone photoresist.

Exemplary, non-limiting wet development can include use of a developer (e.g., an aqueous acidic developer, a non-aqueous acidic developer, or an acid developer in an organic solvent) that includes a halide (e.g., HF, HCl, or HBr), an organic acid (e.g., formic acid, acetic acid, oxalic acid, or citric acid), or an organohalide compound (e.g., such as an organofluorine compound, including trifluoroacetic acid; an organochlorine compound; an organobromine compound, or an organoiodine compound); or use of an organic developer, such as a ketone (e.g., 2-heptanone, cyclohexanone, or acetone), an ester (e.g., γ-butyrolactone or ethyl 3-ethoxypropionate (EEP)), an alcohol (e.g., isopropyl alcohol (IPA)), or an ether, such as a glycol ether (e.g., propylene glycol methyl ether (PGME) or propylene glycol methyl ether acetate (PGMEA)), as well as combinations thereof. Other acids (e.g., aqueous acids) are described herein.

Other development methodologies can include use of an aqueous developer, a non-aqueous developer, an alkaline developer (e.g., an aqueous alkaline developer or a non-aqueous alkaline developer), such as those including ammonium, e.g., ammonium hydroxide ([NH₄]⁺[OH]⁻); ammonium-based ionic liquids, e.g., tetramethylammonium hydroxide (TMAH), tetraethylammonium hydroxide (TEAH), tetrapropylammonium hydroxide (TPAH), tetrabutylammonium hydroxide (TBAH), or other quaternary alkylammonium hydroxides; an organoamine, such as mono-, di-, and tri-organoamines (e.g., dimethylamine, diethylamine, ethylenediamine, triethylenetetramine); or an alkanolamine, such as monoethanolamine, diethanolamine, triethanolamine, or diethyleneglycolamine. In other embodiments, the alkaline developer can include nitrogen-containing bases, e.g., compounds having the formula R^{N1}NH₂, R^{N1}R^{N2}NH, R^{N1}R^{N2}R^{N3}N, or R^{N1}R^{N2}R^{N3}R^{N4}N⁺X^{N1-}, where each of R^{N1}, R^{N2}, R^{N3}, and R^{N4} is, independently, an organo substituent (e.g., optionally substituted alkyl, optionally substituted hydroxyalkyl, or any described herein), or two or more organo substituents that can be joined together, and X^{N1-} may comprise OH⁻, F⁻, Cl⁻, Br⁻, I⁻, or other art-known quaternary ammonium cationic species. These bases may also comprise heterocyclyl nitrogen compounds known in the art, some of which are described herein.

Yet other development methodologies can include use of a deprotecting solvent. Non-limiting deprotecting solvents include an organic acid (e.g., any herein, such as oxalic acid) or include choline ([N(CH₃)₃CH₂CH₂OH]⁺), such as choline hydroxide ([N(CH₃)₃CH₂CH₂OH]⁺[OH]⁻).

The developer can be used in any useful concentration. In one embodiment, the developer solution includes about 0.5 wt. % to about 30 wt. % of the developer(s) in a solvent (e.g., an aqueous solvent, a non-aqueous solvent, an organic solvent, or a combination thereof), including concentrations from about 1 wt. % to about 20 wt. % and 1.1 wt. % to 10 wt. %.

The developer can be used with one or more additives, such as oxidizers, surfactants, salts, and chelating agents. Additives can be optionally present in an amount of less than 10 wt. % or less than 5 wt. % in a developing solution. Non-limiting oxidizers include a peroxide or a peracid, such as hydrogen peroxide, benzoyl peroxide, urea peroxide, or mixtures thereof. Non-limiting surfactants include anionic, cationic, and non-ionic surfactants, such as an alkylphenol ethoxylate (e.g., Triton™ X-100 (polyethylene glycol tert-octylphenyl ether), an octyl phenol ethoxylate, or a nonyl phenol ethoxylate), an alcohol ethoxylate (e.g., BRIJ® 56 (C₁₆H₃₃(OCH₂CH₂)₁₀OH), BRIJ® 58 (C₁₆H₃₃(OCH₂CH₂)₂₀OH), or a fatty alcohol ethoxylate), a fatty acid ethoxylate, a poloxamer, a fatty acid ester of glycerol, an acetylenic diol, an amine ethoxylate, a glucoside, a glucamide, a polyethylene glycol, or poly(ethylene glycol-co-propylene glycol), an ammonium perfluoroalkyl (e.g., ammonium perfluoroalkyl sulfonate or carboxylate), and combinations thereof.

Non-limiting salts include cation(s) selected from the group of ammonium, d-block metal cations (hafnium, zirconium, lanthanum, or the like), f-block metal cations (cerium, lutetium or the like), p-block metal cations (aluminum, tin, or the like), alkali metals (lithium, sodium, potassium or the like), and combinations thereof; and anion(s) selected from the group of fluoride, chloride, bromide, iodide, nitrate, sulfate, phosphate, silicate, borate, peroxide, butoxide, formate, oxalate, ethylenediamine-tetraacetic acid (EDTA), tungstate, molybdate, or the like and combinations thereof. Non-limiting chelating agents can include polyamines, alcohol amines, amino acids, carboxylic acids, or combinations thereof.

In particular embodiments, the positive tone developer is an acidic developer in an aqueous solvent; an acidic developer in an organic solvent; an aqueous alkaline developer (e.g., including NH₄OH, TMAH, TEAH, TPAH, or TBAH, which can be with or without H₂O₂); an aqueous acidic developer (e.g., including HCl or HF); an organic developer; or a deprotecting solvent (e.g., including oxalic acid, choline, or choline hydroxide). A developer can include one solvent or a solvent combination.

As described herein, dry development processes can be used to process a film (e.g., in which dry development can be used alone, before wet development, or after wet development). Non-limiting processes can include use of halides, such as HCl— or HBr-based processes. While this disclosure is not limited to any particular theory or mechanism of operation, the approach is understood to leverage the chemical reactivity of the dry-deposited EUV photoresist films with the clean chemistry (e.g., HCl, HBr, and BCl₃) to form volatile products using vapors or plasma. Such volatile products can be removed in any manner (e.g., by treating with an aqueous acid, as described herein). The dry-deposited EUV photoresist films can be removed with etch rates of up to 1 nm/s. The quick removal of dry-deposited EUV photoresist films by these chemistries is applicable to chamber cleaning, backside clean, bevel clean, and PR developing. Although the films can be removed using vapors at various temperatures (e.g., HCl or HBr at a temperature greater than −10° C., or BCI₃ at a temperature greater than 80° C., for example), a plasma can also be used to further accelerate or enhance the reactivity.

Plasma processes include transformer coupled plasma (TCP), inductively coupled plasma (ICP) or capacitively coupled plasma (CCP), employing equipment and techniques among those known in the art. For example, a process may be conducted at a pressure of >0.5 mTorr (e.g., such as from 1 mTorr to 100 mTorr), at a power level of <1000 W (e.g., <500 W). Temperatures may be from 30° C. to 300° C. (e.g., 30° C. to 120° C.), at flow rate of 100 to 1000 standard cubic centimeters per minute (sccm), e.g., about 500 sccm, for from 1 to 3000 seconds (e.g., 10 seconds to 600 seconds).

Where the halide reactant flows are of hydrogen gas and halide gas, a remote plasma/UV radiation is used to generate radicals from the H₂ and Cl₂ and/or Br₂, and the hydrogen and halide radicals are flowed to the reaction chamber to contact the patterned EUV photoresist on the substrate layer of the wafer. Suitable plasma power may range from 100 W to 500 W, with no bias. It should be understood that while these conditions are suitable for some processing reactors, e.g., a Kiyo etch tool available from Lam Research Corporation, Fremont, CA, a wider range of process conditions may be used according to the capabilities of the processing reactor.

In thermal development processes, the substrate is exposed to dry development chemistry (e.g., a Lewis Acid) in a vacuum chamber (e.g., oven). Suitable chambers can include a vacuum line, a dry development hydrogen halide chemistry gas (e.g., HBr, HCl) line, and heaters for temperature control. In some embodiments, the chamber interior can be coated with corrosion resistant films, such as organic polymers or inorganic coatings. One such coating is polytetrafluoroethylene ((PTFE), e.g., Teflon™). Such materials can be used in thermal processes of this disclosure without risk of removal by plasma exposure.

The process conditions for the dry development may be reactant flow of 100 sccm to 500 sccm (e.g., 500 sccm HBr or HCl), temperature of −10° C. to 120° C. (e.g., −10° C.), pressure of 1 mTorr to 500 mTorr (e.g., 300 mTorr) with no plasma and for a time of about 10 sec to 1 min, dependent on the photoresist film and their composition and properties.

In various embodiments, methods of the present disclosure combine all dry steps of film deposition, formation by vapor deposition, and (EUV) lithographic photopatterning, but which is followed by wet development with an aqueous acid. In other embodiments, methods of the present disclosure combine all dry steps of film deposition, formation by vapor deposition, (EUV) lithographic photopatterning, and dry development, but which is followed by wet treatment with an aqueous acid. In such processes, a substrate may directly go to a dry development/etch chamber following photopatterning in an EUV scanner.

### Other Processes

The methods herein can include any other useful processes, as described below.

For the backside and bevel clean process, the vapor and/or the plasma can be limited to a specific region of the wafer to ensure that only the backside and the bevel are removed, without any film degradation on the frontside of the wafer. The dry-deposited EUV photoresist films being removed are generally composed of Sn, O and C, but the same clean approaches can be extended to films of other metal oxide resists and materials. In addition, this approach can also be used for film strip and PR rework.

Suitable process conditions for a dry bevel edge and backside clean may be a reactant flow of 100 sccm to 500 sccm (e.g., 500 sccm HCl, HBr, or H₂ and Cl₂ or Br₂, BC₃ or H₂), temperature of −10° C. to 120° C. (e.g., 20° C.), pressure of 20 mTorr to 500 mTorr (e.g., 300 mTorr), plasma power of 0 to 500 W at high frequency (e.g., 13.56 MHz), and for a time of about 10 sec to 20 sec, dependent on the photoresist film and composition and properties. It should be understood that while these conditions are suitable for some processing reactors, e.g., a Kiyo etch tool available from Lam Research Corporation, Fremont, CA, a wider range of process conditions may be used according to the capabilities of the processing reactor.

Photolithography processes can involve one or more bake steps, to facilitate the chemical reactions required to produce chemical contrast between exposed and unexposed regions of the photoresist. For high volume manufacturing (HVM), such bake steps can be performed on tracks where the wafers are baked on a hot-plate at a pre-set temperature under ambient air or in some cases N₂ flow. More careful control of the bake ambient as well as introduction of additional reactive gas component in the ambient during these bake steps can help further reduce the dose requirement and/or improve pattern fidelity.

According to various aspects of this disclosure, one or more post-treatments to metal and/or metal oxide-based photoresists after deposition (e.g., post-application bake (PAB) or another post-application treatment) and/or exposure (e.g., post-exposure bake (PEB), which can be omitted; or another post-exposure treatment) and/or development (e.g., post-development bake (PDB) or another post-development treatment) are capable of increasing material property differences between exposed and unexposed photoresist and therefore decreasing dose to size (DtS), improving PR profile, and improving line edge and width roughness (LER/LWR) after subsequent dry development. Such processing can involve a thermal process with the control of temperature, gas ambient, and moisture, resulting in improved dry development performance in processing to follow. In some instances, a remote plasma might be used. Yet in certain instances, PAB and/or PEB and/or PDB are not performed.

In the case of post-application processing (e.g., PAB), a thermal process with control of temperature (e.g., with heating or cooling), gas atmosphere (e.g., air, H₂O, CO₂, CO, O₂, O₃, CH₄, CH₃OH, N₂, H₂, NH₃, N₂O, NO, Ar, He, or their mixtures) or under vacuum, and moisture can be used after deposition and before exposure to change the composition of unexposed metal and/or metal oxide photoresist. The change can increase the EUV sensitivity of the material and thus lower dose to size and edge roughness can be achieved after exposure and dry development.

In the case of post-exposure processing (e.g., PEB), a thermal process with the control of temperature, gas atmosphere (e.g., air, H₂O, CO₂, CO, O₂, O₃, CH₄, CH₃OH, N₂, H₂, NH₃, N₂O, NO, Ar, He, or their mixtures) or under vacuum, and moisture can be used to change the composition of both unexposed and exposed photoresist. The change can increase the composition/material properties difference between the unexposed and exposed photoresist and the etch rate difference of dry development etch gas between the unexposed and exposed photoresist. A higher etch selectivity can thereby be achieved. Due to the improved selectivity, a squarer PR profile can be obtained with improved surface roughness, and/or less photoresist residual/scum. In particular embodiments, PEB can be performed in air and in the optional presence of moisture and CO₂. In other embodiments, PEB can be omitted.

In the case of post-development processing (e.g., post-development bake or PDB), a thermal process with the control of temperature, gas atmosphere (e.g., air, H₂O, CO₂, CO, O₂, O₃, CH₄, CH₃OH, N₂, H₂, NH₃, N₂O, NO, Ar, He, or their mixtures) or under vacuum (e.g., with UV), and moisture can be used to change the composition of the unexposed photoresist. In particular embodiments, the condition also includes use of plasma (e.g., including O₂, O₃, Ar, He, or their mixtures). The change can increase the hardness of material, which can be beneficial if the film will be used as a resist mask when etching the underlying substrate.

In these cases, in alternative implementations, the thermal process could be replaced by a remote plasma process to increase reactive species to lower the energy barrier for the reaction and increase productivity. Remote plasma can generate more reactive radicals and therefore lower the reaction temperature/time for the treatment, leading to increased productivity.

Accordingly, one or multiple processes may be applied to modify the photoresist itself to increase wet or dry development selectivity. This thermal or radical modification can increase the contrast between unexposed and exposed material and thus increase the selectivity of the subsequent development step. The resulting difference between the material properties of unexposed and exposed material can be tuned by adjusting process conditions including temperature, gas flow, moisture, pressure, and/or RF power.

For wet-developed or dry-developed resist films, the treatment temperature in a PAB, PEB, or PDB can be varied to tune and optimize the treatment process, for example from about 90° C. to 250° C. for PAB and about 170° C. to 250° C. or more for PEB and/or PDB. In particular embodiments, PEB is omitted.

In particular embodiments, the PAB, PEB, and/or PDB treatments may be conducted with gas ambient flow in the range of 100 sccm to 10000 sccm, moisture content in the amount of a few percent up to 100% (e.g., 20%-50%), at a pressure between atmospheric and vacuum, and for a duration of about 30 s to 15 min, for example about 1 to 2 min. In particular embodiments, PEB is omitted.

Depending on the selectivity requirements/constraints of the semiconductor processing operation, a thermal treatment such as described herein can be used to lower the EUV dose needed. Or, if higher selectivity is required and higher dose can be tolerated, much higher selectivity, up to 100 times exposed vs. unexposed, can be obtained.

Yet other steps can include in situ metrology, in which physical and structural characteristics (e.g., critical dimension, film thickness, etc.) can be assessed during the photolithography process. Modules to implement in situ metrology include, e.g., scatterometry, ellipsometry, downstream mass spectroscopy, and/or plasma enhanced downstream optical emission spectroscopy modules.

### Apparatuses

The present disclosure also includes any apparatus configured to perform any methods described herein. In one embodiment, the apparatus for depositing a film includes a deposition module comprising a chamber for depositing one or more precursor(s) to provide a film; a patterning module comprising an EUV photolithography tool with a source of sub-30 nm wavelength radiation; and a development module comprising a chamber for developing a film. Post-development treatment (e.g., with an aqueous acid) can be provided within the development module, in another process chamber, or in a separate post-treatment module.

The apparatus can further include a controller having instructions for such modules. In one embodiment, the controller includes one or more memory devices, one or more processors, and system control software coded with instructions for conducting deposition of the film. Such includes can include for, in the deposition module, depositing one or more precursor(s) to provide a film and optionally conducting a PAB or a post-application treatment of the film; in the patterning module, patterning the film with sub-30 nm resolution directly by EUV exposure, thereby forming a pattern within the film; and in the development module, developing the film. In particular embodiments, the development module provides for removal of the EUV exposed or EUV unexposed region(s), thereby providing a pattern within the film. In another embodiment, the apparatus further includes a post-development treatment module, which can provide a process chamber for conducting a post-development treatment of the film.

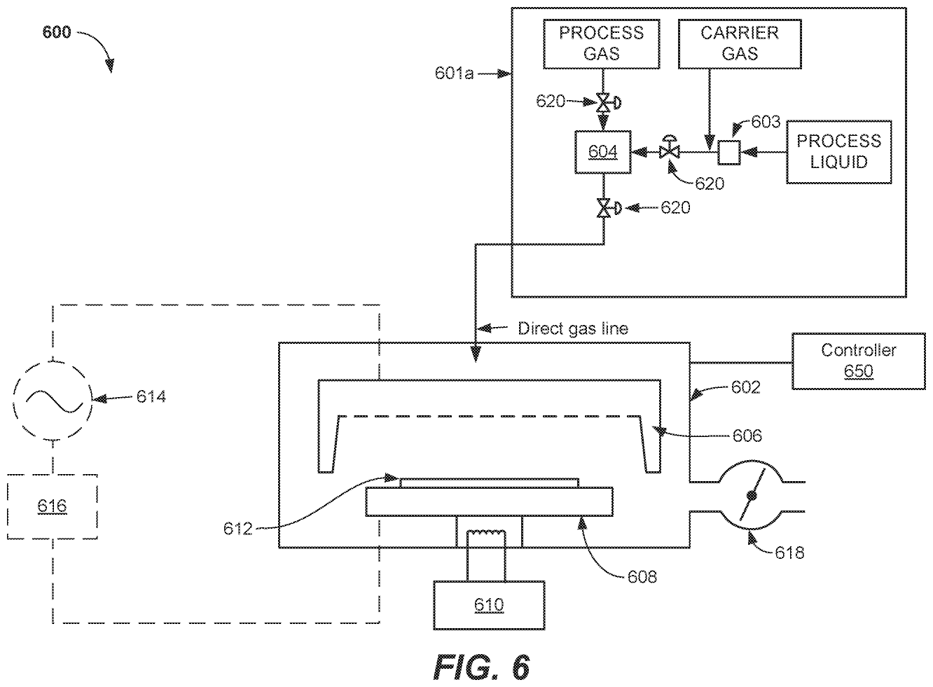

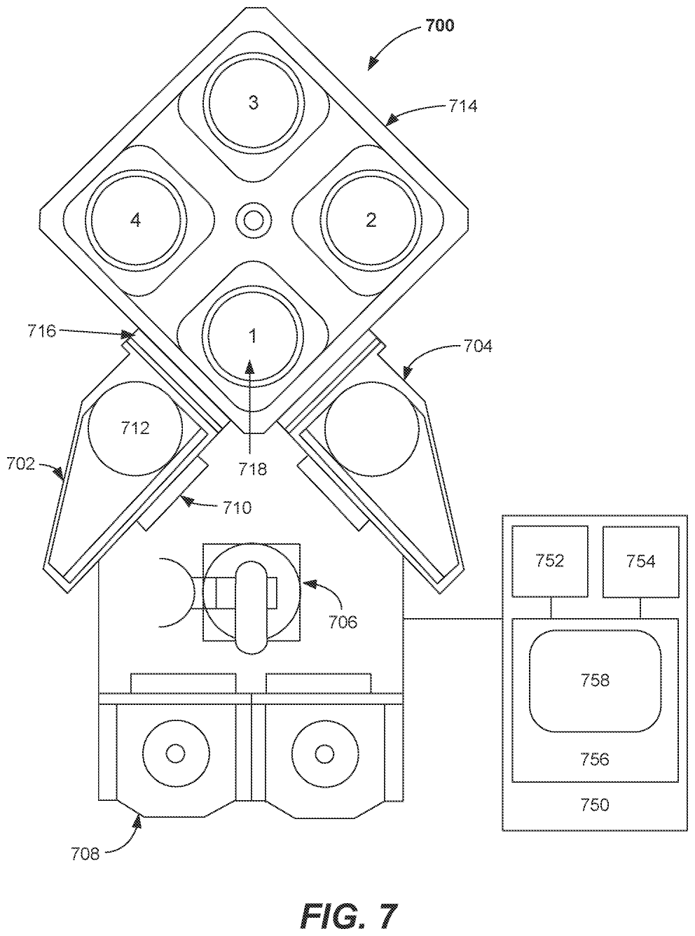

FIG. 6 depicts a schematic illustration of an embodiment of process station 600 having a process chamber body 602 for maintaining a low-pressure environment that is suitable for implementation of described dry deposition and development embodiments as described herein. A plurality of process stations 600 may be included in a common low pressure process tool environment. For example, FIG. 7 depicts an embodiment of a multi-station processing tool 700, such as a VECTOR® processing tool available from Lam Research Corporation, Fremont, CA. In some embodiments, one or more hardware parameters of the process station 600 including those discussed in detail below may be adjusted programmatically by one or more computer controllers 650.

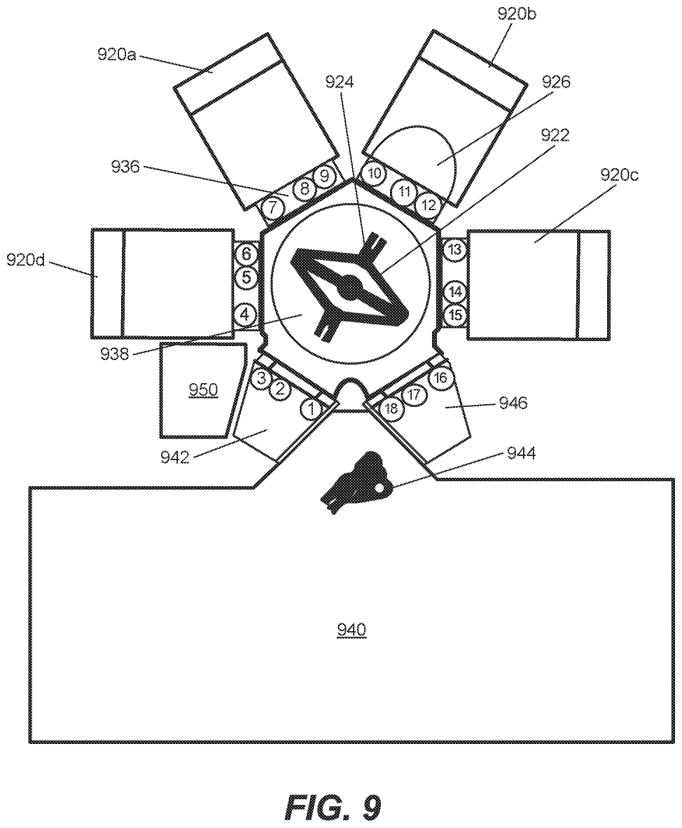

A process station may be configured as a module in a cluster tool. FIG. 9 depicts a semiconductor process cluster tool architecture with vacuum-integrated deposition and patterning modules suitable for implementation of the embodiments described herein. Such a cluster process tool architecture can include resist deposition, resist exposure (EUV scanner), resist development and/or etch modules, as described above and further below with reference to FIGS. 6, 8, and 10.

In some embodiments, certain of the processing functions can be performed consecutively in the same module, for example dry development and etch. And embodiments of this disclosure are directed to methods and apparatus for receiving a wafer, including a photopatterned EUV resist thin film layer disposed on a layer or layer stack to be etched, to a dry development/etch chamber following photopatterning in an EUV scanner; dry developing the photopatterned EUV resist thin film layer; and then etching the underlying layer using the patterned EUV resist as a mask, as described herein.

In other embodiments, differing modules can be employs, especially if a dry process is followed by a wet process or vice versa. Non-limiting embodiments of this disclosure are directed to methods and apparatus for receiving a wafer; depositing an EUV resist thin film layer in a dry deposition process (e.g., using a vapor) or a wet deposition process (e.g., using a liquid), followed by photopatterning in an EUV scanner; and then wet developing the photopatterned EUV resist thin film layer with an aqueous acid, as described herein. Other non-limiting embodiments of this disclosure are directed to methods and apparatus for receiving a wafer; depositing an EUV resist thin film layer in a dry deposition process or a wet deposition process, followed by photopatterning in an EUV scanner; dry developing the photopatterned EUV resist thin film layer; and then treating the pattern with an aqueous acid, as described herein.

Returning to FIG. 6, process station 600 fluidly communicates with reactant delivery system 601a for delivering process gases to a distribution showerhead 606. Reactant delivery system 601a optionally includes a mixing vessel 604 for blending and/or conditioning process gases, for delivery to showerhead 606. One or more mixing vessel inlet valves 620 may control introduction of process gases to mixing vessel 604. Where plasma exposure is used, plasma may also be delivered to the showerhead 606 or may be generated in the process station 600. As noted above, in at least some embodiments, non-plasma thermal exposure is favored.

FIG. 6 includes an optional vaporization point 603 for vaporizing liquid reactant to be supplied to the mixing vessel 604. In some embodiments, a liquid flow controller (LFC) upstream of vaporization point 603 may be provided for controlling a mass flow of liquid for vaporization and delivery to process station 600. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM.

Showerhead 606 distributes process gases toward substrate 612. In the embodiment shown in FIG. 6 the substrate 612 is located beneath showerhead 606 and is shown resting on a pedestal 608. Showerhead 606 may have any suitable shape, and may have any suitable number and arrangement of ports for distributing process gases to substrate 612.

In some embodiments, pedestal 608 may be raised or lowered to expose substrate 612 to a volume between the substrate 612 and the showerhead 606. It will be appreciated that, in some embodiments, pedestal height may be adjusted programmatically by a suitable computer controller 650.

In some embodiments, pedestal 608 may be temperature controlled via heater 610. In some embodiments, the pedestal 608 may be heated to a temperature of greater than 0° C. and up to 300° C. or more, for example 50 to 120° C., such as about 65 to 80° C., during non-plasma thermal exposure of a photopatterned resist to hydrogen halide dry development chemistry, such as HBr, HCl, or BC₃, as described in disclosed embodiments.

Further, in some embodiments, pressure control for process station 600 may be provided by a butterfly valve 618. As shown in the embodiment of FIG. 6, butterfly valve 618 throttles a vacuum provided by a downstream vacuum pump (not shown). However, in some embodiments, pressure control of process station 600 may also be adjusted by varying a flow rate of one or more gases introduced to the process station 600.

In some embodiments, a position of showerhead 606 may be adjusted relative to pedestal 608 to vary a volume between the substrate 612 and the showerhead 606. Further, it will be appreciated that a vertical position of pedestal 608 and/or showerhead 606 may be varied by any suitable mechanism within the scope of the present disclosure. In some embodiments, pedestal 608 may include a rotational axis for rotating an orientation of substrate 612. It will be appreciated that, in some embodiments, one or more of these example adjustments may be performed programmatically by one or more suitable computer controllers 650.

Where plasma may be used, for example in gentle plasma-based dry development embodiments and/or etch operations conducted in the same chamber, showerhead 606 and pedestal 608 electrically communicate with a radio frequency (RF) power supply 614 and matching network 616 for powering a plasma. In some embodiments, the plasma energy may be controlled by controlling one or more of a process station pressure, a gas concentration, an RF source power, an RF source frequency, and a plasma power pulse timing. For example, RF power supply 614 and matching network 616 may be operated at any suitable power to form a plasma having a desired composition of radical species. Examples of suitable powers are up to about 500 W.

In some embodiments, instructions for a controller 650 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, a recipe phase may include instructions for setting a flow rate of a dry development chemistry reactant gas, such as HBr or HCl, and time delay instructions for the recipe phase. In some embodiments, the controller 650 may include any of the features described below with respect to system controller 750 of FIG. 7.

As described above, one or more process stations may be included in a multi-station processing tool. FIG. 7 shows a schematic view of an embodiment of a multi-station processing tool 700 with an inbound load lock 702 and an outbound load lock 704, either or both of which may include a remote plasma source. A robot 706 at atmospheric pressure is configured to move wafers from a cassette loaded through a pod 708 into inbound load lock 702 via an atmospheric port 710. A wafer is placed by the robot 706 on a pedestal 712 in the inbound load lock 702, the atmospheric port 710 is closed, and the load lock is pumped down. Where the inbound load lock 702 includes a remote plasma source, the wafer may be exposed to a remote plasma treatment to treat the silicon nitride surface in the load lock prior to being introduced into a processing chamber 714. Further, the wafer also may be heated in the inbound load lock 702 as well, for example, to remove moisture and adsorbed gases. Next, a chamber transport port 716 to processing chamber 714 is opened, and another robot (not shown) places the wafer into the reactor on a pedestal of a first station shown in the reactor for processing. While the embodiment depicted in FIG. 7 includes load locks, it will be appreciated that, in some embodiments, direct entry of a wafer into a process station may be provided.

The depicted processing chamber 714 includes four process stations, numbered from 1 to 4 in the embodiment shown in FIG. 7. Each station has a heated pedestal (shown at 718 for station 1), and gas line inlets. It will be appreciated that in some embodiments, each process station may have different or multiple purposes. For example, in some embodiments, a process station may be switchable between dry development and etch process modes. Additionally or alternatively, in some embodiments, processing chamber 714 may include one or more matched pairs of dry development and etch process stations. While the depicted processing chamber 714 includes four stations, it will be understood that a processing chamber according to the present disclosure may have any suitable number of stations. For example, in some embodiments, a processing chamber may have five or more stations, while in other embodiments a processing chamber may have three or fewer stations.

FIG. 7 depicts an embodiment of a wafer handling system 790 for transferring wafers within processing chamber 714. In some embodiments, wafer handling system 790 may transfer wafers between various process stations and/or between a process station and a load lock. It will be appreciated that any suitable wafer handling system may be employed. Non-limiting examples include wafer carousels and wafer handling robots. FIG. 7 also depicts an embodiment of a system controller 750 employed to control process conditions and hardware states of process tool 700. System controller 750 may include one or more memory devices 756, one or more mass storage devices 754, and one or more processors 752. Processor 752 may include a CPU or computer, analog, and/or digital input/output connections, stepper motor controller boards, etc.

In some embodiments, system controller 750 controls all of the activities of process tool 700. System controller 750 executes system control software 758 stored in mass storage device 754, loaded into memory device 756, and executed on processor 752. Alternatively, the control logic may be hard coded in the controller 750. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 758 may include instructions for controlling the timing, mixture of gases, gas flow rates, chamber and/or station pressure, chamber and/or station temperature, wafer temperature, target power levels, RF power levels, substrate pedestal, chuck and/or susceptor position, and other parameters of a particular process performed by process tool 700. System control software 758 may be configured in any suitable way. For example, various process tool component subroutines or control objects may be written to control operation of the process tool components used to carry out various process tool processes. System control software 758 may be coded in any suitable computer readable programming language.

In some embodiments, system control software 758 may include input/output control (IOC) sequencing instructions for controlling the various parameters described above. Other computer software and/or programs stored on mass storage device 754 and/or memory device 756 associated with system controller 750 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 718 and to control the spacing between the substrate and other parts of process tool 700.

A process gas control program may include code for controlling hydrogen halide gas composition (e.g., HBr or HCl gas as described herein) and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. Alternatively, the heater control program may control delivery of a heat transfer gas (such as helium) to the substrate.

A plasma control program may include code for setting RF power levels applied to the process electrodes in one or more process stations in accordance with the embodiments herein.

A pressure control program may include code for maintaining the pressure in the reaction chamber in accordance with the embodiments herein.

In some embodiments, there may be a user interface associated with system controller 750. The user interface may include a display screen, graphical software displays of the apparatus and/or process conditions, and user input devices such as pointing devices, keyboards, touch screens, microphones, etc.

In some embodiments, parameters adjusted by system controller 750 may relate to process conditions. Non-limiting examples include process gas composition and flow rates, temperature, pressure, plasma conditions (such as RF bias power levels), etc. These parameters may be provided to the user in the form of a recipe, which may be entered utilizing the user interface.

Signals for monitoring the process may be provided by analog and/or digital input connections of system controller 750 from various process tool sensors. The signals for controlling the process may be output on the analog and digital output connections of process tool 700. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 750 may provide program instructions for implementing the above-described deposition processes. The program instructions may control a variety of process parameters, such as DC power level, RF bias power level, pressure, temperature, etc. The instructions may control the parameters to operate dry development and/or etch processes according to various embodiments described herein.

The system controller 750 can include one or more memory devices and one or more processors configured to execute the instructions so that the apparatus will perform a method in accordance with disclosed embodiments. Machine-readable media containing instructions for controlling process operations in accordance with disclosed embodiments may be coupled to the system controller 750.

In some implementations, the system controller 750 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 750, depending on the processing conditions and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 750 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 750 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 750, in some implementations, may be a part of or coupled to a computer that is integrated with, coupled to the system, otherwise networked to the system, or a combination thereof. For example, the system controller 750 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 750 receives instructions in the form of data, which specify parameters for each of the processing steps to be performed during one or more operations. It should be understood that the parameters may be specific to the type of process to be performed and the type of tool that the system controller 750 is configured to interface with or control. Thus, as described above, the system controller 750 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an atomic layer etch (ALE) chamber or module, an ion implantation chamber or module, a track chamber or module, an EUV lithography chamber (scanner) or module, a dry development chamber or module, and any other semiconductor processing systems that may be associated or used in the fabrication and/or manufacturing of semiconductor wafers.

As noted above, depending on the process step or steps to be performed by the tool, the system controller 750 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

Inductively coupled plasma (ICP) reactors which, in certain embodiments, may be suitable for etch operations suitable for implementation of some embodiments, are now described. Although ICP reactors are described herein, in some embodiments, it should be understood that capacitively coupled plasma reactors may also be used.

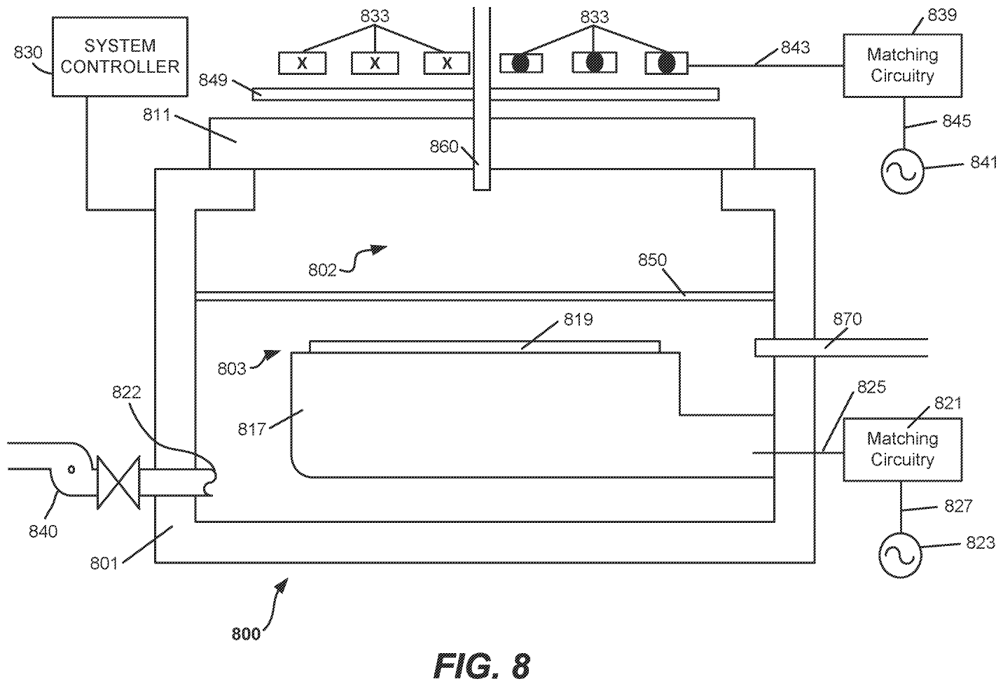

FIG. 8 schematically shows a cross-sectional view of an inductively coupled plasma apparatus 800 appropriate for implementing certain embodiments or aspects of embodiments such as dry development and/or etch, an example of which is a Kiyo® reactor, produced by Lam Research Corp. of Fremont, CA. In other embodiments, other tools or tool types having the functionality to conduct the dry development and/or etch processes described herein may be used for implementation.

The inductively coupled plasma apparatus 800 includes an overall process chamber 824 structurally defined by chamber walls 801 and a window 811. The chamber walls 801 may be fabricated from stainless steel or aluminum. The window 811 may be fabricated from quartz or other dielectric material. An optional internal plasma grid 850 divides the overall process chamber into an upper sub-chamber 802 and a lower sub chamber 803. In most embodiments, plasma grid 850 may be removed, thereby utilizing a chamber space made of sub chambers 802 and 803. A chuck 817 is positioned within the lower sub-chamber 803 near the bottom inner surface. The chuck 817 is configured to receive and hold a semiconductor wafer 819 upon which the etching and deposition processes are performed. The chuck 817 can be an electrostatic chuck for supporting the wafer 819 when present. In some embodiments, an edge ring (not shown) surrounds chuck 817, and has an upper surface that is approximately planar with a top surface of the wafer 819, when present over chuck 817. The chuck 817 also includes electrostatic electrodes for chucking and dechucking the wafer 819. A filter and DC clamp power supply (not shown) may be provided for this purpose. Other control systems for lifting the wafer 819 off the chuck 817 can also be provided. The chuck 817 can be electrically charged using an RF power supply 823. The RF power supply 823 is connected to matching circuitry 821 through a connection 827. The matching circuitry 821 is connected to the chuck 817 through a connection 825. In this manner, the RF power supply 823 is connected to the chuck 817. In various embodiments, a bias power of the electrostatic chuck may be set at about 50 V or may be set at a different bias power depending on the process performed in accordance with disclosed embodiments. For example, the bias power may be between about 20 V and about 100 V, or between about 30 V and about 150 V.

Elements for plasma generation include a coil 833 is positioned above window 811. In some embodiments, a coil is not used in disclosed embodiments. The coil 833 is fabricated from an electrically conductive material and includes at least one complete turn. The example of a coil 833 shown in FIG. 8 includes three turns. The cross sections of coil 833 are shown with symbols, and coils having an “X” extend rotationally into the page, while coils having a “•” extend rotationally out of the page. Elements for plasma generation also include an RF power supply 841 configured to supply RF power to the coil 833. In general, the RF power supply 841 is connected to matching circuitry 839 through a connection 845. The matching circuitry 839 is connected to the coil 833 through a connection 843. In this manner, the RF power supply 841 is connected to the coil 833. An optional Faraday shield 849a is positioned between the coil 833 and the window 811. The Faraday shield 849a may be maintained in a spaced apart relationship relative to the coil 833. In some embodiments, the Faraday shield 849a is disposed immediately above the window 811. In some embodiments, the Faraday shield 849b is between the window 811 and the chuck 817. In some embodiments, the Faraday shield 849b is not maintained in a spaced apart relationship relative to the coil 833. For example, the Faraday shield 849b may be directly below the window 811 without a gap. The coil 833, the Faraday shield 849a, and the window 811 are each configured to be substantially parallel to one another. The Faraday shield 849a may prevent metal or other species from depositing on the window 811 of the process chamber 824.

Process gases may be flowed into the process chamber through one or more main gas flow inlets 860 positioned in the upper sub-chamber 802 and/or through one or more side gas flow inlets 870. Likewise, though not explicitly shown, similar gas flow inlets may be used to supply process gases to a capacitively coupled plasma processing chamber. A vacuum pump, e.g., a one or two stage mechanical dry pump and/or turbomolecular pump 840, may be used to draw process gases out of the process chamber 824 and to maintain a pressure within the process chamber 824. For example, the vacuum pump may be used to evacuate the lower sub-chamber 803 during a purge operation of ALD. A valve-controlled conduit may be used to fluidically connect the vacuum pump to the process chamber 824 so as to selectively control application of the vacuum environment provided by the vacuum pump. This may be done employing a closed loop-controlled flow restriction device, such as a throttle valve (not shown) or a pendulum valve (not shown), during operational plasma processing. Likewise, a vacuum pump and valve controlled fluidic connection to the capacitively coupled plasma processing chamber may also be employed.

During operation of the apparatus 800, one or more process gases may be supplied through the gas flow inlets 860 and/or 870. In certain embodiments, process gas may be supplied only through the main gas flow inlet 860, or only through the side gas flow inlet 870. In some cases, the gas flow inlets shown in the figure may be replaced by more complex gas flow inlets, one or more showerheads, for example. The Faraday shield 849a and/or optional grid 850 may include internal channels and holes that allow delivery of process gases to the process chamber 824. Either or both of Faraday shield 849a and optional grid 850 may serve as a showerhead for delivery of process gases. In some embodiments, a liquid vaporization and delivery system may be situated upstream of the process chamber 824, such that once a liquid reactant or precursor is vaporized, the vaporized reactant or precursor is introduced into the process chamber 824 via a gas flow inlet 860 and/or 870.

Radio frequency power is supplied from the RF power supply 841 to the coil 833 to cause an RF current to flow through the coil 833. The RF current flowing through the coil 833 generates an electromagnetic field about the coil 833. The electromagnetic field generates an inductive current within the upper sub-chamber 802. The physical and chemical interactions of various generated ions and radicals with the wafer 819 etch features of and selectively deposit layers on the wafer 819.

If the plasma grid 850 is used such that there is both an upper sub-chamber 802 and a lower sub-chamber 803, the inductive current acts on the gas present in the upper sub-chamber 802 to generate an electron-ion plasma in the upper sub-chamber 802. The optional internal plasma grid 850 limits the amount of hot electrons in the lower sub-chamber 803. In some embodiments, the apparatus 800 is designed and operated such that the plasma present in the lower sub-chamber 803 is an ion-ion plasma.

Both the upper electron-ion plasma and the lower ion-ion plasma may contain positive and negative ions, though the ion-ion plasma will have a greater ratio of negative ions to positive ions. Volatile etching and/or deposition byproducts may be removed from the lower sub-chamber 803 through port 822. The chuck 817 disclosed herein may operate at elevated temperatures ranging between about 10° C. and about 250° C. The temperature will depend on the process operation and specific recipe.

Apparatus 800 may be coupled to facilities (not shown) when installed in a clean room or a fabrication facility. Facilities include plumbing that provide processing gases, vacuum, temperature control, and environmental particle control. These facilities are coupled to apparatus 800, when installed in the target fabrication facility. Additionally, apparatus 800 may be coupled to a transfer chamber that allows robotics to transfer semiconductor wafers into and out of apparatus 800 using automation.

In some embodiments, a system controller 830 (which may include one or more physical or logical controllers) controls some or all of the operations of a process chamber 824. The system controller 830 may include one or more memory devices and one or more processors. In some embodiments, the apparatus 800 includes a switching system for controlling flow rates and durations when disclosed embodiments are performed. In some embodiments, the apparatus 800 may have a switching time of up to about 500 ms, or up to about 750 ms. Switching time may depend on the flow chemistry, recipe chosen, reactor architecture, and other factors.

In some implementations, the system controller 830 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be integrated into the system controller 830, which may control various components or subparts of the system or systems. The system controller, depending on the processing parameters and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 830 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication or removal of one or more layers, materials, metals, oxides, silicon, silicon dioxide, surfaces, circuits, and/or dies of a wafer.

The system controller 830, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 830 receives instructions in the form of data, which specify parameters for each of the processing steps to be performed during one or more operations. It should be understood that the parameters may be specific to the type of process to be performed and the type of tool that the controller is configured to interface with or control. Thus, as described above, the system controller 830 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an ALE chamber or module, an ion implantation chamber or module, a track chamber or module, an EUV lithography chamber (scanner) or module, a dry development chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

EUVL patterning may be conducted using any suitable tool, often referred to as a scanner, for example the TWINSCAN NXE: 3300B® platform supplied by ASML of Veldhoven, NL). Processing for dry deposition, PAB, EUV exposure, and wet development may be conducted in separate process chambers, and/or process chambers may be configured as a module in a cluster tool architecture with vacuum-integrated deposition and patterning modules suitable for implementation of the embodiments described herein. In some embodiments, certain of the processing functions can be performed consecutively in the same chamber or module, for example dry deposition and PAB.

The EUVL patterning tool may be a standalone device from which the substrate is moved into and out of for deposition and etching as described herein. Or, as described below, the EUVL patterning tool may be a module on a larger multi-component tool. FIG. 9 depicts a semiconductor process cluster tool architecture with vacuum-integrated deposition, EUV patterning and dry development/etch modules that interface with a vacuum transfer module, suitable for implementation of the processes described herein. While the processes may be conducted without such vacuum integrated apparatus, such apparatus may be advantageous in some implementations.

FIG. 9 depicts a semiconductor process cluster tool architecture with vacuum-integrated deposition and patterning modules that interface with a vacuum transfer module, suitable for implementation of processes described herein. The arrangement of transfer modules to “transfer” wafers among multiple storage facilities and processing modules may be referred to as a “cluster tool architecture” system. Deposition and patterning modules are vacuum-integrated, in accordance with the requirements of a particular process. Other modules, such as for etch, may also be included on the cluster.

A vacuum transport module (VTM) 938 interfaces with four processing modules 920a-920d, which may be individually optimized to perform various fabrication processes. By way of example, processing modules 920a-920d may be implemented to perform deposition, evaporation, ELD, dry development, etch, strip, and/or other semiconductor processes. For example, module 920a may be an ALD reactor that may be operated to perform in a non-plasma, thermal atomic layer depositions as described herein, such as Vector tool, available from Lam Research Corporation, Fremont, CA. And module 920b may be a PECVD tool, such as the Lam Vector®. It should be understood that the figure is not necessarily drawn to scale.

Airlocks 942 and 946, also known as a loadlocks or transfer modules, interface with the VTM 938 and a patterning module 940. For example, as noted above, a suitable patterning module may be the TWINSCAN NXE: 3300B@platform supplied by ASML of Veldhoven, NL). This tool architecture allows for work pieces, such as semiconductor substrates or wafers, to be transferred under vacuum so as not to react before exposure. Integration of the deposition modules with the lithography tool is facilitated by the fact that EUVL also requires a greatly reduced pressure given the strong optical absorption of the incident photons by ambient gases such as H₂O, O₂, etc.

As noted above, this integrated architecture is just one possible embodiment of a tool for implementation of the described processes. The processes may also be implemented with a stand-alone EUVL scanner and a deposition reactor, such as a Lam Vector tool, either stand alone or integrated in a cluster architecture with other tools, such as etch, strip etc. (e.g., Lam Kiyo or Gamma tools), as modules, for example as described with reference to FIG. 9 but without the integrated patterning module.

Airlock 942 may be an “outgoing” loadlock, referring to the transfer of a substrate out from the VTM 938 serving a deposition module 920a to the patterning module 940, and airlock 946 may be an “ingoing” loadlock, referring to the transfer of a substrate from the patterning module 940 back in to the VTM 938. The ingoing loadlock 946 may also provide an interface to the exterior of the tool for access and egress of substrates. Each process module has a facet that interfaces the module to VTM 938. For example, deposition process module 920a has facet 936. Inside each facet, sensors, for example, sensors 1-18 as shown, are used to detect the passing of wafer 926 when moved between respective stations. Patterning module 940 and airlocks 942 and 946 may be similarly equipped with additional facets and sensors, not shown.

Main VTM robot 922 transfers wafer 926 between modules, including airlocks 942 and 946. In one embodiment, robot 922 has one arm, and in another embodiment, robot 922 has two arms, where each arm has an end effector 924 to pick wafers such as wafer 926 for transport. Front-end robot 944, in is used to transfer wafers 926 from outgoing airlock 942 into the patterning module 940, from the patterning module 940 into ingoing airlock 946. Front-end robot 944 may also transport wafers 926 between the ingoing loadlock and the exterior of the tool for access and egress of substrates. Because ingoing airlock module 946 has the ability to match the environment between atmospheric and vacuum, the wafer 926 is able to move between the two pressure environments without being damaged.

It should be noted that a EUVL tool can operate at a higher vacuum than a deposition tool. If this is the case, it is desirable to increase the vacuum environment of the substrate during the transfer between the deposition to the EUVL tool to allow the substrate to degas prior to entry into the patterning tool. Outgoing airlock 942 may provide this function by holding the transferred wafers at a lower pressure, no higher than the pressure in the patterning module 940, for a period of time and exhausting any off-gassing, so that the optics of the patterning tool 940 are not contaminated by off-gassing from the substrate. A suitable pressure for the outgoing, off-gassing airlock is no more than 1E-8 Torr.

In some embodiments, a system controller (which may include one or more physical or logical controllers) controls some or all of the operations of the cluster tool and/or its separate modules. It should be noted that the controller can be local to the cluster architecture, or can be located external to the cluster architecture in the manufacturing floor, or in a remote location and connected to the cluster architecture via a network. The system controller 950 may include one or more memory devices and one or more processors. The processor may include a central processing unit (CPU) or computer, analog and/or digital input/output connections, stepper motor controller boards, and other like components. Instructions for implementing appropriate control operations are executed on the processor. These instructions may be stored on the memory devices associated with the controller or they may be provided over a network. In certain embodiments, the system controller executes system control software.

The system control software may include instructions for controlling the timing of application and/or magnitude of any aspect of tool or module operation. System control software may be configured in any suitable way. For example, various process tool component subroutines or control objects may be written to control operations of the process tool components necessary to carry out various process tool processes. System control software may be coded in any suitable compute readable programming language. In some embodiments, system control software includes input/output control (IOC) sequencing instructions for controlling the various parameters described above. For example, each phase of a semiconductor fabrication process may include one or more instructions for execution by the system controller. The instructions for setting process conditions for condensation, deposition, evaporation, patterning and/or etching phase may be included in a corresponding recipe phase, for example.

It should be noted that the computer controlling the wafer movement can be local to the cluster architecture, or can be located external to the cluster architecture in the manufacturing floor, or in a remote location and connected to the cluster architecture via a network. A controller as described above with respect to any of FIGSs. 6, 7, 8, or 10 may be implemented with the tool in FIG. 9.

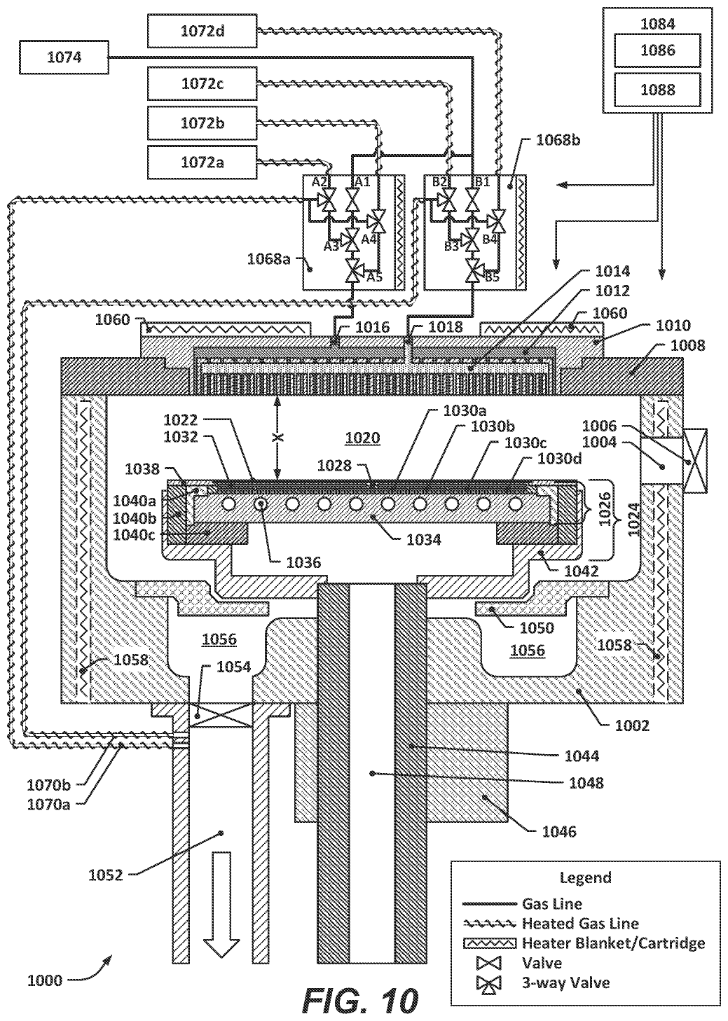

FIG. 10 shows an example of a deposition chamber (e.g., for vapor-based deposition of a film). As can be seen, an apparatus 1000 is depicted that has a processing chamber 1002 that includes a lid 1008. The processing chamber 1002 may include a wafer transfer passage 1004 through one of the walls of the processing chamber 1002 that is sized to allow a substrate 1022 to be passed therethrough and into the interior of the processing chamber 1002, where the substrate 1022 may be placed on a wafer support 1024. The wafer transfer passage 1004 may have a gate valve 1006 or similar door mechanism that may be operated to seal or unseal the wafer transfer passage, thereby allowing the environment within the processing chamber 1002 to be isolated from the environment on the other side of the gate valve 1006. For example, the processing chamber 1002 may be provided substrates 1022 via a wafer handling robot that is located in an adjoining transfer chamber. Such a transfer chamber may, for example, have multiple processing chambers 1002 arranged around its periphery, with each such processing chamber 1002 connected with the transfer chamber via a corresponding gate valve 1006.

The wafer support 1024 may, for example, include an electrostatic chuck (ESC) 1026, which may be used to provide a wafer support surface for supporting the substrate 1022. The ESC 1026 may include, for example, a base plate 1034 that is bonded to a top plate 1028 that is placed atop the base plate 1034. The top plate 1028 may, for example, be made of a ceramic material and may have embedded within it several other components. In the depicted example, the top plate 1028 has two separate electrical systems embedded within it. One such system is an electrostatic clamping electrode system, which may have one or more clamping electrodes 1032 that may be used to generate an electric charge within the substrate 1022 that causes the substrate 1022 to be drawn against the wafer support surface of the top plate 1028. In the implementation of FIG. 10, there are two clamping electrodes 1032 that provide a bi-polar electrostatic clamping system, although some implementations may use only a single clamping electrode 1032 to provide a mono-polar electrostatic clamping system.

The other system is a thermal control system that may be used to control the temperature of the substrate 1022 during processing conditions. In FIG. 10, the thermal control system is a multi-zone thermal control system featuring four annular resistance heater traces 1030a, 1030b, 1030c, and 1030d that are concentric with one another and positioned beneath the clamping electrodes 1032. The center resistance heater traces 1030a may, in some implementations, fill a generally circular area, and each resistance heater trace 1030a/b/c/d may follow a generally serpentine or otherwise meandering path within a corresponding annular region. Each resistance heater trace 1030a/b/c/d may be individually controlled to provide a variety of radial heating profiles in the top plate 1028; such a four-zone heating system may, for example, be controlled to maintain the substrate 1022 so as to have a temperature uniformity of ±0.5° C. in some cases. While the apparatus 1000 of FIG. 10 features a four-zone heating system in the ESC 1026, other implementations may use single-zone or multi-zone heating systems having more or fewer than four zones.

In some implementations, of, for example, temperature control mechanisms discussed above, heat pumps may be used instead of resistance heating traces. For example, in some implementations, the resistance heater traces may be replaced by, or augmented by, Peltier junctions or other, similar devices that may be controlled to “pump” heat from one side thereof to another. Such mechanisms may be used, for example, to draw heat from the top plate 1028 (and thus the substrate 1022) and direct it into the baseplate 1034 and the heat exchange passages 1036, thereby allowing the substrate 1022 to be cooled more rapidly and more effectively, if desired.

The ESC 1026 may also include, for example, a base plate 1034 that may be used to provide structural support to the underside of the top plate 1028 and which may also act as a heat dispersion system. For example, the base plate 1034 may include one or more heat exchange passages 1036 that are arranged in a generally distributed fashion throughout the base plate 1034, e.g., the heat exchange passages 1036 may follow a serpentine, circular switchback, or spiral pattern around the center of the base plate 1034. A heat exchange medium, e.g., water or inert fluorinated liquid, may be circulated through the heat exchange passages 1036 during use. The flow rate and temperature of the heat exchange medium may be externally controlled so as to result in a particular heating or cooling behavior in the base plate 1034.

The ESC 1026 may, for example, be supported by a wafer support housing 1042 that is connected with, and supported by, a wafer support column 1044. The wafer support column 1044 may, for example, have a routing passage 1048 other pass-throughs for routing cabling, fluid flow conduits, and other equipment to the underside of the base plate 1034 and/or the top plate 1028. For example, while not shown in FIG. 10, cabling for providing electrical power to the resistance heater traces 1030a/b/c/d may be routed through the routing passage 1048, as may cabling for providing electrical power to the clamping electrodes 1032. Other cables, e.g., cables for temperature sensors, may also be routed through the routing passage 1048 to locations in the interior of the wafer support 1024. In implementations with a temperature-controllable base plate 1034, conduits for conveying heat exchange medium to and from the base plate 1034 may also be routed through the routing passage 1048. To avoid undue clutter, such cables and conduits are not depicted in FIG. 10, but it is to be understood that they would, nonetheless, be present.

The apparatus 1000 of FIG. 10 also includes a wafer support z-actuator 1046 that may provide movable support to the wafer support column 1044. The wafer support z-actuator 1046 may be actuated to cause the wafer support column 1044, and the wafer support 1024 supported thereby, to move up or down vertically, e.g., by up to several inches, within a reaction space 1020 of the processing chamber 1002. In doing so, a gap distance X between the substrate 1022 and the underside of the showerhead 1010 may be tuned depending on various process conditions.

The wafer support 1024 may also include, in some implementations, one or more edge rings that may be used to control and/or fine-tune various process conditions. In FIG. 10, an upper edge ring 1038 is provided that lies on top of, for example, lower edge rings 1040a and 1040b, which, in turn, are supported by the wafer support housing 1042 and a third lower edge ring 1040c. The upper edge ring 1038 may, for example, be generally subjected to the same processing environment as the substrate 1022, whereas the lower edge rings 1040a/b/c may generally be shielded from the processing environment. Due to the increased exposure of the upper edge ring 1038, the upper edge ring 1038 may have a limited lifespan and may require more frequent replacement or cleaning as compared with the lower edge rings 1040a/b/c.

The apparatus 1000 may also include a system for removing process gases from the processing chamber 1002 during and after processing concludes. For example, the processing chamber 1002 may include an annular plenum 1056 that encircles the wafer support column 1044. The annular plenum 1056 may, in turn, be fluidically connected with a vacuum foreline 1052 that may be connected with a vacuum pump, e.g., such as may be located beneath a subfloor below the apparatus 1000. A regulator valve 1054 may be provided in between the vacuum foreline 1052 and the processing chamber 1002 and actuated to control the flow into the vacuum foreline 1052. In some implementations, a baffle 1050, e.g., an annular plate or other structure that may serve to make the flow into the annular plenum 1056 more evenly distributed about the circumference of the wafer support column 1044, may be provided to reduce the chances of flow non-uniformities developing in reactants flowed across the substrate 1022.

The showerhead 1010, as shown, is a dual-plenum showerhead 1010 and includes a first plenum 1012 that is provided process gas via a first inlet 1016 and a second plenum 1014 that is provided process gas via a second inlet 1018. Generally, two plenums can be employed to maintain separation between the precursor(s) and the counter-reactant(s) prior to release of the precursor and the counter-reactant. The showerhead 1010 may, in some implementations, have more than two plenums. In some instances, a single plenum is used to deliver the precursor(s) into the reaction space 1020 of the processing chamber 1002. Each plenum may have a corresponding set of gas distribution ports that fluidically connect the respective plenum with the reaction space 1020 through the faceplate of the showerhead 1010 (the faceplate being the portion of the showerhead 1010 that is interposed between the lowermost plenum and the reaction space 1020).

The first inlet 1016 and the second inlet 1018 of the showerhead 1010 may be provided processing gases via a gas supply system, which may be configured to provide one or more precursor(s) and/or counter-reactant(s), as discussed herein. The depicted apparatus 1000 is configured to provide multiple precursors and multiple counter-reactants. For example, a first valve manifold 1068a may be configured to provide precursor(s) to the first inlet 1016, while a second valve manifold 1068b may be configured to provide other precursor(s) or other counter-reactants to the second inlet 1018.

A first valve manifold 1068a may be configured to provide one or more precursor(s) to the first inlet 1016, while a second valve manifold 1068b may be configured to provide other precursor(s) or other reactant to the second inlet 1018. In this example, the first valve manifold 1068a, for example, includes multiple valves A1-A5. Valve A2 may, for example, be a three-way valve that has one port fluidically connected with a first vaporizer 1072a, another port fluidically connected with a bypass line 1070a, and a third port fluidically connected with a port on another 3-way valve A3. Similarly, valve A4 may be another three-way valve that has one port fluidically connected with a second vaporizer 1072b, another port fluidically connected with the bypass line 1070a, and a third port fluidically connected with a port on another 3-way valve A5. One of the other ports on valve A5 may be fluidically connected with the first inlet 1016 while the remaining port on valve A5 may be fluidically connected with one of the remaining ports on the valve A3. The remaining port on the valve A3 may, in turn, be fluidically connected with the valve A1 which may be fluidically interposed between the valve A3 and a purge gas source 1074, e.g., nitrogen, argon, or other suitably inert gas (with respect to precursor(s) and/or counter-reactant(s)). In some embodiments, only the first valve manifold is employed.

For the purposes of this disclosure, the term “fluidically connected” is used with respect to volumes, plenums, holes, etc., that may be connected with one another in order to form a fluidic connection, similar to how the term “electrically connected” is used with respect to components that are connected together to form an electric connection. The term “fluidically interposed,” if used, may be used to refer to a component, volume, plenum, or hole that is fluidically connected with at least two other components, volumes, plenums, or holes such that fluid flowing from one of those other components, volumes, plenums, or holes to the other or another of those components, volumes, plenums, or holes would first flow through the “fluidically interposed” component before reaching that other or another of those components, volumes, plenums, or holes. For example, if a pump is fluidically interposed between a reservoir and an outlet, fluid that flowed from the reservoir to the outlet would first flow through the pump before reaching the outlet.

The first valve manifold 1068a may, for example, be controllable to cause vapors from one or both of the vaporizers 1072a and 1072b to be flowed either to the processing chamber 1002 or through the first bypass line 1070a and into the vacuum foreline 1052. The first valve manifold 1068a may also be controllable to cause a purge gas to be flowed from the purge gas source 1074 and into the first inlet 1016.

For example, to flow vapor from the first vaporizer 1072a into the reaction space 1020, the valve A2 may be actuated to cause the vapor from the first vaporizer 1072a to first flow into the first bypass line 1070a. This flow may be maintained for a period of time sufficient to allow the flow of the vapor to reach steady state flow conditions. After sufficient time has passed (or after a flow meter, if used, indicates that the flow rate is stable), valves A2, A3, and A5 may be actuated to cause the vapor flow from the first vaporizer 1072a to be directed to the first inlet. Similar operations with valves A4 and A5 may be performed to deliver vapor from the second vaporizer 1072b to the first inlet 1016. In some instances, it may be desirable to purge one of the vapors from the first plenum 1012 by actuating the valves A1, A3, and A5 so as to cause the purge gas from the purge gas source 1074 to be flowed into the first inlet 1016. In some additional implementations, it may be desirable to simultaneously flow vapor from one of the vaporizers 1072a or 1072b in tandem with flowing gas from the purge gas into the first inlet 1016. Such implementations may be used to dilute the concentration of the reactant(s) contained in such vapor(s).

It will be appreciated that the second valve manifold 1068b may be controlled in a similar manner, e.g., by controlling valves B1-B5, to provide vapors from vaporizers 1072c and 1072d to the second inlet 1018 or to the second bypass line 1070b. It will be further appreciated that different manifold arrangements may be utilized as well, including a single unitary manifold that includes valves for controlling flow of the precursor(s), counter-reactant(s), or other reactants to the first inlet 1016 and the second inlet 1018.

As mentioned earlier, some apparatuses 1000 may feature a lesser number of vapor sources, e.g., only two vaporizers 1072, in which case the valve manifold(s) 1068 may be modified to have a lesser number of valves, e.g., only valves A1-A3.

As discussed above, apparatuses such as apparatus 1000, which may be used to provide for dry deposition of films, may be configured to maintain particular temperature profiles within the processing chamber 1002. In particular, such apparatuses 1000 may be configured to maintain the substrate 1022 at a lower temperature, e.g., at least 25° C. to 50° C. lower, than most of the equipment of the apparatus 1002 that comes into direct contact with the precursor(s) and/or counter-reactant(s). Additionally, the temperature of the equipment of the apparatus 1000 that comes into direct contact with the precursor(s) and/or counter-reactant(s) may be kept to an elevated level that is sufficiently high that condensation of the vaporized reactants on the surfaces of such equipment is discouraged. At the same time, the substrate 1022 temperature may be controlled to a level that promotes condensation, or at least deposition, of the reactants on the substrate 1022.

To provide for such temperature control, various heating systems may be included in the apparatus 1000. For example, the processing chamber 1002 may have receptacles for receiving cartridge heaters 1058, e.g., for a processing chamber 1002 that has a generally cylindrical interior volume but a square or rectangular external shape, vertical holes for receiving cartridge heaters 1058 may be bored into the four corners of the chamber 1002 housing. In some implementations, the showerhead 1010 may be covered with heater blankets 1060, which may be used to apply heat across the exposed upper surface of the showerhead 1010 to keep the showerhead temperature elevated. It may also be beneficial to heat various gas lines that are used to conduct the vaporized reactants from the vaporizers 1072 to the showerhead 1010. For example, resistive heater tape may be wound around such gas lines and used to heat them to an elevated temperature. As shown in FIG. 10, all of the gas lines that potentially have precursor(s) and/or counter-reactant(s) flowing through them are shown as being heated, including the bypass lines 1070. The only exceptions are the gas lines from the valve manifolds 1068 to the first inlet 1016 and the second inlet 1018, which may be quite short and may be indirectly heated by the showerhead 1010. Of course, even these gas lines may be actively heated, if desired. In some implementations, heaters may be provided proximate to the gate valve 1006 to provide heat to the gate valve as well.

The various operational systems of the apparatus 1000 may be controlled by a controller 1084, which may include one or more processors 1086 and one or more memory devices 1088 that are operatively connected with each other and that are communicatively connected with various systems and subsystems of the apparatus 1000 so as to provide for control functionality for those systems. For example, the controller 1084 may be configured to control the valves A1-A5 and B1-B5, the various heaters 1058, 1060, the vaporizers 1072, the regulator valve 1054, the gate valve 1006, the wafer support z-actuator, and so forth.

Once the film layer has been deposited on the substrate 1022, the substrate 1022 may, as noted above, be transferred to one or more subsequent processing chambers or tool for additional operations (e.g., any described herein). Further deposition apparatuses are described in International Patent Application No. PCT/US2020/038968, filed Jun. 22, 2020, published as International Publication No. WO 2020/263750, titled “APPARATUS FOR PHOTORESIST DRY DEPOSITION,” which is herein incorporated by reference in its entirety.

Embodiments of this disclosure are directed to such processing and processing apparatus.

### EXAMPLES

### Example 1: Positive-Tone Wet Development of Organotin PR with Dilute Aqueous Acids

Initial experiments suggest lower DtS and improved selectivity when using dilute aqueous HCl (e.g., 0.9% (v/v) HCl), as compared to aqueous 2.5% (v/v) TMAH. Development was performed for 30 seconds for 100 nm films that were patterned with e-beam raster patterns.

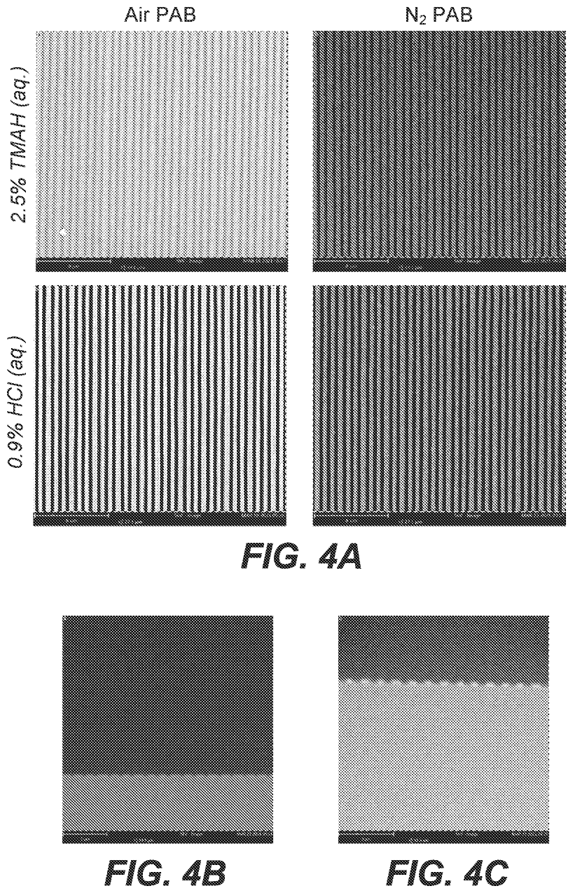

FIG. 4A-C provides SEM images of resist films produced by using a positive tone development process with aqueous TMAH (top row in FIG. 4A, side view in FIG. 4B) or aqueous HCl (bottom row in FIG. 4A, side view in FIG. 4C). PAB was performed for 3 minutes at 200° C. under air or nitrogen (N₂). As can be seen, an aqueous acid can provide an alternative developer option for processing of organotin photoresists.

### Example 2: Dilution Studies

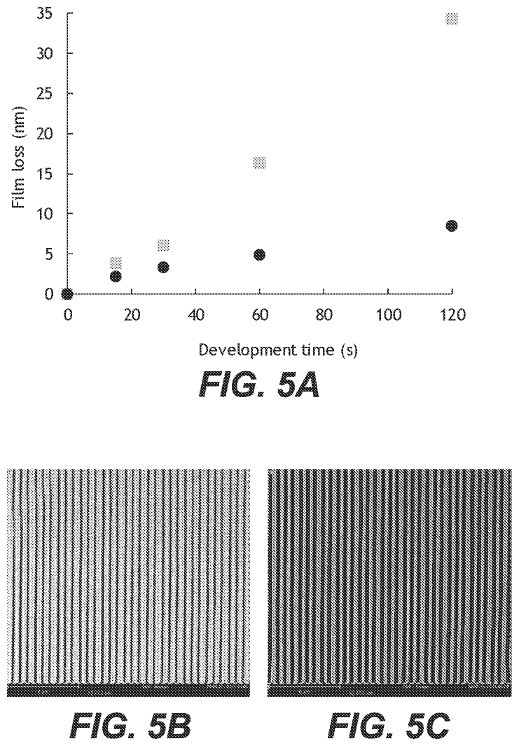

Positive tone development was performed with differing concentrations of aqueous acid, including 0.5% (v/v) HCl (aq) or 0.9% (v/v) HCl (aq). As can be seen in FIG. 5A-5C, 0.5% (v/v) HCl development still cleared exposed regions within 30 seconds. The process flow included deposition of an organotin photoresist film to a thickness of about 100 nm, in which PAB was not performed; EUV exposure by way of e-beam raster exposure for 10 seconds (FIG. 5B) or 20 seconds (FIG. 5C), in which PEB was not performed; and then development with either 0.5% (v/v) HCl (aq) or 0.9% (v/v) HCl (aq) for 30 seconds.

### Example 3: Preliminary Screening

Preliminary screening studies were conducted to characterize developed films. In particular, if the aqueous acid includes a halogen, then tin halide species may be inadvertently maintained on a developed surface. The process flow included deposition of an organotin photoresist film to a thickness of about 100 nm; UV exposure for 2 minutes; and then development with 0.9% (v/v) HCl (aq) for 30 seconds. Optionally, the developed film can be rinsed with water. After development, energy-dispersive X-ray spectroscopy (EDX) and x-ray photoelectron spectroscopy (XPS) studies were conducted for a developed films.

In particular, no chloride species (Cl⁻) were detected in any EDX experiments. Further XPS studies were conducted to understand whether any undesirable Sn—Cl species could be formed upon introduction of Cl⁻ (by way of using HCl within the developer solution). As seen in Table 1, no Sn—Cl residue was detected on developed surfaces.

TABLE 1

| Sample description [PR thickness] | Si % | C % | O % | Sn % | Cl % |
|---|---|---|---|---|---|
| Baseline: Bare Si [0 nm] | 52.8 | 5.1 | 41.0 | 0.1 | — |
| UV exposed + HCl (aq.) developed + | 53.7 | 4.7 | 40.1 | 0.4 | — |
| H₂O rinse [0 nm] | | | | | |
| UV exposed + HCl (aq.) developed | 52.8 | 5.5 | 40.0 | 0.4 | — |
| [0 nm] | | | | | |
| Baseline: Undeveloped PR [100 nm] | — | 39.6 | 36.1 | 19.9 | — |
| Unexposed + HCl (aq.) developed + | — | 37.4 | 35.2 | 19.5 | — |
| H₂O rinse [94 nm] | | | | | |

### Definitions

By “acid” is meant any molecule, ion, or compound capable of donating a proton or forming a covalent bond with an electron pair.

By “acyloxy” or “alkanoyloxy,” as used interchangeably herein, is meant an acyl or alkanoyl group, as defined herein, attached to the parent molecular group through an oxy group. In particular embodiments, the alkanoyloxy is —O—C(O)-Ak, in which Ak is an alkyl group, as defined herein. In some embodiments, an unsubstituted alkanoyloxy is a C₂₋₇ alkanoyloxy group. Exemplary alkanoyloxy groups include acetoxy.

By “alkenyl” is meant an optionally substituted C₂₋₂₄ alkyl group having one or more double bonds. The alkenyl group can be cyclic (e.g., C₃₋₂₄ cycloalkenyl) or acyclic. The alkenyl group can also be substituted or unsubstituted. For example, the alkenyl group can be substituted with one or more substitution groups, as described herein for alkyl. Non-limiting unsubstituted alkenyl groups include allyl and vinyl. In some embodiments, the unsubstituted alkenyl group is a C₂₋₆, C₂₋₈, C₂₋₁₀, C₂₋₁₂, C₂₋₁₆, C₂₋₁₈, C₂₋₂₀, C₂₋₂₄, C₃₋₈, C₃₋₁₀, C₃₋₁₂, C₃₋₁₆, C₃₋₁₈, C₃₋₂₀, or C₃₋₂₄ alkenyl group.

By “alkenylene” is meant a multivalent (e.g., bivalent) form of an alkenyl group, which is an optionally substituted C₂₋₂₄ alkyl group having one or more double bonds. The alkenylene group can be cyclic (e.g., C₃₋₂₄ cycloalkenyl) or acyclic. The alkenylene group can be substituted or unsubstituted. For example, the alkenylene group can be substituted with one or more substitution groups, as described herein for alkyl. Exemplary, non-limiting alkenylene groups include —CH═CH— or —CH═CHCH₂—.

By “alkoxy” is meant —OR, where R is an optionally substituted alkyl group, as described herein. Exemplary alkoxy groups include methoxy, ethoxy, butoxy, trihaloalkoxy, such as trifluoromethoxy, etc. The alkoxy group can be substituted or unsubstituted. For example, the alkoxy group can be substituted with one or more substitution groups, as described herein for alkyl. Exemplary unsubstituted alkoxy groups include C₁₋₃, C₁₋₆, C₁₋₁₂, C₁₋₁₆, C₁₋₁₈, C₁₋₂₀, or C₁₋₂₄ alkoxy groups.

By “alkyl” and the prefix “alk” is meant a branched or unbranched saturated hydrocarbon group of 1 to 24 carbon atoms, such as methyl (Me), ethyl (Et), n-propyl (n-Pr), isopropyl (i-Pr), cyclopropyl, n-butyl (n-Bu), isobutyl (i-Bu), s-butyl (s-Bu), t-butyl (t-Bu), cyclobutyl, n-pentyl, isopentyl, s-pentyl, neopentyl, hexyl, heptyl, octyl, nonyl, decyl, dodecyl, tetradecyl, hexadecyl, eicosyl, tetracosyl, and the like. The alkyl group can be cyclic (e.g., C₃₋₂₄ cycloalkyl) or acyclic. The alkyl group can be branched or unbranched. The alkyl group can also be substituted or unsubstituted. For example, the alkyl group can include haloalkyl, in which the alkyl group is substituted by one or more halo groups, as described herein. In another example, the alkyl group can be substituted with one, two, three or, in the case of alkyl groups of two carbons or more, four substituents independently selected from the group consisting of: (1) C₁₋₆ alkoxy (e.g., —O-Ak, wherein Ak is optionally substituted C₁₋₆ alkyl); (2) amino (e.g., —NR_{N1}R^{N2}, where each of R^{N1} and R^{N2} is, independently, H or optionally substituted alkyl, or R^{N1} and R^{N2}, taken together with the nitrogen atom to which each are attached, form a heterocyclyl group); (3) aryl; (4) arylalkoxy (e.g., —O-Lk-Ar, wherein Lk is a bivalent form of optionally substituted alkyl and Ar is optionally substituted aryl); (5) aryloyl (e.g., —C(O)—Ar, wherein Ar is optionally substituted aryl); (6) cyano (e.g., —CN); (7) carboxyaldehyde (e.g., —C(O)H); (8) carboxyl (e.g., —CO₂H); (9) C₃₋₈ cycloalkyl (e.g., a monovalent saturated or unsaturated non-aromatic cyclic C₃₋₈ hydrocarbon group); (10) halo (e.g., F, Cl, Br, or I); (11) heterocyclyl (e.g., a 5-, 6- or 7-membered ring, unless otherwise specified, containing one, two, three, or four non-carbon heteroatoms, such as nitrogen, oxygen, phosphorous, sulfur, or halo); (12) heterocyclyloxy (e.g., —O-Het, wherein Het is heterocyclyl, as described herein); (13) heterocyclyloyl (e.g., —C(O)—Het, wherein Het is heterocyclyl, as described herein); (14) hydroxyl (e.g., —OH); (15)N-protected amino; (16) nitro (e.g., —NO₂); (17) oxo (e.g., ═O); (18) —CO₂R^{A}, where R^{A} is selected from the group consisting of (a) C₁₋₆ alkyl, (b) C₄₋₁₈ aryl, and (c) (C₄₋₁₈ aryl) C₁₋₆ alkyl (e.g., -Lk-Ar, wherein Lk is a bivalent form of optionally substituted alkyl group and Ar is optionally substituted aryl); (19) —C(O)NR^{B}R^{C}, where each of R^{B} and R^{C} is, independently, selected from the group consisting of (a) hydrogen, (b) C₁₋₆ alkyl, (c) C₄₋₁₈ aryl, and (d) (C₄₋₁₈ aryl) C₁₋₆ alkyl (e.g., -Lk-Ar, wherein Lk is a bivalent form of optionally substituted alkyl group and Ar is optionally substituted aryl); and (20) —NR^{G}R^{H}, where each of R^{G} and R^{H} is, independently, selected from the group consisting of (a) hydrogen, (b) an N-protecting group, (c) C₁₋₆ alkyl, (d) C₂₋₆ alkenyl (e.g., optionally substituted alkyl having one or more double bonds), (e) C₂₋₆ alkynyl (e.g., optionally substituted alkyl having one or more triple bonds), (f) C₄₋₁₈ aryl, (g) (C₄₋₁₈ aryl) C₁₋₆ alkyl (e.g., Lk-Ar, wherein Lk is a bivalent form of optionally substituted alkyl group and Ar is optionally substituted aryl), (h) C₃₋₈ cycloalkyl, and (i) (C₃₋₈ cycloalkyl) C₁₋₆ alkyl (e.g., -Lk-Cy, wherein Lk is a bivalent form of optionally substituted alkyl group and Cy is optionally substituted cycloalkyl, as described herein), wherein in one embodiment no two groups are bound to the nitrogen atom through a carbonyl group. The alkyl group can be a primary, secondary, or tertiary alkyl group substituted with one or more substituents (e.g., one or more halo or alkoxy). In some embodiments, the unsubstituted alkyl group is a C₁₋₃, C₁₋₆, C₁₋₈, C₁₋₁₀, C₁₋₁₂, C₁₋₁₆, C₁₋₁₈, C₁₋₂₀, C₁₋₂₄, C₂₋₆, C₂₋₈, C₂₋₁₀, C₂₋₁₂, C₂₋₁₆, C₂₋₁₈, C₂₋₂₀, C₂₋₂₄, C₃₋₈, C₃₋₁₀, C₃₋₁₂, C₃₋₁₆, C₃₋₁₈, C₃₋₂₀, or C₃₋₂₄ alkyl group.

By “alkylene” is meant a multivalent (e.g., bivalent) form of an alkyl group, as described herein. Exemplary alkylene groups include methylene, ethylene, propylene, butylene, etc. In some embodiments, the alkylene group is a C₁₋₃, C₁₋₆, C₁₋₁₂, C₁₋₁₆, C₁₋₁₈, C₁₋₂₀, C₁₋₂₄, C₂₋₃, C₂₋₆, C₂₋₁₂, C₂₋₁₆, C₂₋₁₈, C₂₋₂₀, or C₂₋₂₄ alkylene group. The alkylene group can be branched or unbranched. The alkylene group can also be substituted or unsubstituted. For example, the alkylene group can be substituted with one or more substitution groups, as described herein for alkyl.

By “alkynyl” is meant an optionally substituted C₂₋₂₄ alkyl group having one or more triple bonds. The alkynyl group can be cyclic or acyclic and is exemplified by ethynyl, 1-propynyl, and the like. The alkynyl group can also be substituted or unsubstituted. For example, the alkynyl group can be substituted with one or more substitution groups, as described herein for alkyl. In some embodiments, the unsubstituted alkynyl group is a C₂₋₆, C₂₋₈, C₂₋₁₀, C₂₋₁₂, C₂₋₁₆, C₂₋₁₈, C₂₋₂₀, C₂₋₂₄, C₃₋₈, C₃₋₁₀, C₃₋₁₂, C₃₋₁₆, C₃₋₁₈, C₃₋₂₀, or C₃₋₂₄ alkynyl group.

By “alkynylene” is meant a multivalent (e.g., bivalent) form of an alkynyl group, which is an optionally substituted C₂₋₂₄ alkyl group having one or more triple bonds. The alkynylene group can be cyclic or acyclic. The alkynylene group can be substituted or unsubstituted. For example, the alkynylene group can be substituted with one or more substitution groups, as described herein for alkyl. Exemplary, non-limiting alkynylene groups include —C≡C— or —C≡CCH₂—.

By “amino” is meant —NR^{N1}R^{N2}, where each of R^{N1} and R^{N2} is, independently, H, optionally substituted alkyl, or optionally substituted aryl, or R^{N1} and R^{N2}, taken together with the nitrogen atom to which each are attached, form a heterocyclyl group, as defined herein.

By “aryl” is meant a group that contains any carbon-based aromatic group including, but not limited to, phenyl, benzyl, anthracenyl, anthryl, benzocyclobutenyl, benzocyclooctenyl, biphenylyl, chrysenyl, dihydroindenyl, fluoranthenyl, indacenyl, indenyl, naphthyl, phenanthryl, phenoxybenzyl, picenyl, pyrenyl, terphenyl, and the like, including fused benzo-C₄₋₈ cycloalkyl radicals (e.g., as defined herein) such as, for instance, indanyl, tetrahydronaphthyl, fluorenyl, and the like. The term aryl also includes heteroaryl, which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term non-heteroaryl, which is also included in the term aryl, defines a group that contains an aromatic group that does not contain a heteroatom. The aryl group can be substituted or unsubstituted. The aryl group can be substituted with one, two, three, four, or five substituents, such as any described herein for alkyl.

By “arylene” is meant a multivalent (e.g., bivalent) form of an aryl group, as described herein. Exemplary arylene groups include phenylene, naphthylene, biphenylene, triphenylene, diphenyl ether, acenaphthenylene, anthrylene, or phenanthrylene. In some embodiments, the arylene group is a C₄₋₁₈, C₄₋₁₄, C₄₋₁₂, C₄₋₁₀, C₆₋₁₈, C₆₋₁₄, C₆₋₁₂, or C₆₋₁₀ arylene group. The arylene group can be branched or unbranched. The arylene group can also be substituted or unsubstituted. For example, the arylene group can be substituted with one or more substitution groups, as described herein for alkyl or aryl.

By “(aryl)(alkyl) ene” is meant a bivalent form including an arylene group, as described herein, attached to an alkylene or a heteroalkylene group, as described herein. In some embodiments, the (aryl)(alkyl) ene group is -L-Ar— or -L-Ar-L- or —Ar-L-, in which Ar is an arylene group and each L is, independently, an optionally substituted alkylene group or an optionally substituted heteroalkylene group.

By “carbonyl” is meant a —C(O)— group, which can also be represented as >C═O, or a —CO group.

By “carboxyl” is meant a —CO₂H group.

By “carboxylic acid” is meant an acid, as defined herein, having one or more carboxyl groups. Examples of carboxylic acids include a monocarboxylic acid (having a single carboxyl group) or a dicarboxylic acid (having two carboxyl groups).

By “carboxyalkyl” is meant an alkyl group, as defined herein, substituted by one or more carboxyl groups, as defined herein.

By “carboxyaryl” is meant an aryl group, as defined herein, substituted by one or more carboxyl groups, as defined herein.

By “cyclic anhydride” is meant a 3—, 4-, 5-, 6- or 7-membered ring (e.g., a 5-, 6- or 7-membered ring), unless otherwise specified, having a —C(O)—O—C(O)— group within the ring. The term “cyclic anhydride” also includes bicyclic, tricyclic and tetracyclic groups in which any of the above rings is fused to one, two, or three rings independently selected from the group consisting of an aryl ring, a cyclohexane ring, a cyclohexene ring, a cyclopentane ring, a cyclopentene ring, and another monocyclic heterocyclic ring. Exemplary cyclic anhydride groups include a radical formed from succinic anhydride, glutaric anhydride, maleic anhydride, phthalic anhydride, isochroman-1,3-dione, oxepanedione, tetrahydrophthalic anhydride, hexahydrophthalic anhydride, pyromellitic dianhydride, naphthalic anhydride, 1,2-cyclohexanedicarboxylic anhydride, etc., by removing one or more hydrogen. Other exemplary cyclic anhydride groups include dioxotetrahydrofiranyl, dioxodihydroisobenzofuranyl, etc. The cyclic anhydride group can also be substituted or unsubstituted. For example, the cyclic anhydride group can be substituted with one or more groups including those described herein for heterocyclyl.

By “cycloalkenyl” is meant a monovalent unsaturated non-aromatic or aromatic cyclic hydrocarbon group of from three to eight carbons, unless otherwise specified, having one or more double bonds. The cycloalkenyl group can also be substituted or unsubstituted. For example, the cycloalkenyl group can be substituted with one or more groups including those described herein for alkyl.

By “cycloalkyl” is meant a monovalent saturated or unsaturated non-aromatic or aromatic cyclic hydrocarbon group of from three to eight carbons, unless otherwise specified, and is exemplified by cyclopropyl, cyclobutyl, cyclopentyl, cyclopentadienyl, cyclohexyl, cycloheptyl, bicyclo[2.2.1.]heptyl, and the like. The cycloalkyl group can also be substituted or unsubstituted. For example, the cycloalkyl group can be substituted with one or more groups including those described herein for alkyl.

By “halo” is meant F, Cl, Br, or I.

By “haloalkenyl” is meant an alkenyl group, as defined herein, substituted with one or more halo.

By “haloalkyl” is meant an alkyl group, as defined herein, substituted with one or more halo.

By “haloalkynyl” is meant an alkynyl group, as defined herein, substituted with one or more halo.

By “haloaryl” is meant an aryl group, as defined herein, substituted with one or more halo.

By “heteroalkyl” is meant an alkyl group, as defined herein, containing one, two, three, or four non-carbon heteroatoms (e.g., independently selected from the group consisting of nitrogen, oxygen, phosphorous, sulfur, selenium, or halo).

By “heteroalkylene” is meant a bivalent form of an alkyl group, as defined herein, containing one, two, three, or four non-carbon heteroatoms (e.g., independently selected from the group consisting of nitrogen, oxygen, phosphorous, sulfur, selenium, or halo). The heteroalkylene group can be substituted or unsubstituted. For example, the heteroalkylene group can be substituted with one or more substitution groups, as described herein for alkyl.

By “heterocyclyl” is meant a 3—, 4-, 5-, 6- or 7-membered ring (e.g., a 5-, 6- or 7-membered ring), unless otherwise specified, containing one, two, three, or four non-carbon heteroatoms (e.g., independently selected from the group consisting of nitrogen, oxygen, phosphorous, sulfur, selenium, or halo). The 3-membered ring has zero to one double bonds, the 4- and 5-membered ring has zero to two double bonds, and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. Heterocyclics include acridinyl, adenyl, alloxazinyl, azaadamantanyl, azabenzimidazolyl, azabicyclononyl, azacycloheptyl, azacyclooctyl, azacyclononyl, azahypoxanthinyl, azaindazolyl, azaindolyl, azecinyl, azepanyl, azepinyl, azetidinyl, azetyl, aziridinyl, azirinyl, azocanyl, azocinyl, azonanyl, benzimidazolyl, benzisothiazolyl, benzisoxazolyl, benzodiazepinyl, benzodiazocinyl, benzodihydrofuryl, benzodioxepinyl, benzodioxinyl, benzodioxanyl, benzodioxocinyl, benzodioxolyl, benzodithiepinyl, benzodithiinyl, benzodioxocinyl, benzofuranyl, benzophenazinyl, benzopyranonyl, benzopyranyl, benzopyrenyl, benzopyronyl, benzoquinolinyl, benzoquinolizinyl, benzothiadiazepinyl, benzothiadiazolyl, benzothiazepinyl, benzothiazocinyl, benzothiazolyl, benzothienyl, benzothiophenyl, benzothiazinonyl, benzothiazinyl, benzothiopyranyl, benzothiopyronyl, benzotriazepinyl, benzotiazinonyl, benzotriazinyl, benzotriazolyl, benzoxathiinyl, benzotrioxepinyl, benzoxadiazepinyl, benzoxathiazepinyl, benzoxathiepinyl, benzoxathiocinyl, benzoxazepinyl, benzoxazinyl, benzoxazocinyl, benzoxazolinonyl, benzoxazolinyl, benzoxazolyl, benzylsultamyl benzylsultimyl, bipyrazinyl, bipyridinyl, carbazolyl (e.g., 4H-carbazolyl), carbolinyl (e.g., β-carbolinyl), chromanonyl, chromanyl, chromenyl, cinnolinyl, coumarinyl, cytdinyl, cytosinyl, decahydroisoquinolinyl, decahydroquinolinyl, diazabicyclooctyl, diazetyl, diaziridinethionyl, diaziridinonyl, diaziridinyl, diazirinyl, dibenzisoquinolinyl, dibenzoacridinyl, dibenzocarbazolyl, dibenzofuranyl, dibenzophenazinyl, dibenzopyranonyl, dibenzopyronyl (xanthonyl), dibenzoquinoxalinyl, dibenzothiazepinyl, dibenzothiepinyl, dibenzothiophenyl, dibenzoxepinyl, dihydroazepinyl, dihydroazetyl, dihydrofuranyl, dihydrofuryl, dihydroisoquinolinyl, dihydropyranyl, dihydropyridinyl, dihydroypyridyl, dihydroquinolinyl, dihydrothienyl, dihydroindolyl, dioxanyl, dioxazinyl, dioxindolyl, dioxiranyl, dioxenyl, dioxinyl, dioxobenzofuranyl, dioxolyl, dioxotetrahydrofuranyl, dioxothiomorpholinyl, dithianyl, dithiazolyl, dithienyl, dithiinyl, furanyl, furazanyl, furoyl, furyl, guaninyl, homopiperazinyl, homopiperidinyl, hypoxanthinyl, hydantoinyl, imidazolidinyl, imidazolinyl, imidazolyl, indazolyl (e.g., 1H-indazolyl), indolenyl, indolinyl, indolizinyl, indolyl (e.g., 1H-indolyl or 3H-indolyl), isatinyl, isatyl, isobenzofuranyl, isochromanyl, isochromenyl, isoindazoyl, isoindolinyl, isoindolyl, isopyrazolonyl, isopyrazolyl, isoxazolidiniyl, isoxazolyl, isoquinolinyl, isoquinolinyl, isothiazolidinyl, isothiazolyl, morpholinyl, naphthindazolyl, naphthindolyl, naphthiridinyl, naphthopyranyl, naphthothiazolyl, naphthothioxolyl, naphthotriazolyl, naphthoxindolyl, naphthyridinyl, octahydroisoquinolinyl, oxabicycloheptyl, oxauracil, oxadiazolyl, oxazinyl, oxaziridinyl, oxazolidinyl, oxazolidonyl, oxazolinyl, oxazolonyl, oxazolyl, oxepanyl, oxetanonyl, oxetanyl, oxetyl, oxtenayl, oxindolyl, oxiranyl, oxobenzoisothiazolyl, oxochromenyl, oxoisoquinolinyl, oxoquinolinyl, oxothiolanyl, phenanthridinyl, phenanthrolinyl, phenazinyl, phenothiazinyl, phenothienyl (benzothiofuranyl), phenoxathiinyl, phenoxazinyl, phthalazinyl, phthalazonyl, phthalidyl, phthalimidinyl, piperazinyl, piperidinyl, piperidonyl (e.g., 4-piperidonyl), pteridinyl, purinyl, pyranyl, pyrazinyl, pyrazolidinyl, pyrazolinyl, pyrazolopyrimidinyl, pyrazolyl, pyridazinyl, pyridinyl, pyridopyrazinyl, pyridopyrimidinyl, pyridyl, pyrimidinyl, pyrimidyl, pyronyl, pyrrolidinyl, pyrrolidonyl (e.g., 2-pyrrolidonyl), pyrrolinyl, pyrrolizidinyl, pyrrolyl (e.g., 2H-pyrrolyl), pyrylium, quinazolinyl, quinolinyl, quinolizinyl (e.g., 4H-quinolizinyl), quinoxalinyl, quinuclidinyl, selenazinyl, selenazolyl, selenophenyl, succinimidyl, sulfolanyl, tetrahydrofuranyl, tetrahydrofuryl, tetrahydroisoquinolinyl, tetrahydroisoquinolyl, tetrahydropyridinyl, tetrahydropyridyl (piperidyl), tetrahydropyranyl, tetrahydropyronyl, tetrahydroquinolinyl, tetrahydroquinolyl, tetrahydrothienyl, tetrahydrothiophenyl, tetrazinyl, tetrazolyl, thiadiazinyl (e.g., 6H-1,2,5-thiadiazinyl or 2H,6H-1,5,2-dithiazinyl), thiadiazolyl, thianthrenyl, thianyl, thianaphthenyl, thiazepinyl, thiazinyl, thiazolidinedionyl, thiazolidinyl, thiazolyl, thienyl, thiepanyl, thiepinyl, thietanyl, thietyl, thiiranyl, thiocanyl, thiochromanonyl, thiochromanyl, thiochromenyl, thiodiazinyl, thiodiazolyl, thioindoxyl, thiomorpholinyl, thiophenyl, thiopyranyl, thiopyronyl, thiotriazolyl, thiourazolyl, thioxanyl, thioxolyl, thymidinyl, thyminyl, triazinyl, triazolyl, trithianyl, urazinyl, urazolyl, uretidinyl, uretinyl, uricyl, uridinyl, xanthenyl, xanthinyl, xanthionyl, and the like, as well as modified forms thereof (e.g., including one or more oxo and/or amino) and salts thereof. The heterocyclyl group can be substituted or unsubstituted. For example, the heterocyclyl group can be substituted with one or more substitution groups, as described herein for alkyl.

By “hydrocarbyl” is meant a univalent group formed by removing a hydrogen atom from a hydrocarbon. Non-limiting unsubstituted hydrocarbyl groups include alkyl, alkenyl, alkynyl, and aryl, as defined herein, in which these groups include only carbon and hydrogen atoms. The hydrocarbyl group can be substituted or unsubstituted. For example, the hydrocarbyl group can be substituted with one or more substitution groups, as described herein for alkyl. In other embodiments, any alkyl or aryl group herein can be replaced with a hydrocarbyl group, as defined herein.

By “hydroxyl” is meant —OH.

By “hydroxyalkyl” is meant an alkyl group, as defined herein, substituted by one to three hydroxyl groups, with the proviso that no more than one hydroxyl group may be attached to a single carbon atom of the alkyl group and is exemplified by hydroxymethyl, dihydroxypropyl, and the like.

By “hydroxyaryl” is meant an aryl group, as defined herein, substituted by one to three hydroxyl groups, with the proviso that no more than one hydroxyl group may be attached to a single carbon atom of the aryl group and is exemplified by hydroxyphenyl, dihydroxyphenyl, and the like.

By “isocyanato” is meant —NCO.

By “oxido” is meant an —O— group.

By “oxo” is meant an ═O group.

By “oxoacid” is meant an acid, as defined herein, that contains one or more oxygen atoms. Non-limiting oxoacids include a phosphorous oxoacid (e.g., an oxoacid, as defined herein, including one or more phosphorous atoms) or a sulfur oxoacid (e.g., an oxoacid, as defined herein, including one or more sulfur atoms).

By “phosphine” is meant a trivalent or tetravalent phosphorous having hydrocarbyl moieties. In some embodiments, phosphine is a —PR^{P}₃ group, where each R^{P} is, independently, H, optionally substituted alkyl, or optionally substituted aryl. The phosphine group can be substituted or unsubstituted. For example, the phosphine group can be substituted with one or more substitution groups, as described herein for alkyl.

By “selenol” is meant an —SeH group.

By “tellurol” is meant an —TeH group.

By “thioisocyanato” is meant —NCS.

By “thiol” is meant an —SH group.

As used herein, the terms “top,” “bottom,” “upper,” “lower,” “above,” and “below” are used to provide a relative relationship between structures. The use of these terms does not indicate or require that a particular structure must be located at a particular location in the apparatus.

### CONCLUSION

Process and apparatus for use of an aqueous acid for developing or treating a radiation-sensitive film. In some instances, use of the aqueous acid for positive tone development of dry deposited (e.g., by chemical vapor deposition (CVD)) EUV photopattemable resist films, is disclosed. In other instances, use of the aqueous acid for removing residual resist components is also disclosed.

It is understood that the examples and embodiments described herein are for illustrative purposes only and that various modifications or changes in light thereof will be suggested to persons skilled in the art. Although various details have been omitted for clarity's sake, various design alternatives may be implemented. Therefore, the present examples are to be considered as illustrative and not restrictive, and the disclosure is not to be limited to the details given herein, but may be modified within the scope of the disclosure.

The following sample claims are provided for further illustration of certain embodiments of the disclosure. The disclosure is not necessarily limited to these embodiments.

1. A method comprising:
exposing a radiation-sensitive resist film to a patterning radiation source, thereby providing an exposed resist film having an exposed region and an unexposed region; and
developing the exposed resist film by removing the exposed region with an aqueous acid, thereby forming a pattern by a positive tone wet development process.

2. The method of claim 1, wherein the method does not include a baking operation before or after said exposing.

3. The method of claim 1, wherein the method comprises a baking operation before said exposing.

4. The method of claim 1, wherein the resist film further comprises a hydrophobic capping layer disposed on a top surface.

5. The method of claim 1, wherein the resist film comprises a vertical gradient characterized by an increase in hydrophobicity at a top surface.

6. (canceled)

7. A method comprising:
exposing a radiation-sensitive resist film to a patterning radiation source, thereby providing an exposed resist film having an exposed region and an unexposed region;
developing the exposed resist film by removing the unexposed region, thereby forming a pattern by a negative tone development process; and
treating the pattern with an aqueous acid.

8. The method of claim 7, wherein said developing comprises a wet process or a dry process.

9. The method of claim 8, wherein said developing comprises use of an alkaline developer, an acidic developer, or a deprotecting solvent.

10. The method of claim 9, wherein said developing comprises use of a quaternary alkylammonium hydroxide, tetramethylammonium hydroxide (TMAH), choline, a halide, hydrogen fluoride (HF), hydrogen chloride (HCl), an organic acid, formic acid, acetic acid, oxalic acid, or citric acid.

11. The method of claim 8, wherein said developing comprises use of a vapor-based acidic etchant.

12. The method of claim 11, wherein the vapor-based acidic etchant comprises hydrogen chloride (HCl), hydrogen bromide (HBr), boron trichloride (BCl₃), silicon tetrachloride (SiCl₄), a combination of hydrogen gas (H₂) and chlorine gas (Cl₂), or a combination of hydrogen gas (H₂) and bromine gas (Cl₂).

13. The method of claim 7, wherein said treating comprises removing residual species or particles formed after said developing.

14. The method of claim 1, wherein the aqueous acid comprises about 0.1% (v/v) to 2% (v/v) of an acid in a solvent.

15. The method of claim 14, wherein the acid is a halogen-containing acid, a hydrogen halide, an inorganic acid, a phosphorus oxoacid, a sulfur oxoacid, or a carboxylic acid.

16. The method of claim 15, wherein the acid is selected from the group consisting of hydrogen chloride (HCl), hydrogen bromide (HBr), hydrogen iodide (HI), phosphoric acid, sulfuric acid, formic acid, acetic acid, trifluoroacetic acid, oxalic acid, and citric acid.

17. The method of claim 1, wherein the resist film comprises an Extreme Ultraviolet (EUV)-sensitive photoresist layer or an EUV-sensitive inorganic photoresist layer.

18. (canceled)

19. The method of claim 1, wherein the resist film comprises tin (Sn), indium (In), bismuth (Bi), antimony (Sb), tellurium (Te), an oxide thereof, an alloy thereof, or a combination thereof.

20. The method of claim 1, wherein the resist film comprises a chemical vapor deposited (CVD) film, a spin-on film, an organometallic oxide film, an organometallic oxide hydroxide film, a tin oxide film, or an organotin oxide film.

21. (canceled)

22. The method of claim 21, wherein said applying comprises:
providing one or more precursors comprising a structure having formula (I) or (II) to the surface of the substrate:
MₐR_{b} (I),
wherein:
M is a metal or an atom having a high EUV absorption cross-section;
each R is, independently, H, halo, optionally substituted alkyl, optionally substituted cycloalkyl, optionally substituted cycloalkenyl, optionally substituted alkenyl, optionally substituted alkynyl, optionally substituted alkoxy, optionally substituted alkanoyloxy, optionally substituted aryl, optionally substituted amino, optionally substituted bis(trialkylsilyl)amino, optionally substituted trialkylsilyl, oxo, an anionic ligand, a neutral ligand, or a multidentate ligand;
a≥1; and b≥1; or
MₐR_{b}L_{c} (II),
wherein:
M is a metal or an atom having a high EUV absorption cross-section;
each R is, independently, halo, optionally substituted alkyl, optionally substituted aryl, optionally substituted amino, optionally substituted alkoxy, or L;
each L is, independently, a ligand, an anionic ligand, a neutral ligand, a multidentate ligand, ion, or other moiety that is reactive with a counter-reactant, in which R and L with M, taken together, can optionally form a heterocyclyl group or in which R and L, taken together, can optionally form a heterocyclyl group;
a≥1; b≥1; and c≥1.

23. An apparatus for processing a substrate, the apparatus comprising:
(a) one or more process chambers, each process chamber optionally comprising a chuck or a pedestal; and
one or more inlets into the process chambers and associated flow-control hardware; and
(b) a controller having at least one processor and a memory, wherein
the at least one processor and the memory are communicatively connected with one another, the at least one processor is at least operatively connected with the flow-control hardware, and the memory stores computer-executable instructions for controlling the at least one processor to at least control the flow-control hardware and for causing claim 1.
